(19) United States
(12) Patent Application Publication
(10) Pub. No.: US 2026/0223506 A1
(43) Pub. Date: Jul. 30, 2026

(54) DISPLAY DEVICE AND ELECTRONIC DEVICE

(71) Applicant: Samsung Display Co., Ltd., Yongin-si (KR)

(72) Inventors: Kyung Rock SON, Yongin-si (KR); Yu Jin LEE, Yongin-si (KR); Jae Phil LEE, Yongin-si (KR)

(21) Appl. No.: 19/382,007

(22) Filed: Nov. 6, 2025

(30) Foreign Application Priority Data
Jan. 24, 2025 (KR) 10-2025-0011464

(51) Int. Cl. H10H 29/41; H10H 29/49

(52) U.S. Cl. CPC H10H 29/41; H10H 29/49

(57) ABSTRACT

A display device includes a pixel electrode layer on a substrate and including a pixel electrode, an insulating layer on the pixel electrode layer and covering a portion of the pixel electrode, a light emitting element on the insulating layer and including a first contact electrode located at a first side surface, and a first connection electrode on the insulating layer and the first side surface of the light emitting element and connecting the pixel electrode and the first contact electrode. The insulating layer is located at least below bottom surface vertex portions of the light emitting element and supports the light emitting element. The insulating layer includes a first opening having a width smaller than a width of the first contact electrode and below a portion of the first contact electrode, and a portion of the first connection electrode is located inside the first opening.

### CROSS-REFERENCE TO RELATED APPLICATION

This application claims priority to and the benefit of Korean Patent Application No. 10-2025-0011464 filed on January 24, 2025, in the Korean Intellectual Property Office, the entire content of which is incorporated by reference herein.

### BACKGROUND

### Field

Embodiments of the present disclosure relate to a display device and an electronic device capable of displaying an image.

### Description of the Related Art

With the advance of information-oriented society, more and more demands are placed on display devices and electronic devices capable of displaying images in various ways. Accordingly, various types of display devices and electronic devices including pixels for displaying images are being developed. A display device may be provided alone, or may be included in an electronic device and used as a display screen of the electronic device.

### SUMMARY

Aspects and features of embodiments of the present disclosure provide a display device and an electronic device capable of improving reliability.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to one or more embodiments of the present disclosure, there is provided a display device including a pixel electrode layer located on a substrate and including a pixel electrode, an insulating layer located on the pixel electrode layer and covering a portion of the pixel electrode, a light emitting element located on the insulating layer and including a first contact electrode located at a first side surface of the light emitting element, and a first connection electrode located on the insulating layer and the first side surface of the light emitting element and connecting the pixel electrode and the first contact electrode, wherein the insulating layer is located at least below bottom surface vertex portions of the light emitting element and supporting the light emitting element, the insulating layer including a first opening having width smaller than a width of the first contact electrode and located below a portion of the first contact electrode, and a portion of the first connection electrode is located inside the first opening.

In one or more embodiments, the light emitting element may further include a second side surface facing the first side surface, a third side surface in contact with one end of the first side surface and one end of the second side surface, and a fourth side surface in contact with an other end of the first side surface and an other end of the second side surface, and the first contact electrode may further be located at a portion of the third side surface and a portion of the fourth side surface of the light emitting element.

In one or more embodiments, the first opening may include a first slit-type opening crossing the first side surface of the light emitting element below the first contact electrode, a second slit-type opening crossing the third side surface of the light emitting element below the first contact electrode, and a third slit-type opening crossing the fourth side surface of the light emitting element below the first contact electrode.

In one or more embodiments, at least two slit-type openings from among the first slit-type opening, the second slit-type opening, and the third slit-type opening may be spaced from each other.

In one or more embodiments, at least two slit-type openings from among the first slit-type opening, the second slit-type opening, and the third slit-type opening may be connected to form one integral opening.

In one or more embodiments, a length of each of the first slit-type opening, the second slit-type opening, and the third slit-type opening may be 2 µm to 3 µm.

In one or more embodiments, the first slit-type opening may have a width smaller than the width of the first contact electrode in a direction in which an edge where the first side surface and the bottom surface of the light emitting element meet extends, the second slit-type opening may have a width smaller than the width of the first contact electrode in a direction in which an edge where the third side surface and the bottom surface of the light emitting element meet extends, the third slit-type opening may have a width smaller than the width of the first contact electrode in a direction in which an edge where the fourth side surface and the bottom surface of the light emitting element meet extends, and the width of each of the first slit-type opening, the second slit-type opening, and the third slit-type opening may be equal to or greater than 1 µm.

In one or more embodiments, the pixel electrode layer may further include a common electrode spaced from the pixel electrode and having a portion covered by the insulating layer, and the light emitting element may further include a second contact electrode located at the second side surface.

In one or more embodiments, the display device may further include a second connection electrode located on the insulating layer and the second side surface of the light emitting element and connecting the common electrode and the second contact electrode, the insulating layer may further include a second opening having a width smaller than a width of the second contact electrode below a portion of the second contact electrode, and a portion of the second connection electrode may be located inside the second opening.

In one or more embodiments, the second contact electrode may further be located at an other portion of the third side surface of the light emitting element and an other portion of the fourth side surface, and the second opening may include at least one from among a fourth slit-type opening crossing the second side surface of the light emitting element below the second contact electrode, a fifth slit-type opening crossing the third side surface of the light emitting element below the second contact electrode, and a sixth slit-type opening crossing the fourth side surface of the light emitting element below the second contact electrode.

In one or more embodiments, the second opening may include at least two slit-type openings from among the fourth slit-type opening, the fifth slit-type opening, and the sixth slit-type opening, and the at least two slit-type openings may be spaced from each other.

In one or more embodiments, the second opening may include at least two slit-type openings from among the fourth slit-type opening, the fifth slit-type opening, and the sixth slit-type opening, and the at least two slit-type openings may be connected to each other to form one integral opening.

In one or more embodiments, a length of each of the fourth slit-type opening, the fifth slit-type opening, and the sixth slit-type opening may be 2 µm to 3 µm.

In one or more embodiments, the fourth slit-type opening may have a width smaller than the width of the second contact electrode in a direction in which an edge where the second side surface and the bottom surface of the light emitting element meet extends, the fifth slit-type opening may have a width smaller than the width of the second contact electrode in a direction in which an edge where the third side surface and the bottom surface of the light emitting element meet extends, the sixth slit-type opening may have a width smaller than the width of the second contact electrode in a direction in which an edge where the fourth side surface and the bottom surface of the light emitting element meet extends, and the width of each of the fourth slit-type opening, the fifth slit-type opening, and the sixth slit-type opening may be equal to or greater than 1 µm.

In one or more embodiments, the first contact electrode and the second contact electrode may further be located on different portions of a bottom surface of the light emitting element, the first connection electrode may be in contact with the bottom surface of the first contact electrode on the first opening, and the second connection electrode may be in contact with the bottom surface of the second contact electrode on the second opening.

According to one or more embodiments of the present disclosure, there is provided an electronic device including a display module including a display panel, and a processor configured to transmit an image data signal to the display module, wherein the display panel includes a pixel electrode layer located on a substrate and including a pixel electrode, an insulating layer located on the pixel electrode layer and covering a portion of the pixel electrode, a light emitting element located on the insulating layer and including a first contact electrode located at a first side surface of the light emitting element, and a first connection electrode located on the insulating layer and the first side surface of the light emitting element and connecting the pixel electrode and the first contact electrode, wherein the insulating layer is located at least below bottom surface vertex portions of the light emitting element and supporting the light emitting element, the insulating layer including a first opening having a width smaller than a width of the first contact electrode below a portion of the first contact electrode, and a portion of the first connection electrode is located inside the first opening.

In one or more embodiments, the light emitting element may further include a second side surface facing the first side surface, a third side surface in contact with one end of the first side surface and one end of the second side surface, and a fourth side surface in contact with an other end of the first side surface and an other end of the second side surface, the first contact electrode may further be located at a portion of the third side surface and a portion of the fourth side surface of the light emitting element, and the first opening may include at least one slit-type opening crossing at least one among the first side surface, the third side surface, or the fourth side surface of the light emitting element.

In one or more embodiments, the pixel electrode layer may further include a common electrode spaced from the pixel electrode and a portion covered by the insulating layer, the light emitting element may further include a second contact electrode located at the second side surface, an other portion of the third side surface and an other portion of the fourth side surface, and the display panel may further include a second connection electrode located on the insulating layer and the second contact electrode and connecting the common electrode and the second contact electrode.

In one or more embodiments, the insulating layer may further include a second opening having a width smaller than the width of the second contact electrode and located below a portion of the second contact electrode, and a portion of the second connection electrode may be located inside the second opening.

In one or more embodiments, the second opening may include at least one slit-type opening crossing at least one from among the second side surface, the third side surface, or the fourth side surface of the light emitting element.

The display device and the electronic device according to one or more embodiments may include an insulating layer located on a pixel electrode, and a light emitting element and a connection electrode located on the insulating layer. In one or more embodiments, the insulating layer may include an opening having a narrower width than the width of the light emitting element under a contact electrode of the light emitting element, and a portion of the connection electrode may be located inside the opening.

According to the display device and the electronic device according to one or more embodiments, the connection electrode may be prevented from being disconnected at the periphery of the light emitting element while stably supporting the light emitting element by the insulating layer. Accordingly, open-circuit failures of the display device and the electronic device may be prevented, and the reliability of the display device and the electronic device may be improved.

However, effects, aspects, and features according to embodiments of the present disclosure are not limited to those discussed above and various other effects, aspects, and features are incorporated herein.

### BRIEF DESCRIPTION OF THE DRAWINGS

The above and other aspects and features of embodiments of the present disclosure will become more apparent by describing in detail embodiments thereof with reference to the attached drawings, in which:

FIG. 1 is a perspective view illustrating a display device according to one or more embodiments;

FIG. 2 is a plan view illustrating a display panel according to one or more embodiments;

FIG. 3 is a block diagram illustrating a display device according to one or more embodiments;

FIG. 4 is an equivalent circuit diagram illustrating a sub-pixel according to one or more embodiments;

FIG. 5 is a waveform diagram showing driving signals of a sub-pixel according to one or more embodiments;

FIG. 6 is a plan view illustrating a display panel according to one or more embodiments;

FIG. 7 is a plan view illustrating a display panel according to one or more embodiments;

FIG. 8 is a cross-sectional view showing a display panel according to one or more embodiments;

FIG. 9 is a cross-sectional view showing an area A1 of FIG. 8 in detail;

FIG. 10 is a plan view showing an insulating layer located between a pixel electrode layer and a light emitting element of a display panel according to one or more embodiments;

FIG. 11 is a plan view showing the insulating layer and the light emitting element located on the insulating layer of FIG. 10;

FIG. 12 is a cross-sectional view showing an example of an open-circuit failure that may occur in a display panel according to one or more embodiments;

FIG. 13 is a plan view illustrating an insulating layer between a pixel electrode layer and a light emitting element of a display panel according to one or more embodiments;

FIG. 14 is a plan view illustrating the insulating layer and the light emitting element located on the insulating layer of FIG. 13;

FIG. 15 is a cross-sectional view showing a display panel according to one or more embodiments;

FIG. 16 is a cross-sectional view showing an area A2 of FIG. 15 in detail;

FIG. 17 is a plan view illustrating an insulating layer between a pixel electrode layer and a light emitting element of a display panel according to one or more embodiments;

FIG. 18 is a plan view illustrating the insulating layer and the light emitting element located on the insulating layer of FIG. 17;

FIG. 19 is a plan view illustrating an insulating layer between a pixel electrode layer and a light emitting element of a display panel according to one or more embodiments;

FIG. 20 is a plan view illustrating the insulating layer and the light emitting element located on the insulating layer of FIG. 19;

FIG. 21 is a plan view illustrating an insulating layer between a pixel electrode layer and a light emitting element of a display panel according to one or more embodiments;

FIG. 22 is a plan view illustrating the insulating layer and the light emitting element located on the insulating layer of FIG. 21;

FIG. 23 is a plan view illustrating an insulating layer between a pixel electrode layer and a light emitting element of a display panel according to one or more embodiments;

FIG. 24 is a plan view illustrating the insulating layer and the light emitting element located on the insulating layer of FIG. 23;

FIG. 25 is a plan view illustrating an insulating layer between a pixel electrode layer and a light emitting element of a display panel according to one or more embodiments;

FIG. 26 is a plan view illustrating the insulating layer and the light emitting element located on the insulating layer of FIG. 25;

FIG. 27 is a plan view illustrating openings of an insulating layer according to one or more embodiments;

FIG. 28 is a plan view illustrating an insulating layer between a pixel electrode layer and a light emitting element of a display panel according to one or more embodiments;

FIG. 29 is a plan view illustrating the insulating layer and the light emitting element located on the insulating layer of FIG. 28;

FIG. 30 is a plan view illustrating an insulating layer between a pixel electrode layer and a light emitting element of a display panel according to one or more embodiments;

FIG. 31 is a plan view illustrating the insulating layer and the light emitting element located on the insulating layer of FIG. 30;

FIGS. 32 – 36 are cross-sectional views showing a manufacturing method of a display device according to one or more embodiments;

FIG. 37 is a block diagram of an electronic device according to one or more embodiments; and

FIG. 38 is a schematic diagram of electronic devices according to various embodiments.

### DETAILED DESCRIPTION

The present disclosure will now be described more fully hereinafter with reference to the accompanying drawings, in which embodiments of the present disclosure are shown. The present disclosure may, however, be embodied in different forms and should not be construed as limited to embodiments set forth herein. Rather, these embodiments are provided so that the present disclosure will be thorough and complete, and will fully convey the scope of the present disclosure to those skilled in the art.

It will also be understood that when an element or a layer is referred to as being "on" another element or layer, it can be directly on the other element or layer, or intervening layers may also be present. The same reference numbers indicate the same components throughout the specification.

It will be understood that, although the terms "first," "second," etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Further, the phrase "in a plan view" means when an object portion is viewed from above, and the phrase "in a schematic cross-sectional view" means when a schematic cross-section taken by vertically cutting an object portion is viewed from the side. The terms "overlap" or "overlapped" mean that a first object may be above or below or to a side of a second object, and vice versa. Additionally, the term "overlap" may include layer, stack, face or facing, extending over, covering, or partly covering or any other suitable term as would be appreciated and understood by those of ordinary skill in the art. The expression "not overlap" may include meaning such as "apart from" or "set aside from" or "offset from" and any other suitable equivalents as would be appreciated and understood by those of ordinary skill in the art. The terms "face" and "facing" may mean that a first object may directly or indirectly oppose a second object. In a case in which a third object intervenes between a first and second object, the first and second objects may be understood as being indirectly opposed to one another, although still facing each other.

The spatially relative terms "below," "beneath," "lower," "above," "upper," and/or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned "below" or "beneath" another device may be placed "above" another device. Accordingly, the illustrative term "below" may include both the lower and upper positions. The device may also be oriented in other directions and thus the spatially relative terms may be interpreted differently depending on the orientations.

When an element is referred to as being "connected" or "coupled" to another element, the element may be "directly connected" or "directly coupled" to another element, or "electrically connected" or "electrically coupled" to another element with one or more intervening elements interposed therebetween. It will be further understood that when the terms "comprises," "comprising," "has," "have," "having," "includes" and/or "including" are used, they may specify the presence of stated features, integers, steps, operations, elements and/or components, but do not preclude the presence or addition of other features, integers, steps, operations, elements, components, and/or any combination thereof.

The terms "about" or "approximately" as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, "about" may mean within one or more standard deviations, or within ± 30%, 20%, 10%, 5% of the stated value.

In the specification and the claims, the term "and/or" is intended to include any combination of the terms "and" and "or" for the purpose of its meaning and interpretation. For example, "A and/or B" may be understood to mean "A, B, or A and B." The terms "and" and "or" may be used in the conjunctive or disjunctive sense and may be understood to be equivalent to "and/or." In the specification and the claims, the phrase "at least one of" is intended to include the meaning of "at least one selected from the group of" for the purpose of its meaning and interpretation. For example, "at least one of A and B" may be understood to mean "A, B, or A and B."

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Features of each of various embodiments of the present disclosure may be partially or entirely combined with each other and may technically variously interwork with each other, and respective embodiments may be implemented independently of each other or may be implemented together in association with each other.

Hereinafter, embodiments of the present disclosure are described with reference to the drawings.

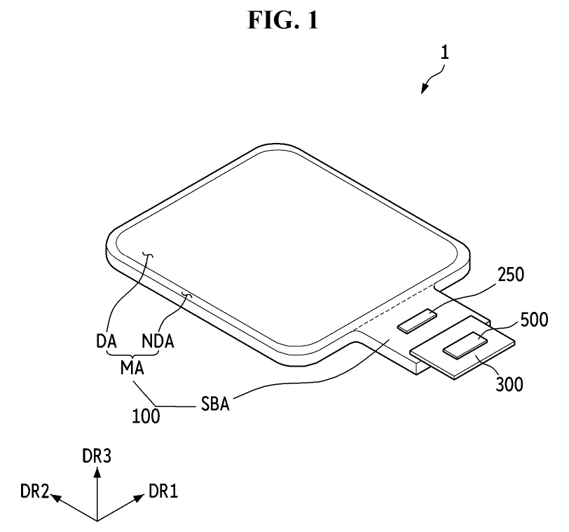

FIG. 1 is a perspective view illustrating a display device according to one or more embodiments.

Referring to FIG. 1, a display device 1 may be a device capable of providing an image, such as a moving image and/or a still image. For example, the display device 1 may be a device that includes a display module including a display panel 100 and thus may display an image. As an example, the display device 1 may refer to all electronic devices that provide a display screen on which an image may be displayed or include a display module for displaying an image. The display device 1 may be included in an electronic device that provides a display screen and may form the display screen of the electronic device.

For example, the display device 1 may be included in various electronic devices such as televisions, laptop computers, monitors, billboards and the Internet of Things (IOT) as well as portable electronic devices such as mobile phones, smart phones, tablet personal computers (tablet PCs), smart watches, watch phones, mobile communication terminals, electronic notebooks, electronic books, portable multimedia players (PMPs), navigation systems and ultra mobile PCs (UMPCs), and used as a display screen. In addition, the display device 1 may be included in other electronic devices such as a virtual reality (VR) device, an augmented reality (AR) device, and/or the like and used to display an image in the electronic device.

In FIG. 1, a display module, which is a main component of the display device 1, is illustrated. In one or more embodiments, the display device 1 (or an electronic device including a display module) may further include an additional component. For example, the display device 1 may further include a housing or a casing that accommodates the display module of FIG. 1.

In one or more embodiments, the display device 1 may be a light emitting display device such as an organic light emitting display using an organic light emitting diode (OLED), a quantum dot light emitting display including a quantum dot light emitting layer, an inorganic light emitting display including an inorganic semiconductor, and a micro or nano light emitting display using a micro or nano light emitting diode (LED). Hereinafter, as an example of the display device 1 to which embodiments may be applied, a micro or nano light emitting display including a micro or nano light emitting diode will be disclosed. However, the present disclosure is not limited thereto. For example, the type of light emitting element included in the display device 1 is not limited to a micro or nano light emitting diode, and the display device 1 may include a light emitting element of another type and/or shape. Further, the display device 1 according to embodiments is not limited to a light emitting display device, and the type and/or shape of the display device 1 may vary depending on embodiments.

The display device 1 may include a display panel 100, a display driving circuit 250, a circuit board 300, and a power supply unit 500. The display panel 100, the display driving circuit 250, the circuit board 300, and the power supply unit 500 may be included in the display module of the display device 1.

In one or more embodiments, the display panel 100 may have a substantially quadrilateral planar shape. For example, the display panel 100 may have a substantially quadrilateral shape on a plane defined by a first direction DR1 and a second direction DR2 intersecting each other. The corners of the display panel 100 may be rounded or may be right-angled. The planar shape of the display panel 100 is not limited to the rectangular shape, and may be formed in another polygonal shape, a circular shape or an elliptical shape. The display panel 100 may be substantially flat, but is not limited thereto. For example, the display panel 100 may include a curved portion in at least a part (e.g., left and right ends). In one or more embodiments, the display panel 100 may be formed to be flexible so that it can be curved, bent, folded, and/or rolled.

The display panel 100 may include a main region MA where an image is displayed. In one or more embodiments, the display panel 100 may further include a sub-region SBA.

The main region MA may include a display area DA for displaying an image and a non-display area NDA that is a peripheral area of the display area DA and disposed around the display area DA along an edge or a periphery of the display area DA. The display area DA may include pixels to display an image. Each of the pixels may include a plurality of sub-pixels. For example, each of the pixels may include a first sub-pixel that emits light of a first color, a second sub-pixel that emits light of a second color, and a third sub-pixel that emits light of a third color, but the present disclosure is not limited thereto.

The sub-region SBA may protrude from one side of the main region MA in the second direction DR2 (e.g., the longitudinal direction). Although FIG. 1 shows a state in which the sub-region SBA is unfolded, the sub-region SBA may be bent. When the sub-region SBA is bent, the sub-region SBA may overlap the main region MA in a third direction DR3, which is the thickness direction of the display panel 100, and may be located on the bottom surface of the display panel 100. The display driving circuit 250 may be arranged in the sub-region SBA.

The display driving circuit 250 may generate signals and voltages (for example, driving signals and driving voltages of the display panel 100) for driving the display panel 100. The display driving circuit 250 may be formed as an integrated circuit (IC) and attached onto the display panel 100 by a chip on glass (COG) method, a chip on plastic (COP) method, and/or an ultrasonic bonding method, but the present disclosure is not limited thereto. For example, the display driving circuit 250 may be attached onto the circuit board 300 by a chip on film (COF) method.

The circuit board 300 may be attached to one end of the sub-region SBA of the display panel 100, and may be electrically connected to the display panel 100 and the display driving circuit 250. The display panel 100 and the display driving circuit 250 may receive digital video data, timing signals, and driving voltages through the circuit board 300. The circuit board 300 may be a flexible printed circuit board (FPCB), a printed circuit board (PCB), or a flexible film such as a chip on film.

The power supply unit 500 may generate panel driving voltages according to a power voltage supplied from the outside. The power supply unit 500 may be formed as an integrated circuit (IC) and attached to the circuit board 300 by a COF method.

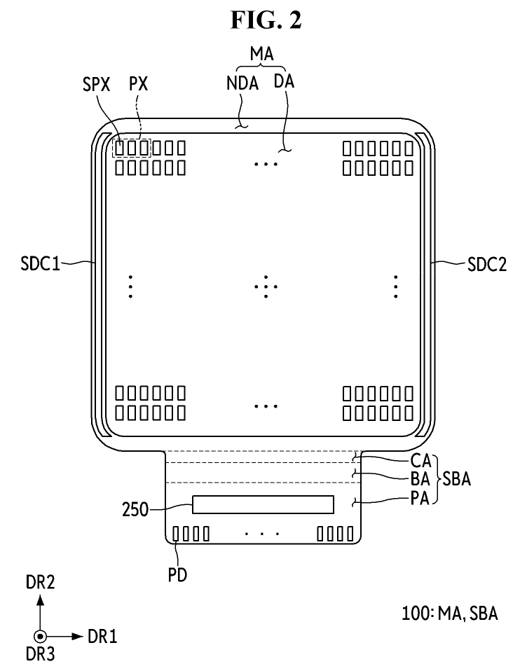

FIG. 2 is a plan view illustrating a display panel according to one or more embodiments. In FIG. 2, the sub-region SBA is illustrated in an unfolded state.

Referring to FIGS. 1 and 2, the display panel 100 may include the main region MA and the sub-region SBA.

The main region MA may include the display area DA and the non-display area NDA. The display area DA may occupy most of the main region MA.

The display area DA may include pixels PX for displaying an image. Each of the pixels PX may include a plurality of sub-pixels SPX. The pixel PX may be defined as a minimum unit sub-pixel group capable of expressing a white grayscale. For example, the pixel PX may include three sub-pixels SPX that emit light of different colors. However, the number, type, and/or ratio of the sub-pixels SPX included in each pixel PX may vary depending on embodiments.

The non-display area NDA may be located adjacent to the display area DA. For example, the non-display area NDA may surround the display area DA. The non-display area NDA may be an edge area of the display panel 100.

In one or more embodiments, a first scan driver SDC1 and a second scan driver SDC2 may be located in the non-display area NDA. The first scan driver SDC1 and the second scan driver SDC2 may be located on different sides of the display area DA. Each of the first scan driver SDC1 and the second scan driver SDC2 may be electrically connected to the display driving circuit 250 through a plurality of wires. Each of the first scan driver SDC1 and the second scan driver SDC2 may receive scan control signals inputted from the display driving circuit 250, generate scan signals in response to the scan control signals, and output the generated scan signals to scan lines.

Although FIG. 2 shows an embodiment in which the display device 1 (for example, the display panel 100) includes the first scan driver SDC1 and the second scan driver SDC2, the present disclosure is not limited thereto. For example, the number or location of the scan driver included in the display device 1 may vary depending on embodiments.

The sub-region SBA may protrude from one side of the main region MA in the second direction DR2 (e.g., the longitudinal direction). The length of the sub-region SBA in the second direction DR2 may be less than the length of the main region MA in the second direction DR2. The length of the sub-region SBA in the first direction DR1 may be less than or equal to the length of the main region MA in the first direction DR1. The sub-region SBA may be bent, so that at least a part of the sub-region SBA may overlap the main region MA in the third direction DR3. For example, a part of the sub-region SBA may be located under the main region MA.

The sub-region SBA may include a connection area CA, a pad area PA, and a bending area BA.

The connection area CA may be an area protruding from one side of the main region MA in the second direction DR2. One side of the connection area CA may be in contact with the non-display area NDA of the main region MA, and the other side of the connection area CA may be in contact with the bending area BA.

The pad area PA may be an area on which pads PD and the display driving circuit 250 are arranged. The display driving circuit 250 may be attached to driving pads of the pad area PA using a conductive adhesive member such as an anisotropic conductive film. The circuit board 300 may be attached to the pads PD of the pad area PA using a conductive adhesive member such as an anisotropic conductive film. One side of the pad area PA may be in contact with the bending area BA.

The bending area BA may be an area that can be bent. When the display panel 100 is bent in the bending area BA, the pad area PA may be located under the connection area CA and the main region MA. The bending area BA may be located between the connection area CA and the pad area PA. One side of the bending area BA may be in contact with the connection area CA, and the other side of the bending area BA may be in contact with the pad area PA.

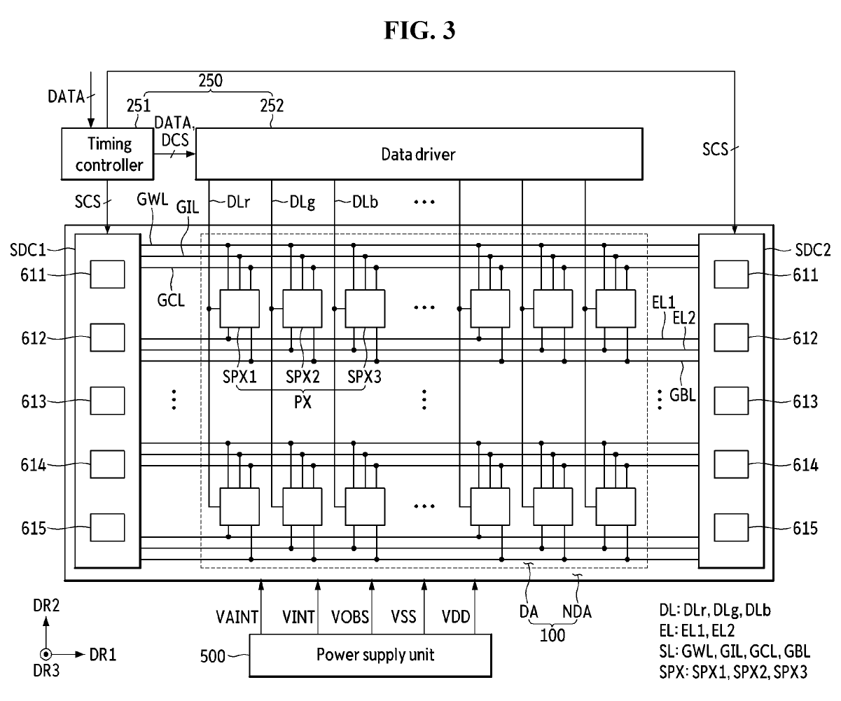

FIG. 3 is a block diagram illustrating a display device according to one or more embodiments.

Referring to FIG. 3, the display area DA may include pixels PX, scan lines SL, emission control lines EL, and data lines DL.

The pixels PX may be arranged along the first direction DR1 and the second direction DR2. For example, the pixels PX may be arranged in a matrix form along the first direction DR1 and the second direction DR2. For example, the pixels PX may be arranged along rows and columns of a matrix along the first direction DR1 and the second direction DR2. The scan lines SL and the emission control lines EL may extend in the first direction DR1 and may be arranged along the second direction DR2. The data lines DL may extend in the second direction DR2 and may be arranged along the first direction DR1. The scan lines SL may include write scan lines GWL, initialization scan lines GIL, control scan lines GCL, and bias scan lines GBL. The configuration of the scan lines SL may be different according to the structure or driving method of the pixels PX.

Each of the pixels PX may include a plurality of sub-pixels SPX. For example, each of the pixels PX may include a first sub-pixel SPX1, a second sub-pixel SPX2, and a third sub-pixel SPX3. The first sub-pixel SPX1, the second sub-pixel SPX2, and the third sub-pixel SPX3 may emit light of a first color, light of a second color, and light of a third color, respectively. The light of the first color, the light of the second color, and the light of the third color may be red light (for example, light in a red wavelength band having a main peak wavelength of about 600 nm to 750 nm), green light (for example, light in a green wavelength band having a main peak wavelength of about 480 nm to 560 nm), and blue light (for example, light in a blue wavelength band having a main peak wavelength of about 370 nm to 460 nm), respectively, but the present disclosure is not limited thereto. In one or more embodiments, the first sub-pixel SPX1, the second sub-pixel SPX2, and the third sub-pixel SPX3 of each of the pixels PX may be arranged along the first direction DR1. The number, type, arrangement structure, and/or emission wavelength of the sub-pixels SPX included in each of the pixels PX may vary depending on the embodiments.

Each of the sub-pixels SPX may be connected to one of the write scan lines GWL, one of the initialization scan lines GIL, one of the control scan lines GCL, one of the bias scan lines GBL, one of the emission control lines EL, and one of the data lines DL. In describing embodiments, “connection” may include “physical connection” and/or “electrical connection.”

Each of the plurality of sub-pixels SPX may receive the data voltage of the data line DL according to the write scan signal of the write scan line GWL. Each of the plurality of sub-pixels SPX may include a light emitting element that emits light with a luminance corresponding to the data voltage. The plurality of sub-pixels SPX included in each pixel PX may be connected to the different data lines DL. For example, the first sub-pixel SPX1, the second sub-pixel SPX2, and the third sub-pixel SPX3 may be respectively connected to a first data line DLr, a second data line DLg, and a third data line DLb. Accordingly, the luminance of each of the first sub-pixel SPX1, the second sub-pixel SPX2, and the third sub-pixel SPX3 may be controlled individually.

In one or more embodiments, each of the pixels PX may be connected to two or more emission control lines EL, and an emission period (or on-duty ratio) of at least two of the sub-pixels SPX included in each pixel PX may be controlled independently and/or individually by different emission control signals supplied to the different emission control lines EL. For example, in each horizontal line (e.g., each pixel row) of the display area DA, a first emission control line EL1 and a second emission control line EL2, which are connected to different sub-pixels SPX from among the sub-pixels SPX of the pixels PX arranged on the corresponding horizontal line, may be located. For example, the first emission control line EL1 may be connected to the first sub-pixels SPX1 of the pixels PX arranged on the corresponding horizontal line, and the second emission control line EL2 may be connected to the second sub-pixels SPX2 and the third sub-pixels SPX3 included in the pixels PX of the corresponding horizontal line.

The first sub-pixel SPX1 may emit light during a first emission period in response to a first emission control signal supplied through the first emission control line EL1. The first emission period may be a period during which a driving current may flow through the first sub-pixel SPX1 by the first emission control signal. The second sub-pixel SPX2 and the third sub-pixel SPX3 may emit light during a second emission period in response to a second emission control signal supplied through the second emission control line EL2. The second emission period may be a period during which a driving current may flow through the second sub-pixel SPX2 and the third sub-pixel SPX3 by the second emission control signal. The first emission period and the second emission period may be controlled independently or separately from each other.

In one or more embodiments, the duration of the first emission period may be different from the duration of the second emission period. For example, the duration of the first emission period may correspond to an on-duty ratio adjusted to allow the first sub-pixel SPX1 to emit light with a desired luminance according to a driving current optimized according to the luminous efficiency of the first sub-pixel SPX1 (e.g., a driving current in a range in which the light emitting element of the first sub-pixel SPX1 exhibits the optimal consumption efficiency). The duration of the second emission period may correspond to an on-duty ratio adjusted to allow the second sub-pixel SPX2 and the third sub-pixel SPX3 to emit light with a desired luminance according to a driving current optimized according to the luminous efficiency of the second sub-pixel SPX2 and the third sub-pixel SPX3 (e.g., a driving current in a range in which the light emitting elements of the second sub-pixel SPX2 and the third sub-pixel SPX3 exhibit the optimal consumption efficiency). In this case, an emission control signal output unit 615 included in the first scan driver SDC1 and the second scan driver SDC2 may output emission control signals having different pulse widths to the first emission control line EL1 and the second emission control line EL2.

However, the present disclosure is not limited thereto. For example, in another embodiment, the first sub-pixel SPX1, the second sub-pixel SPX2, and the third sub-pixel SPX3 included in one pixel PX may be commonly connected to one emission control line EL. For example, one emission control line EL may be located in one horizontal line, and the sub-pixels SPX located in the one horizontal line may be commonly connected to the one emission control line EL. In this case, the emission periods of the first sub-pixel SPX1, the second sub-pixel SPX2, and the third sub-pixel SPX3 may be controlled by the emission control signal supplied to the one emission control line EL.

The first scan driver SDC1, the second scan driver SDC2, and the display driving circuit 250 may be located in the non-display area NDA.

Each of the first scan driver SDC1 and the second scan driver SDC2 may be electrically connected to the pixels PX through the scan lines SL and the emission control lines EL. For example, each of the first scan driver SDC1 and the second scan driver SDC2 may be electrically connected to the sub-pixels SPX of each pixel PX through the write scan lines GWL, the initialization scan lines GIL, the control scan lines GCL, the bias scan lines GBL, and the emission control lines EL.

Each of the first scan driver SDC1 and the second scan driver SDC2 may include a write scan signal output unit 611, an initialization scan signal output unit 612, a control scan signal output unit 613, a bias scan signal output unit 614, and the emission control signal output unit 615. Each of the write scan signal output unit 611, the initialization scan signal output unit 612, the control scan signal output unit 613, the bias scan signal output unit 614, and the emission control signal output unit 615 may receive a scan timing control signal SCS from a timing controller 251.

The write scan signal output unit 611 may generate write scan signals in response to the scan timing control signal SCS and sequentially output them to the write scan lines GWL.

The initialization scan signal output unit 612 may generate initialization scan signals in response to the scan timing control signal SCS and sequentially output them to the initialization scan lines GIL.

The control scan signal output unit 613 may generate control scan signals in response to the scan timing control signal SCS and sequentially output them to the control scan lines GCL.

The bias scan signal output unit 614 may generate bias scan signals according to the scan timing control signal SCS and output them sequentially to the bias scan lines GBL.

The emission control signal output unit 615 may generate emission control signals according to the scan timing control signal SCS and sequentially output them to the emission control lines EL. In one or more embodiments, when the sub-pixels SPX of each horizontal line are divided and connected to the plurality of emission control lines EL (e.g., the first emission control line EL1 and the second emission control line EL2 of each horizontal line), the emission control signal output unit 615 may output each emission control signal to the plurality of emission control lines EL for each horizontal period.

The display driving circuit 250 may include the timing controller 251 and a data driver 252.

The data driver 252 may be electrically connected to the pixels PX through the data lines DL. For example, the data driver 252 may be electrically connected to the sub-pixels SPX of each pixel PX through the first data line DLr, the second data line DLg, and the third data line DLb.

The data driver 252 may receive the digital video data DATA and the data timing control signal DCS from the timing controller 251. The data driver 252 converts the digital video data DATA into analog data voltages in response to the data timing control signal DCS, and outputs them to the data lines DL. The sub-pixels SPX may be selected by the write scan signal of the first scan driver SDC1 and the second scan driver SDC2, and data voltages may be supplied to the selected sub-pixels SPX.

The timing controller 251 may receive digital video data DATA and timing signals from the outside. The timing controller 251 may generate the scan timing control signal SCS and the data timing control signal DCS for controlling the display panel 100 in response to the timing signals. The timing controller 251 may output the scan timing control signal SCS to the first scan driver SDC1 and the second scan driver SDC2. The timing controller 251 may output the digital video data DATA and the data timing control signal DCS to the data driver 252.

The power supply unit 500 may generate panel driving voltages according to a power voltage supplied from the outside. For example, the power supply unit 500 may generate and supply a first driving voltage VDD, a second driving voltage VSS, a third driving voltage VINT, a fourth driving voltage VAINT, and a fifth driving voltage VOBS to the display panel 100. The first driving voltage VDD, the second driving voltage VSS, the third driving voltage VINT, the fourth driving voltage VAINT, and the fifth driving voltage VOBS may be supplied to the sub-pixels SPX through respective power lines connected between the power supply unit 500 and the sub-pixels SPX, and may be used to drive the sub-pixels SPX. According to the structure or operation method of the sub-pixels SPX, the number and/or type of panel driving voltages outputted from the power supply unit 500 may be changed.

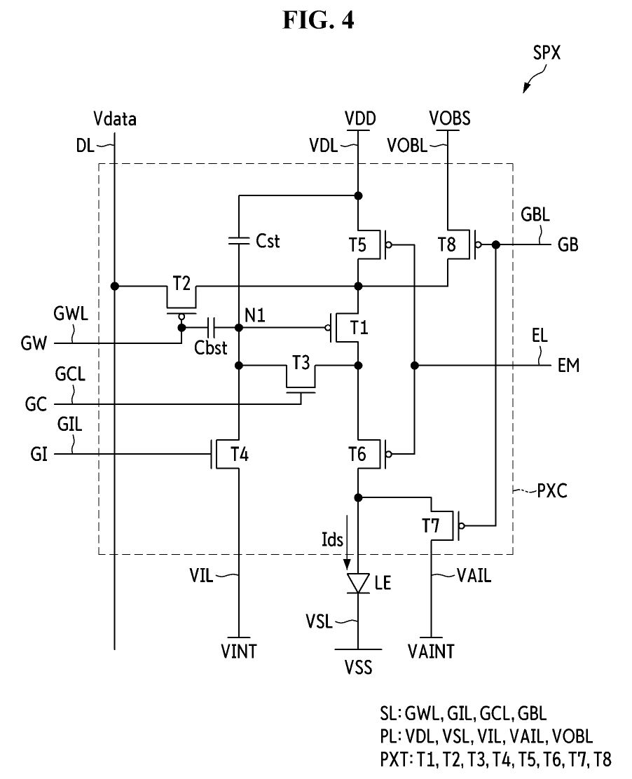

FIG. 4 is an equivalent circuit diagram illustrating a sub-pixel according to one or more embodiments. For example, FIG. 4 may be an equivalent circuit diagram showing one sub-pixel SPX from among the sub-pixels SPX of FIGS. 2 and 3. For example, the sub-pixel SPX of FIG. 4 may be the first sub-pixel SPX1, the second sub-pixel SPX2, or the third sub-pixel SPX3 of FIG. 3. In one or more embodiments, the circuit configurations of the sub-pixels SPX constituting each pixel PX may be substantially the same.

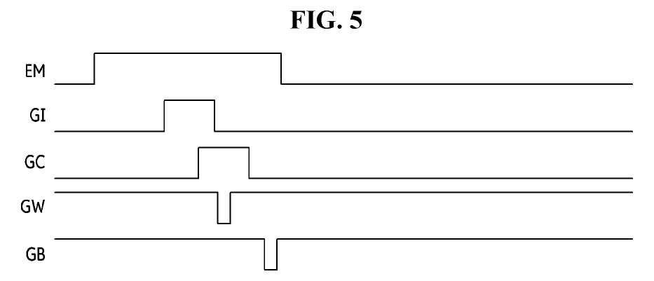

FIG. 5 is a waveform diagram showing driving signals of a sub-pixel according to one or more embodiments. For example, FIG. 5 shows a write scan signal GW, a control scan signal GC, an initialization scan signal GI, a bias scan signal GB and an emission control signal EM supplied to the scan lines SL and the emission control line EL of FIG. 4.

Referring to FIGS. 4 and 5 in addition to FIGS. 1 - 3, each of the sub-pixels SPX may include a pixel circuit PXC and a light emitting element LE electrically connected to the pixel circuit PXC.

The sub-pixel SPX may be connected to at least one scan driver through the scan lines SL and the emission control line EL. For example, the sub-pixel SPX may be connected to the first scan driver SDC1 and the second scan driver SDC2 through the write scan line GWL, the initialization scan line GIL, the control scan line GCL, the bias scan line GBL, and the emission control line EL. The first scan driver SDC1 and the second scan driver SDC2 may output the write scan signal GW, the initialization scan signal GI, the control scan signal GC, the bias scan signal GB, and the emission control signal EM to the write scan line GWL, the initialization scan line GIL, the control scan line GCL, the bias scan line GBL, and the emission control line EL, respectively.

When the sub-pixel SPX is the first sub-pixel SPX1, the sub-pixel SPX may be connected to the first emission control line EL1 located on the corresponding horizontal line, and may receive the emission control signal EM (also referred to as “first emission control signal”) from the first emission control line EL1. When the sub-pixel SPX is the second sub-pixel SPX2 or the third sub-pixel SPX3, the sub-pixel SPX may be connected to the second emission control line EL2 located on the corresponding horizontal line, and may receive the emission control signal EM (also referred to as “second emission control signal”) from the second emission control line EL2.

The sub-pixel SPX may be connected to the data driver 252 through the data line DL. The data driver 252 may output a data voltage Vdata corresponding to the image data of each frame to the data line DL.

When the sub-pixel SPX is the first sub-pixel SPX1, the sub-pixel SPX may be connected to the first data line DLr located in the corresponding pixel column. When the sub-pixel SPX is the second sub-pixel SPX2, the sub-pixel SPX may be connected to the second data line DLg located in the corresponding pixel column. When the sub-pixel SPX is the third sub-pixel SPX3, the sub-pixel SPX may be connected to the third data line DLb located in the corresponding pixel column.

The sub-pixel SPX may be connected to the power supply unit 500 through power lines PL. For example, the sub-pixel SPX may be connected to the power supply unit 500 through a first power line VDL, a second power line VSL, a third power line VIL, a fourth power line VAIL, and a fifth power line VOBL. The power supply unit 500 may supply the first driving voltage VDD, the second driving voltage VSS, the third driving voltage VINT, the fourth driving voltage VAINT, and the fifth driving voltage VOBS to the first power line VDL, the second power line VSL, the third power line VIL, the fourth power line VAIL, and the fifth power line VOBL, respectively. In one or more embodiments, the first driving voltage VDD, the second driving voltage VSS, the third driving voltage VINT, the fourth driving voltage VAINT, and the fifth driving voltage VOBS may be a high potential pixel voltage (e.g., an anode voltage), a low potential pixel voltage (e.g., a cathode voltage or common voltage), a first initialization voltage (e.g., a gate initialization voltage), a second initialization voltage (e.g., an anode initialization voltage), and a bias voltage, respectively.

The pixel circuit PXC may control a driving current Ids supplied to the light emitting element LE in response to the driving signals (e.g., the write scan signal GW, the initialization scan signal GI, the control scan signal GC, the bias scan signal GB, the emission control signal EM, and the data voltage Vdata) supplied to the sub-pixel SPX. The emission timing and luminance of the light emitting element LE may be controlled by the pixel circuit PXC.

The pixel circuit PXC may include pixel transistors PXT and a storage capacitor Cst. In one or more embodiments, the pixel circuit PXC may further include a boosting capacitor Cbst.

In one or more embodiments, the pixel transistors PXT may include first to eighth transistors T1 to T8. The first transistor T1 may be a driving transistor of the sub-pixel SPX. The second to eighth transistors T2 to T8 may be switching transistors of the sub-pixel SPX.

In one or more embodiments, the sub-pixel SPX may include different types of pixel transistors PXT. For example, the first, second, fifth, sixth, seventh, and eighth transistors T1, T2, T5, T6, T7, and T8 may be P-type transistors (e.g., P-type polycrystalline silicon transistors including active layers including polycrystalline silicon), and the third and fourth transistors T3 and T4 may be N-type transistors (e.g., N-type oxide transistors including active layers including an oxide semiconductor). In one embodiment, the active layers of P-type transistors (e.g., the active layers including polycrystalline silicon) and the active layers of N-type transistors (e.g., the active layers including an oxide semiconductor) may be located in different layers within the display panel 100 (e.g., a backplane layer of the display panel 100). However, the present disclosure is not limited thereto. For example, the pixel transistors PXT according to another embodiment may include active layers including the same semiconductor material, and may be formed as the same type transistors.

The first transistor T1 may be connected between the fifth transistor T5 and the sixth transistor T6. The first transistor T1 may be connected to the first power line VDL via the fifth transistor T5, and may be connected to the light emitting element LE via the sixth transistor T6. The gate electrode of the first transistor T1 may be connected to a first node N1. The first transistor T1 may control the driving current Ids flowing through the sub-pixel SPX according to the voltage of the first node N1 applied to the gate electrode of the first transistor T1 (for example, a voltage corresponding to the data voltage Vdata).

The second transistor T2 may be connected between the data line DL and the first electrode of the first transistor T1 (e.g., the source electrode of the first transistor T1 connected to the fifth transistor T5). The gate electrode of the second transistor T2 may be connected to the write scan line GWL. The second transistor T2 may be turned on by the write scan signal GW of a gate-on voltage (for example, a low level voltage at which the second transistor T2 can be turned on) supplied from the write scan line GWL. When the second transistor T2 is turned on, the data voltage Vdata supplied from the data line DL may be transmitted to the first electrode (e.g., the source electrode) of the first transistor T1.

The third transistor T3 may be connected between the second electrode of the first transistor T1 (e.g., the drain electrode of the first transistor T1 connected to the sixth transistor T6) and the first node N1. The gate electrode of the third transistor T3 may be connected to the control scan line GCL. The third transistor T3 may be turned on by the control scan signal GC of a gate-on voltage (e.g., a high level voltage at which the third transistor T3 can be turned on) supplied from the control scan line GCL to connect the gate electrode of the first transistor T1 to the second electrode of the first transistor T1. When the third transistor T3 is turned on, the first transistor T1 may be driven as a diode (e.g., the first transistor T1 may be diode-connected), and a voltage corresponding to the data voltage Vdata may be applied to the first node N1.

The fourth transistor T4 may be connected between the first node N1 and the third power line VIL. The gate electrode of the fourth transistor T4 may be connected to the initialization scan line GIL. The fourth transistor T4 may be turned on by the initialization scan signal GI of a gate-on voltage (e.g., a high level voltage at which the fourth transistor T4 can be turned on) supplied from the initialization scan line GIL to connect the first node N1 to the third power line VIL. When the fourth transistor T4 is turned on, the voltage of the first node N1 may be initialized to the third driving voltage VINT of the third power line VIL.

The fifth transistor T5 may be connected between the first power line VDL and the first electrode of the first transistor T1. The gate electrode of the fifth transistor T5 may be connected to the emission control line EL (e.g., the first emission control line EL1 or the second emission control line EL2 of FIG. 3). The fifth transistor T5 may be turned on by the emission control signal EM of a gate-on voltage (e.g., a low level voltage at which the fifth transistor T5 can be turned on) supplied from the emission control line EL to connect the first electrode of the first transistor T1 to the first power line VDL. When the fifth transistor T5 is turned on, the first power line VDL may be connected to the first electrode of the first transistor T1.

The sixth transistor T6 may be connected between the second electrode of the first transistor T1 and the light emitting element LE. The gate electrode of the sixth transistor T6 may be connected to the emission control line EL. The sixth transistor T6 may be turned on by the emission control signal EM of a gate-on voltage (e.g., a low level voltage at which the sixth transistor T6 can be turned on) supplied from the emission control line EL to connect the second electrode of the first transistor T1 to the light emitting element LE.

The seventh transistor T7 may be connected between the first electrode of the light emitting element LE (e.g., the anode electrode connected to the sixth transistor T6) and the fourth power line VAIL. The gate electrode of the seventh transistor T7 may be connected to the bias scan line GBL. The seventh transistor T7 may be turned on by the bias scan signal GB of a gate-on voltage (e.g., a low level voltage at which the seventh transistor T7 can be turned on) supplied from the bias scan line GBL to connect the first electrode of the light emitting element LE to the fourth power line VAIL. When the seventh transistor T7 is turned on, the voltage of the first electrode of the light emitting element LE may be initialized to the fourth driving voltage VAINT of the fourth power line VAIL.

The eighth transistor T8 may be connected between the fifth power line VOBL and the first electrode of the first transistor T1. The gate electrode of the eighth transistor T8 may be connected to the bias scan line GBL. The eighth transistor T8 may be turned on by the bias scan signal GB of a gate-on voltage (e.g., a low level voltage at which the eighth transistor T8 can be turned on) supplied from the bias scan line GBL to connect the first electrode of the first transistor T1 to the fifth power line VOBL. When the eighth transistor T8 is turned on, the voltage of the first electrode of the first transistor T1 may be initialized to the fifth driving voltage VOBS of the fifth power line VOBL. In one or more embodiments, the fifth driving voltage VOBS may be a bias voltage having a voltage level suitable for compensating the hysteresis characteristics of the first transistor T1.

The storage capacitor Cst may be connected between the first node N1 and the first power line VDL. The storage capacitor Cst may be charged with a voltage corresponding to the data voltage Vdata applied to the first node N1.

The boosting capacitor Cbst may be connected between the first node N1 and the write scan line GWL. The voltage of the first node N1 may be stabilized by the coupling effect of the boosting capacitor Cbst, thereby stabilizing the operation of the first transistor T1. The boosting capacitor Cbst may be formed by a parasitic capacitance formed between the first node N1 and the write scan line GWL, or may be designed separately.

The sub-pixel SPX may emit light during a partial period of each frame period, which corresponds to the on-duty ratio, and may not emit light during the remaining period. The emission period and non-emission period of the sub-pixel SPX may be controlled by the emission control signal EM.

A period during which the fifth transistor T5 and the sixth transistor T6 are turned off (e.g., a period during which the emission control signal EM of a high level is supplied to the sub-pixel SPX) may be a non-emission period of the sub-pixel SPX. The non-emission period of the sub-pixel SPX may include an initialization period for initializing a voltage of a specific node (e.g., the first node N1 and/or the like) of the sub-pixel SPX, and a data write and storage period for charging the storage capacitor Cst with a voltage corresponding to the data voltage Vdata. In one or more embodiments, the initialization scan signal GI, the control scan signal GC, the write scan signal GW, and the bias scan signal GB of a gate-on voltage may be supplied during the non-emission period of the sub-pixel SPX. In one or more embodiments, the initialization scan signal GI, the control scan signal GC, and the bias scan signal GB of the gate-on voltage may be sequentially supplied during the non-emission period of the sub-pixel SPX. The periods in which the initialization scan signal GI and the control scan signal GC of the gate-on voltage are supplied may overlap, but the present disclosure is not limited thereto. The write scan signal GW of the gate-on voltage may be supplied during the period when the control scan signal GC of the gate-on voltage is supplied.

The period during which the fifth transistor T5 and the sixth transistor T6 are turned on (e.g., the period during which the emission control signal EM of a low level is supplied to the sub-pixel SPX) may be an emission period of the sub-pixel SPX. During the emission period of the sub-pixel SPX, the first transistor T1 may supply the driving current Ids corresponding to the voltage of the first node N1 to the light emitting element LE.

The light emitting element LE may be connected between the pixel circuit PXC and the second power line VSL. For example, the first electrode (e.g., the anode electrode or pixel electrode) of the light emitting element LE may be connected to a node between the sixth transistor T6 and the seventh transistor T7, and the second electrode (e.g., the cathode electrode or common electrode) of the light emitting element LE may be connected to the second power line VSL. The light emitting element LE may emit light to correspond to the driving current Ids supplied from the pixel circuit PXC.

In one embodiment, the sub-pixel SPX may include a single light emitting element LE, but is not limited thereto. For example, the sub-pixel PX may include a plurality of light emitting elements LE.

In one or more embodiments, the light emitting element LE may be a micro light emitting diode including an inorganic compound such as a nitride-based or phosphide-based semiconductor material, but is not limited thereto. For example, the light emitting element LE may be an organic light emitting element, a quantum dot light emitting element, or another type of light emitting element. In addition, the size or shape of the light emitting element LE may be different according to one or more embodiments.

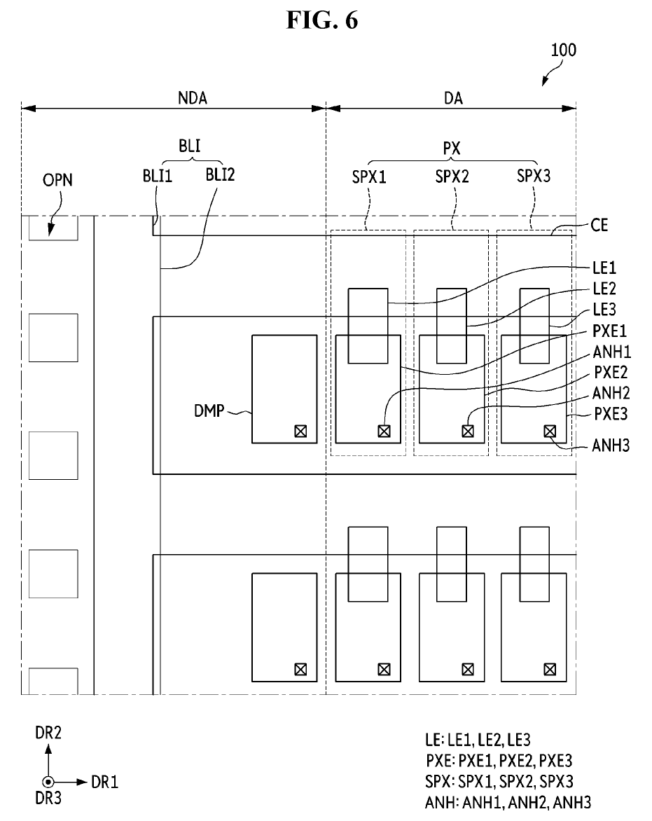

FIG. 6 is a plan view illustrating a display panel according to another embodiment. For example, FIG. 6 shows a part of the display area DA where two pixels PX are sequentially located in the second direction DR2, and a part of the non-display area NDA adjacent to a part of the display area DA and where a power bus line BLI is located.

FIG. 6 shows one embodiment of a light emitting element layer including light emitting elements LE of sub-pixels SPX. The display panel 100 may further include a backplane layer including circuit elements of the sub-pixels SPX (for example, circuit elements included in each of the pixel circuits PXC of the sub-pixels SPX.

Referring to FIG. 6, each of the sub-pixels SPX may include the pixel electrode PXE, and the light emitting element LE located on the pixel electrode PXE. In one or more embodiments, when the light emitting element LE is a micro LED of a flip-chip type or a lateral type, each of the sub-pixels SPX may further include a common electrode CE located on one surface (for example, a bottom surface or a top surface) of the light emitting element LE together with the pixel electrode PXE. In another embodiment, when the light emitting element LE is a micro LED of a vertical type, the light emitting element LE of each of the sub-pixels SPX may be located on the pixel electrode PXE, and the common electrode CE (for example, the common electrode CE located as a common layer in the entire display area DA) may be located on the light emitting elements LE of the sub-pixels SPX. FIG. 6 shows the display panel 100 including the light emitting elements LE of a flip-chip type. The pixel electrode PXE may also be referred to as the anode electrode or the first electrode, and the common electrode CE may also be referred to as the cathode electrode or the second electrode.

In one or more embodiments, the sub-pixels SPX of each pixel PX may be arranged along the first direction DR1 and may share one common electrode CE. For example, the common electrode CE may extend in the first direction DR1 in each pixel row (or horizontal line) of the display area DA, and the sub-pixels SPX of the pixels PX located on the corresponding pixel row may share one common electrode CE.

In one or more embodiments, the sub-pixels SPX of the display area DA may be aligned in a stripe form. For example, in each pixel column including pixels PX arranged along the second direction DR2 in the display area DA, the first sub-pixels SPX1 may be arranged sequentially or continuously along the second direction DR2. In addition, the second sub-pixels SPX2 included in each pixel column may be arranged sequentially or continuously along the second direction DR2, and the third sub-pixels SPX3 included in each pixel column may be arranged sequentially or continuously along the second direction DR2. However, the present disclosure is not limited thereto, and the arrangement shape of the pixels PX and/or the sub-pixels SPX may be variously modified.

The first sub-pixel SPX1 may include a first pixel electrode PXE1 and the common electrode CE (or a part of the common electrode CE) spaced (e.g., spaced apart) from each other, and a first light emitting element LE1 located on the first pixel electrode PXE1 and the common electrode CE. The first light emitting element LE1 may refer to the light emitting element LE of the first sub-pixel SPX1. The first light emitting element LE1 may be electrically connected between the first pixel electrode PXE1 and the common electrode CE.

The second sub-pixel SPX2 may include a second pixel electrode PXE2 and the common electrode CE spaced (e.g., spaced apart) from each other, and a second light emitting element LE2 located on the second pixel electrode PXE2 and the common electrode CE. The second light emitting element LE2 may refer to the light emitting element LE of the second sub-pixel SPX2. The second light emitting element LE2 may be electrically connected between the second pixel electrode PXE2 and the common electrode CE.

The third sub-pixel SPX3 may include a third pixel electrode PXE3 and the common electrode CE spaced (e.g., spaced apart) from each other, and a third light emitting element LE3 located on the third pixel electrode PXE3 and the common electrode CE. The third light emitting element LE3 may refer to the light emitting element LE of the third sub-pixel SPX3. The third light emitting element LE3 may be electrically connected between the third pixel electrode PXE3 and the common electrode CE.

In one or more embodiments, the first pixel electrode PXE1, the second pixel electrode PXE2, and the third pixel electrode PXE3 of each pixel PX may be sequentially arranged along the first direction DR1, and may be spaced (e.g., spaced apart) from the common electrode CE in the second direction DR2. The first pixel electrode PXE1, the second pixel electrode PXE2, and the third pixel electrode PXE3 may face different parts of the common electrode CE in the second direction DR2. In another embodiment, when the sub-pixels SPX include a micro LED of a vertical type, the first pixel electrode PXE1, the second pixel electrode PXE2, and the third pixel electrode PXE3 may face the common electrode CE in the third direction DR3.

The pixel circuit PXC (see FIG. 4) and the pixel electrode PXE of each of the sub-pixels SPX may be electrically connected to each other through an anode contact hole ANH (or a first contact hole). For example, the first pixel electrode PXE1 of the first sub-pixel SPX1 may be electrically connected to at least one circuit element (for example, the sixth and seventh transistors T6 and T7 of FIG. 4) included in the pixel circuit PXC of the first sub-pixel SPX1 through a first anode contact hole ANH1 and/or at least one connection pattern. Similarly, the second pixel electrode PXE2 of the second sub-pixel SPX2 may be electrically connected to at least one circuit element included in the pixel circuit PXC of the second sub-pixel SPX2 through a second anode contact hole ANH2 and/or at least one connection pattern, and the third pixel electrode PXE3 of the third sub-pixel SPX3 may be electrically connected to at least one circuit element included in the pixel circuit PXC of the third sub-pixel SPX3 through a third anode contact hole ANH3 and/or at least one connection pattern.

The light emitting elements LE may be located between the respective pixel electrodes PXE and the common electrode CE. For example, the first light emitting element LE1 may be located on the first pixel electrode PXE1 and the common electrode CE, and a part of the first light emitting element LE1 may overlap the first pixel electrode PXE1 and another part of the first light emitting element LE1 may overlap the common electrode CE. The second light emitting element LE2 may be located on the second pixel electrode PXE2 and the common electrode CE, and a part of the second light emitting element LE2 may overlap the second pixel electrode PXE2 and another part of the second light emitting element LE2 may overlap the common electrode CE. The third light emitting element LE3 may be located on the third pixel electrode PXE3 and the common electrode CE, and a part of the third light emitting element LE3 may overlap the third pixel electrode PXE3 and another part of the third light emitting element LE3 may overlap the common electrode CE.

Each of the light emitting elements LE may emit light of a specific color (for example, red light, green light, blue light, or white light). In one or more embodiments, the first light emitting element LE1, the second light emitting element LE2, and the third light emitting element LE3 may emit light of different colors. For example, the first light emitting element LE1, the second light emitting element LE2, and the third light emitting element LE3 may emit light of a first color (for example, red light), light of a second color (for example, green light), and light of a third color (for example, blue light), respectively.

In one or more embodiments, the light emitting elements LE of at least two sub-pixels SPX may have different sizes. For example, the size of the first light emitting element LE1 may be larger than the size of each of the second light emitting element LE2 and the third light emitting element LE3. The sizes of the second light emitting element LE2 and the third light emitting element LE3 may be the same (e.g., may be substantially the same) or different.

In one or more embodiments, the light emitting elements LE may have a differentiated or optimized size depending on the luminous efficiency of the light emitting elements LE and/or the like. For example, depending on the luminous efficiency of each of the first light emitting element LE1, the second light emitting element LE2, and the third light emitting element LE3, at least two light emitting elements LE from among the first light emitting element LE1, the second light emitting element LE2, and the third light emitting element LE3 may have different sizes. For example, when the luminous efficiency of the first light emitting element LE1 is less than the luminous efficiency of each of the second light emitting element LE2 and the third light emitting element LE3 based on the same size and shape, the size of the first light emitting element LE1 may be larger than the size of each of the second light emitting element LE2 and the third light emitting element LE3. Accordingly, the luminous efficiency of the first light emitting element LE1 may be improved, and the luminous efficiency deviation of the first light emitting element LE1, the second light emitting element LE2, and the third light emitting element LE3 may be reduced or prevented.

In one or more embodiments, the first light emitting element LE1, the second light emitting element LE2, and the third light emitting element LE3 may emit light of the same color. In this case, a color filter and/or a light conversion layer (for example, light conversion layer including wavelength conversion particles such as quantum dots and/or the like) for converting light emitted from the light emitting element LE of the corresponding sub-pixel SPX to light corresponding to the emission color of the corresponding sub-pixel SPX may be located on at least one light emitting element LE of the first sub-pixel SPX1, the second sub-pixel SPX2, and the third sub-pixel SPX3. When the first light emitting element LE1, the second light emitting element LE2, and the third light emitting element LE3 emit light of the same color, the first light emitting element LE1, the second light emitting element LE2, and the third light emitting element LE3 may have the same size (e.g., may have substantially the same size) or different sizes. For example, depending on the light conversion efficiency by the light conversion layer, at least one of the size of the light emitting elements LE of the sub-pixels SPX or the area of the emission areas EA of the sub-pixels SPX may be differentiated.

The common electrode CE may be electrically connected to the power bus line BLI (for example, cathode bus line) to which the second driving voltage VSS is applied. In one or more embodiments, the common electrode CE may extend to the non-display area NDA around the display area DA, and may be electrically connected to the power bus line BLI in the non-display area NDA. The common electrode CE may be electrically connected to the power bus line BLI through at least one contact hole and/or connection line, or may be integrally formed with at least a part of the power bus line BLI. For example, the power bus line BLI may include a plurality of wiring layers, and one of the plurality of wiring layers and the common electrode CE may be formed as substantially one pattern.

In one or more embodiments, the second power line VSL (see FIG. 4) to which the second driving voltage VSS is applied may be also located in the display area DA. For example, the second power line VSL crossing or overlapping the common electrode CE may be located in the backplane layer located under the common electrode CE. In this case, the common electrode CE may be electrically connected to the second power line VSL through at least one contact hole and/or connection line in the display area DA.

The power bus line BLI may be located in the non-display area NDA, and may be located on at least one side of the display area DA. For example, the power bus line BLI may be located on the left side and the right side of the display area DA, and may be further selectively located on at least one of the upper side or the lower side of the display area DA. In FIG. 6, a part of the power bus line BLI located on the left side of the display area DA is illustrated.

The power bus line BLI may be electrically connected to the power supply unit 500 (see FIG. 3). For example, the power bus line BLI may be electrically connected to the power supply unit 500 through at least one pad PD and/or at least one connection line located in the sub-region SBA and/or the non-display area NDA of the main region MA (e.g., see FIG. 2). Accordingly, the second driving voltage VSS outputted from the power supply unit 500 may be applied to the power bus line BLI. The power bus line BLI may form a part of the second power line VSL electrically connected between the power supply unit 500 and the sub-pixels SPX. In addition to the embodiments described above, the connection structure between the common electrode CE and the second power line VSL may be variously changed.

In one or more embodiments, the power bus line BLI may be formed as multiple layers including the first wiring layer BLI1 and the second wiring layer BLI2. The first wiring layer BLI1 and the second wiring layer BLI2 may be electrically connected to each other.

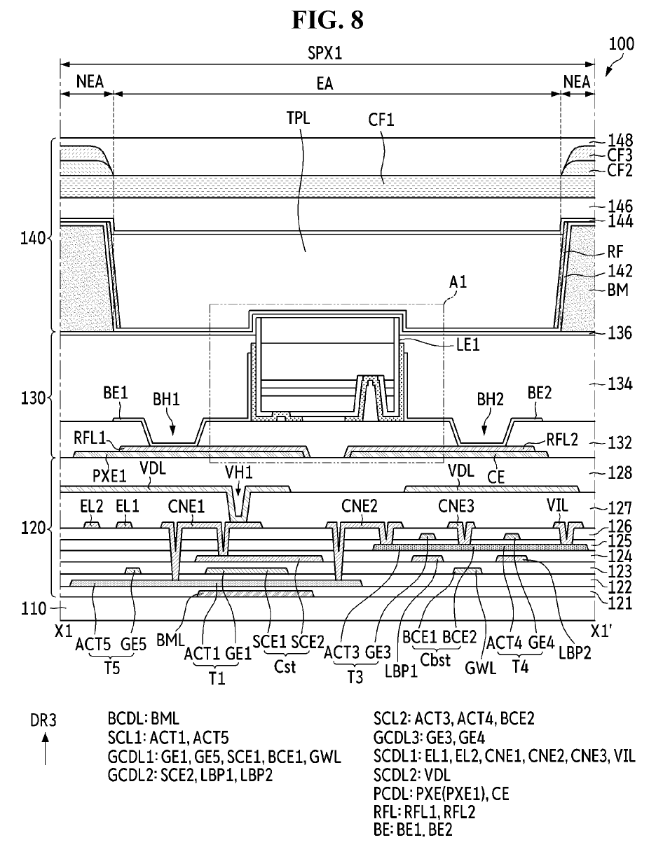

In one or more embodiments, the power bus line BLI may further include at least one wiring layer located inside the backplane layer. For example, the power bus line BLI may further include a third wiring layer located below the second wiring layer BLI2. The third wiring layer may be located in at least one conductive layer (e.g., the second source-drain conductive layer SCDL2 (see FIG. 8)) included in the backplane layer, and the end portion of the third wiring layer may be covered by at least one insulating layer (e.g., the seventh insulating layer 128 (see FIG. 8)). The at least one insulating layer may be open in an area overlapping the second wiring layer BLI2 (or the first wiring layer BLI1) and the third wiring layer, and thus, may be in contact and/or connected to the second wiring layer BLI2 and the third wiring layer. In a case where the power bus line BLI does not include the second wiring layer BLI2, the third wiring layer may be in direct contact and/or may be connected to the first wiring layer BLI1.

The first wiring layer BLI1 may be located in (e.g., at) the same layer as the pixel electrodes PXE and the common electrode CE, and may include a conductive material included in the pixel electrodes PXE and the common electrode CE. In one or more embodiments, the first wiring layer BLI1 may be integrally formed with the common electrode CE. For example, at least one end of the common electrode CE may extend to the non-display area NDA, and may be connected to the first wiring layer BLI1 of the power bus line BLI.

The second wiring layer BLI2 may overlap at least a part of the first wiring layer BLI1 (e.g., the second wiring layer BLI2 may overlap at least a part of the first wiring layer BLI1 in the third direction DR3). In one or more embodiments, the second wiring layer BLI2 may be located under the first wiring layer BLI1, and may be in contact with and/or connected to the first wiring layer BLI1.

In one or more embodiments, the second wiring layer BLI2 may have a width greater than that of the first wiring layer BLI1 in the first direction DR1. For example, the second wiring layer BLI2 may extend further toward the outer edge of the display panel 100 from a portion overlapping the first wiring layer BLI1, and may cover the scan driver (for example, the first scan driver SDC1 and the second scan driver SDC2 of FIGS. 2 and 3). In one or more embodiments, the second wiring layer BLI2 may include a plurality of openings OPN. Accordingly, gas generated by outgassing in the display panel 100 may be appropriately discharged.

In one or more embodiments, dummy patterns DMP may be further located in the non-display area NDA. For example, the dummy patterns DMP may have a shape and/or size corresponding to those of the pixel electrodes PXE, and may be located around the pixel electrodes PXE located at the outermost edge of the display area DA. In one or more embodiments, dummy pixel circuits connected to the respective dummy patterns DMP may be located under the dummy patterns DMP. The dummy patterns DMP, and/or the dummy pixel circuits may be omitted.

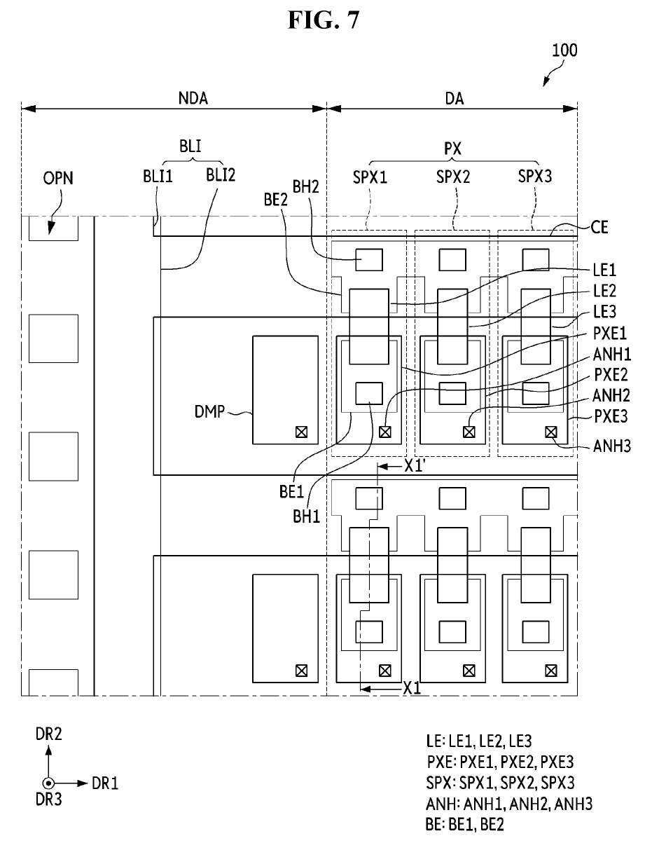

FIG. 7 is a plan view illustrating a display panel according to one or more embodiments. In comparison with FIG. 6, FIG. 7 shows the display panel 100 further including connection electrodes BE. In describing the following embodiments, components substantially identical or similar to those of at least one embodiment described above are designated with the same reference numerals, and redundant descriptions will be omitted.

Referring to FIGS. 6 and 7, the display panel 100 may further include the connection electrodes BE located in the sub-pixels SPX. For example, each sub-pixel SPX may include a first connection electrode BE1 located on the pixel electrode PXE, and a second connection electrode BE2 located on the common electrode CE.

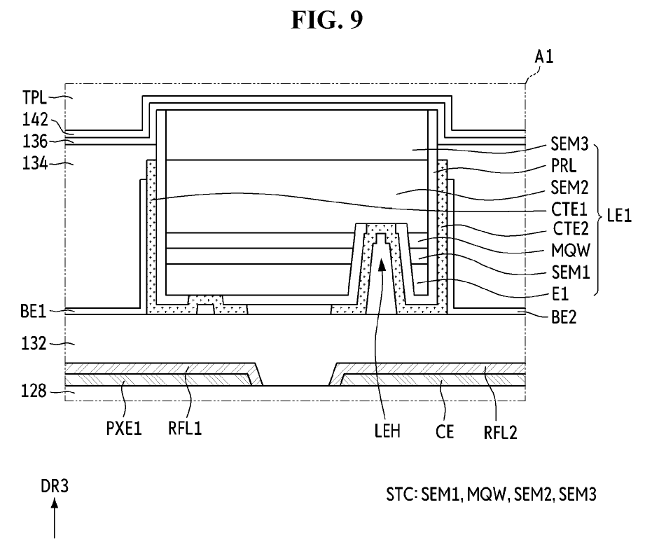

The first connection electrode BE1 may connect the pixel electrode PXE to the light emitting element LE. For example, in each sub-pixel SPX, the first connection electrode BE1 may be electrically connected to the pixel electrode PXE (or a first reflective layer RFL1 (see FIG. 8) connected to the pixel electrode PXE) through a first connection hole BH1. The first connection hole BH1 may be an opening formed in an insulating layer or an adhesive layer located between the pixel electrode PXE and the light emitting element LE. Further, the first connection electrode BE1 may be in contact with a part of the light emitting element LE (for example, the first contact electrode CTE1 (see FIG. 9) of the light emitting element LE) and may be electrically connected to the light emitting element LE.

The second connection electrode BE2 may connect the common electrode CE to the light emitting element LE. For example, in each sub-pixel SPX, the second connection electrode BE2 may be electrically connected to the common electrode CE (or a second reflective layer RFL2 (see FIG. 8) connected to the common electrode CE) through a second connection hole BH2. The second connection hole BH2 may be an opening formed in an insulating layer or an adhesive layer located between the common electrode CE and the light emitting element LE. Further, the second connection electrode BE2 may be in contact with another part of the light emitting element LE (for example, the second contact electrode CTE2 (see FIG. 9) of the light emitting element LE) located on the common electrode CE and may be electrically connected to the light emitting element LE.

In one or more embodiments, as illustrated in FIG. 7, the second connection electrodes BE2 of the sub-pixels SPX located in one pixel PX or one horizontal line may be integrally formed as substantially one pattern, but the present disclosure is not limited thereto. For example, in another embodiment, the second connection electrodes BE2 of the sub-pixels SPX may be formed to be separated from each other in each of the sub-pixel areas. The shapes and sizes of the connection electrodes BE may be variously formed according to one or more embodiments.

In addition, although the embodiment in which the first connection electrode BE1 and the pixel electrode PXE are electrically connected through the first connection hole BH1, and the second connection electrode BE2 and the common electrode CE are electrically connected through the second connection hole BH2 is illustrated in FIG. 7, the present disclosure is not limited thereto. For example, in another embodiment, the insulating layer or the adhesive layer on the pixel electrode PXE and the common electrode CE may partially cover the pixel electrode PXE and the common electrode CE only under the light emitting element LE and/or directly around the light emitting element LE, and may not be located on other parts of the pixel electrode PXE and the common electrode CE. In this case, the first connection hole BH1 and the second connection hole BH2 may be omitted, and the first connection electrode BE1 and the second connection electrode BE2 may be directly located on other parts of the pixel electrode PXE and the common electrode CE, respectively, to be electrically connected to the pixel electrode PXE and the common electrode CE, respectively.

In one or more embodiments, the display panel 100 may further include a configuration or an additional electrode located in the light emitting element layer. For example, the display panel 100 may further include a reflective layer RFL (see FIG. 8) located beneath the light emitting elements LE.

FIG. 8 is a cross-sectional view showing a display panel according to one or more embodiments. For example, FIG. 8 shows an embodiment of a cross-section in respect to a portion of the display panel 100 corresponding to the line X1-X1’ of FIG. 7.

FIG. 9 is a cross-sectional view showing an area A1 of FIG. 8 in detail. For example, FIG. 9 shows an example of the first light emitting element LE1 included in the first sub-pixel SPX1. In one or more embodiments, the first light emitting element LE1, the second light emitting element LE2, and the third light emitting element LE3 of each of the first sub-pixel SPX1, the second sub-pixel SPX2, and the third sub-pixel SPX3 may have substantially the same or similar cross-sections.

Referring to FIGS. 8 and 9 in addition to FIGS. 1 - 7, the display panel 100 may include a substrate 110, and a backplane layer 120 and a light emitting element layer 130 located on the substrate 110. In one or more embodiments, the display panel 100 may further include an optical layer 140 located on the light emitting element layer 130. The backplane layer 120, the light emitting element layer 130, and the optical layer 140 may be sequentially located on the substrate 110 along the third direction DR3.

The substrate 110 may include an insulating material such as glass and/or polymer resin. When the substrate 110 includes polymer resin, it may be a flexible substrate that can be stretched.

The substrate 110 may include the display area DA and the non-display area NDA. The display area DA may include the emission areas EA of the sub-pixels SPX. Each emission area EA may include a light emitting element area where the light emitting element LE of each sub-pixel SPX is located. The display area DA may further include a non-emission area NEA located at the periphery of the emission areas EA. The non-emission area NEA may surround the emission areas EA.

The backplane layer 120 may include circuit elements included in the pixel circuits PXC of the sub-pixels SPX and wires connected to the sub-pixels SPX. In one or more embodiments, the backplane layer 120 may be formed entirely on one surface of the substrate 110.

The backplane layer 120 may include at least one semiconductor layer, conductive layers, and/or insulating layers. In one or more embodiments, when the pixel circuits PXC include at least two types of pixel transistors PXT including different materials, the backplane layer 120 may include a plurality of semiconductor layers.

For example, the backplane layer 120 may include a lower conductive layer BCDL, a barrier layer 121 (or a buffer layer), the first semiconductor layer SCL1 (e.g., a polycrystalline silicon semiconductor layer), a first insulating layer 122 (e.g., a first inorganic insulating layer), the first gate conductive layer GCDL1 (or a first conductive layer), a second insulating layer 123 (e.g., a second inorganic insulating layer), the second gate conductive layer GCDL2 (or a second conductive layer), a third insulating layer 124 (e.g., a third inorganic insulating layer), the second semiconductor layer SCL2 (e.g., an oxide semiconductor layer), a fourth insulating layer 125 (e.g., a fourth inorganic insulating layer), the third gate conductive layer GCDL3 (or a third conductive layer), a fifth insulating layer 126 (e.g., a fifth inorganic insulating layer), the first source-drain conductive layer SCDL1 (or a fourth conductive layer), a sixth insulating layer 127 (e.g., a first organic insulating layer), the second source-drain conductive layer SCDL2 (or a fifth conductive layer), and a seventh insulating layer 128 (e.g., a second organic insulating layer) that are sequentially located on the substrate 110 along the third direction DR3.

The lower conductive layer BCDL may include a lower conductive pattern BML located below the first transistor T1. The lower conductive pattern BML may entirely or partially cover the bottom surface of the first active layer ACT1 included in the first transistor T1. For example, the lower conductive pattern BML may be located below the first active layer ACT1 to overlap a channel region (e.g., a portion of the first active layer ACT1 overlapping the first gate electrode GE1) of the first active layer ACT1. In one or more embodiments, the lower conductive layer BCDL may include a light blocking material. For example, the lower conductive layer BCDL may include metal, and the lower conductive pattern BML may be formed as a lower metal pattern. Accordingly, light may be prevented from being incident on the channel region of the first active layer ACT1 from the bottom of the first active layer ACT1, the operating characteristics of the first transistor T1 may be stabilized.

The barrier layer 121 may be located on the lower conductive layer BCDL. The barrier layer 121 may protect the circuit elements of the backplane layer 120 and the light emitting elements LE on the backplane layer 120 from moisture permeating through the substrate 110 that is susceptible to moisture permeation. In one or more embodiments, the barrier layer 121 may be formed as a plurality of inorganic insulating layers.

The circuit elements of the backplane layer 120 may be located on the barrier layer 121. For example, the pixel transistors PXT, the storage capacitor Cst, and the boosting capacitor Cbst included in the pixel circuit PXC of each of the sub-pixels SPX may be located on the barrier layer 121. Additionally, wires of the backplane layer 120 may be located on the barrier layer 121. For example, signal lines and power lines electrically connected to the sub-pixels SPX may be located on the barrier layer 121.

FIG. 8 shows, as an example of the circuit elements included in the backplane layer 120, the first transistor T1, the third transistor T3, the fourth transistor T4, the fifth transistor T5, the storage capacitor Cst, and the boosting capacitor Cbst that are included in the first sub-pixel SPX1. Further, FIG. 8 shows, as an example of wires included in the backplane layer 120, the write scan line GWL, the first and second emission control lines EL1 and EL2, the first power line VDL, and the third power line VIL. Each of other wires may include at least one wiring layer included in at least one conductive layer included in the backplane layer 120, and may be formed as a single-layer or multi-layer wire.

In one or more embodiments, each of the pixel circuits PXC may include first type transistors and second type transistors. The first type transistors and the second type transistors may be located in different layers within the backplane layer 120. For example, as shown in FIG. 4, each of the pixel circuits PXC may include the first, second, fifth, sixth, seventh, and eighth P-type transistors T1, T2, T5, T6, T7, and T8 and the third and fourth N-type transistors T3 and T4. The active layers included in the first, second, fifth, sixth, seventh, and eighth transistors T1, T2, T5, T6, T7, and T8 and the active layers included in the third and fourth transistors T3 and T4 may be formed in patterns of different semiconductor layers. Further, the gate electrodes included in the first, second, fifth, sixth, seventh, and eighth transistors T1, T2, T5, T6, T7, and T8 and the gate electrodes included in the third and fourth transistors T3 and T4 may be formed in patterns of different conductive layers.

The first semiconductor layer SCL1 (also referred to as “first semiconductor pattern layer”) may be located on the barrier layer 121. The first semiconductor layer SCL1 may include an active layer of each of the first type transistors. For example, the first semiconductor layer SCL1 may include the first active layer ACT1 included in the first transistor T1, a fifth active layer ACT5 included in the fifth transistor T5, and second, sixth, seventh, and eighth active layers included in the second, sixth, seventh, and eighth transistors T2, T6, T7, and T8. In one or more embodiments, the patterns (for example, the first and fifth active layers ACT1 and ACT5 and the second, sixth, seventh, and eighth active layers of each sub-pixel SPX) of the first semiconductor layer SCL1 included in one sub-pixel SPX may be formed integrally, but the present disclosure is not limited thereto.

The patterns of the first semiconductor layer SCL1 may include a first semiconductor material. In one or more embodiments, the first semiconductor material may be polycrystalline silicon (e.g., low temperature polycrystalline silicon), but is not limited thereto. For example, the first semiconductor material may be an oxide semiconductor (e.g., at least one of zinc oxide (ZnO), zinc-tin oxide (ZTO), indium-zinc oxide (IZO), indium oxide (InO), titanium oxide (TiO), indium-gallium oxide (IGO), indium-gallium-zinc oxide (IGZO), indium-gallium-tin oxide (IGTO), indium-zinc-tin oxide (IZTO), or indium-tin-gallium-zinc oxide (ITGZO), or another oxide semiconductor) or monocrystalline silicon.

The first insulating layer 122 may be located on the first semiconductor layer SCL1 and the barrier layer 121. The first insulating layer 122 may include at least one insulating material (e.g., silicon nitride (SiNx), silicon oxide (SiOx), silicon oxynitride (SiON), titanium oxide (TiOx), aluminum oxide (AlOx), or another inorganic insulating material) and may be formed as a single-layer or multi-layers.

The first gate conductive layer GCDL1 may be located on the first insulating layer 122. The first gate conductive layer GCDL1 may include a gate electrode of each of the first type transistors. For example, the first gate conductive layer GCDL1 may include the first gate electrode GE1 included in the first transistor T1, a fifth gate electrode GE5 included in the fifth transistor T5, and second, sixth, seventh, and eighth gate electrodes included in the second, sixth, seventh, and eighth transistors T2, T6, T7, and T8.

The first gate conductive layer GCDL1 may further include at least one conductive pattern and/or wire. For example, the first gate conductive layer GCDL1 may further include a first capacitor electrode SCE1 of the storage capacitor Cst, a first electrode BCE1 of the boosting capacitor Cbst, and the write scan line GWL. In one or more embodiments, the first gate electrode GE1 of each pixel circuit PXC and the first capacitor electrode SCE1 of the storage capacitor Cst may be formed integrally, and the first electrode BCE1 of the boosting capacitor Cbst of each pixel circuit PXC and the write scan line GWL connected to the pixel circuit PXC may be formed integrally. In one or more embodiments, the first gate conductive layer GCDL1 may further include the bias scan line GBL of FIG. 4.

The second insulating layer 123 may be located on the first gate conductive layer GCDL1 and the first insulating layer 122. The second insulating layer 123 may include at least one insulating material (e.g., an inorganic insulating material) and may be formed as a single layer or multiple layers.

The second gate conductive layer GCDL2 may be located on the second insulating layer 123. The second gate conductive layer GCDL2 may include the second capacitor electrode SCE2 of the storage capacitor Cst. The first capacitor electrode SCE1 and the second capacitor electrode SCE2 of the storage capacitor Cst may overlap each other while the second insulating layer 123 is interposed between the first capacitor electrode SCE1 and the second capacitor electrode SCE2.

The second gate conductive layer GCDL2 may further include at least one conductive pattern and/or wire. For example, the second gate conductive layer GCDL2 may further include a first blocking pattern LBP1 and a second blocking pattern LBP2. The first blocking pattern LBP1 and the second blocking pattern LBP2 may be respectively located under a channel region of a third active layer ACT3 (for example, a part of the third active layer ACT3 that overlaps the third gate electrode GE3), and a channel region of a fourth active layer ACT4 (for example, a part of the fourth active layer ACT4 that overlaps the fourth gate electrode GE4). Accordingly, light may be blocked from being incident on the channel regions of the third active layer ACT3 and the fourth active layer ACT4 from the bottom of the third active layer ACT3 and the fourth active layer ACT4, and the operating characteristics of the third transistor T3 and the fourth transistor T4 may be stabilized. In one or more embodiments, the second gate conductive layer GCDL2 may further include the fourth power line VAIL of FIG. 4.

The third insulating layer 124 may be located on the second gate conductive layer GCDL2 and the second insulating layer 123. The third insulating layer 124 may include at least one insulating material (e.g., an inorganic insulating material) and may be formed as a single layer or multiple layers.

The second semiconductor layer SCL2 (also referred to as “second semiconductor pattern layer”) may be located on the third insulating layer 124. The second semiconductor layer SCL2 may include the active layer of each of the second type transistors. For example, the second semiconductor layer SCL2 may include the third active layer ACT3 included in the third transistor T3 and the fourth active layer ACT4 included in the fourth transistor T4. In one or more embodiments, the patterns (for example, the third and fourth active layers ACT3 and ACT4 of each sub-pixel SPX) of the second semiconductor layer SCL2 included in one sub-pixel SPX may be formed integrally, but the present disclosure is not limited thereto. In one or more embodiments, the second semiconductor layer SCL2 may further include the second electrode BCE2 of the boosting capacitor Cbst, and the second electrode BCE2 of the boosting capacitor Cbst may be integrally formed with the third and fourth active layers ACT3 and ACT4.

The patterns of the second semiconductor layer SCL2 may include a second semiconductor material. In one or more embodiments, the second semiconductor material may be an oxide semiconductor, but is not limited thereto. For example, the second semiconductor material may be polycrystalline silicon or monocrystalline silicon.

The fourth insulating layer 125 may be located on the second semiconductor layer SCL2 and the third insulating layer 124. The fourth insulating layer 125 may include at least one insulating material (e.g., an inorganic insulating material) and may be formed as a single layer or multiple layers.

The third gate conductive layer GCDL3 may be located on the fourth insulating layer 125. The third gate conductive layer GCDL3 may include a gate electrode of each of the second type transistors. For example, the third gate conductive layer GCDL3 may include the third gate electrode GE3 included in the third transistor T3 and the fourth gate electrode GE4 included in the fourth transistor T4. The third gate conductive layer GCDL3 may further include at least one conductive pattern and/or wire. For example, the third gate conductive layer GCDL3 may further include at least one of the initialization scan line GIL, the control scan line GCL, or the fifth power line VOBL.

The fifth insulating layer 126 may be located on the third gate conductive layer GCDL3 and the fourth insulating layer 125. The fifth insulating layer 126 may include at least one insulating material (e.g., an inorganic insulating material) and may be formed as a single layer or multiple layers.

The first source-drain conductive layer SCDL1 may be located on the fifth insulating layer 126. The first source-drain conductive layer SCDL1 may include at least one electrode, a conductive pattern and/or a wire. For example, the first source-drain conductive layer SCDL1 may include first, second, and third connection patterns CNE1, CNE2, and CNE3, the first and second emission control lines EL1 and EL2, and the third power line VIL.

The first connection pattern CNE1 may be electrically connected to the fifth active layer ACT5, the second capacitor electrode SCE2 of the storage capacitor Cst, and the first power line VDL through at least one contact hole or via hole. The second connection pattern CNE2 may be electrically connected to the first active layer ACT1 and the third active layer ACT3 through at least one contact hole. The third connection pattern CNE3 may be electrically connected to the third active layer ACT3 and the fourth active layer ACT4 through at least one contact hole. The third connection pattern CNE3 may be electrically connected to the first gate electrode GE1 and the first capacitor electrode SCE1 of the storage capacitor Cst through at least one contact hole in an unillustrated area. In one or more embodiments, the first source-drain conductive layer SCDL1 may further include an additional connection pattern for appropriately connecting the circuit elements of each sub-pixel SPX.

The first emission control line EL1 may be electrically connected to the fifth gate electrode GE5 and the sixth gate electrode of the first sub-pixel SPX1 through at least one contact hole in an unillustrated area. The second emission control line EL2 may be electrically connected to the fifth and sixth gate electrodes of the second and third sub-pixels SPX2 and SPX3 through at least one contact hole in an unillustrated area. The third power line VIL may be electrically connected to the fourth active layer ACT4 through at least one contact hole.

The sixth insulating layer 127 may be located on the first source-drain conductive layer SCDL1 and the fifth insulating layer 126. The sixth insulating layer 127 may include at least one insulating material (e.g., acrylic resin, epoxy resin, phenolic resin, polyamide resin, polyimide resin, or another organic insulating material) and may be formed as a single layer or multiple layers.

The second source-drain conductive layer SCDL2 may be located on the sixth insulating layer 127. The second source-drain conductive layer SCDL2 may include at least one electrode, a conductive pattern and/or a wire. For example, the second source-drain conductive layer SCDL2 may include the first power line VDL.

In one or more embodiments, the first power line VDL may extend substantially in the second direction DR2 in the display area DA, and may be commonly connected to the sub-pixels SPX arranged continuously and/or sequentially along the second direction DR2. The first power line VDL illustrated as two separated patterns in FIG. 8 may be substantially one integral wire. The first power line VDL may be electrically connected to the first connection pattern CNE1 through the first via hole VH1 (or contact hole). The first via hole VH1, which is an opening formed in the sixth insulating layer 127 for contact between the first connection pattern CNE1 and the first power line VDL, may be a type of contact hole. In one or more embodiments, the first power line VDL may overlap the channel regions of the first active layer ACT1, the third active layer ACT3, and the fourth active layer ACT4. Accordingly, light may be prevented from being incident on the channel regions of the first active layer ACT1, the third active layer ACT3, and the fourth active layer ACT4 from the top of the first active layer ACT1, the third active layer ACT3, and the fourth active layer ACT4, and the operating characteristics of the first transistor T1, the third transistor T3, and the fourth transistor T4 may be stabilized.

In one or more embodiments, the second source-drain conductive layer SCDL2 may further include an anode connection pattern connected to a pixel electrode PXE of each sub-pixels SPX and the data lines DL of FIGS. 3 and 4. The anode connection pattern of each sub-pixel SPX may be electrically connected between the pixel electrode PXE and the pixel circuit PXC of the corresponding sub-pixel SPX. For example, the anode connection pattern of each sub-pixel SPX may be electrically connected to the sixth and seventh active layers of the corresponding sub-pixel SPX through at least one contact hole and/or at least one connection pattern, and may be electrically connected to the pixel electrode PXE of the corresponding sub-pixel SPX through the anode contact hole ANH of FIG. 7.

The seventh insulating layer 128 may be located on the second source-drain conductive layer SCDL2 and the sixth insulating layer 127. The seventh insulating layer 128 may include at least one insulating material (e.g., an organic insulating material) and may be formed as a single layer or multiple layers.

The patterns included in each of the conductive layers of the backplane layer 120 may include at least one conductive material. For example, the electrodes, the conductive patterns, and/or the wires included in each of the lower conductive layer BCDL, the first gate conductive layer GCDL1, the second gate conductive layer GCDL2, the third gate conductive layer GCDL3, the first source-drain conductive layer SCDL1 and the second source-drain conductive layer SCDL2 may include copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg), and/or another metal, an alloy thereof, or another conductive material. In one or more embodiments, the electrodes, the conductive patterns, and/or the wires located in the same conductive layer may be concurrently (e.g., simultaneously) formed using the same conductive material. The patterns included in each of the conductive layers of the backplane layer 120 may have a single-layer or multi-layer structure.

The light emitting element layer 130 may be located on the seventh insulating layer 128. The light emitting element layer 130 may include the pixel electrodes PXE, the light emitting elements LE, and the common electrode CE included in the sub-pixels SPX. Additionally, the light emitting element layer 130 may further include a plurality of insulating layers. In one or more embodiments, the insulating layers of the light emitting element layer 130 may include eighth and ninth insulating layers 132 and 134 and a first capping layer 136.

A pixel electrode layer PCDL including the pixel electrodes PXE of the sub-pixels SPX may be located on the seventh insulating layer 128. For example, the pixel electrode layer PCDL may include the first pixel electrode PXE1, the second pixel electrode PXE2, and the third pixel electrode PXE3. In one or more embodiments, the light emitting element LE may be a flip-chip type micro LED. The flip-chip type micro LED refers to an LED in which first and second contact electrodes CTE1 and CTE2 are formed on one surface (e.g., the bottom surface) of the light emitting element LE. When the light emitting element LE is a flip-chip type micro LED, the pixel electrode layer PCDL may further include the common electrode CE. For example, the pixel electrodes PXE and the common electrode CE of the sub-pixels SPX may be located in (e.g., at) the same layer and may be concurrently (e.g., simultaneously) formed using the same conductive material. FIG. 8 illustrates the common electrode CE and the first pixel electrode PXE1 of the first sub-pixel SPX1 from among the patterns of the pixel electrode layer PCDL.

The first pixel electrode PXE1 of the first sub-pixel SPX1 may be electrically connected to the pixel circuit PXC of the first sub-pixel SPX1 through the first anode contact hole ANH1 of FIG. 7. The second pixel electrode PXE2 of the second sub-pixel SPX2 may be electrically connected to the pixel circuit PXC of the second sub-pixel SPX2 through the second anode contact hole ANH2 of FIG. 7. The third pixel electrode PXE3 of the third sub-pixel SPX3 may be electrically connected to the pixel circuit PXC of the third sub-pixel SPX3 through the third anode contact hole ANH3 of FIG. 7.

The patterns (e.g., the pixel electrodes PXE and the common electrode CE) of the pixel electrode layer PCDL may include at least one conductive material, and may be formed as a single layer or multiple layers. In one or more embodiments, the patterns of the pixel electrode layer PCDL may include a metal (for example, molybdenum (Mo), aluminum (Al), chromium (Cr), gold (Au), titanium (Ti), nickel (Ni), neodymium (Nd), copper (Cu), and/or other metals, or an alloy thereof) and have a single layer or multiple layers structure. For example, the patterns of the pixel electrode layer PCDL may be low-resistance patterns formed with a three-layer structure (Ti/Al/Ti) of titanium (Ti), aluminum (Al), and titanium (Ti). Alternatively, the patterns of the pixel electrode layer PCDL may include other low- resistance materials (e.g., copper (Cu)) and/or structures. In case of reducing or minimizing the resistance of the patterns included in the pixel electrode layer PCDL, the first driving voltage VDD and the second driving voltage VSS may be stably transmitted to the light emitting elements LE of the sub-pixels SPX.

The reflective layer RFL may be located on the pixel electrode layer PCDL. For example, each sub-pixel SPX may include a first reflective layer RFL1 located on the pixel electrode PXE, and a second reflective layer RFL2 located on the common electrode CE.

The first reflective layer RFL1 may cover at least one portion of the pixel electrode PXE. For example, the first reflective layer RFL1 may be located on one portion of the pixel electrode PXE including an end portion overlapping the light emitting element LE.

The second reflective layer RFL2 may cover at least one portion of the common electrode CE. For example, the second reflective layer RFL2 may be located on one portion of the common electrode CE including an end portion overlapping the light emitting element LE.

The reflective layer RFL may include a material with high reflectivity for light emitted from the light emitting element LE. In one or more embodiments, the reflective layer RFL may be a conductive layer of a single layer or multi-layers including a conductive material. For example, the reflective layer RFL may include silver (Ag), or aluminum (Al), and/or include other metal with high light reflectivity. For example, the reflective layer RFL may be formed of a three-layer structure (ITO/Ag/ITO) of indium tin oxide (ITO), silver (Ag), and indium tin oxide (ITO).

In a case where the first reflective layer RFL1 and the second reflective layer RFL2 have conductivity, the first reflective layer RFL1, the pixel electrode PXE may be electrically connected to one portion of the light emitting element LE through the first connection electrode BE1, and the common electrode CE may be electrically connected to the other portion of the light emitting element LE through the second connection electrode BE2.

In FIG. 8, each of the pixel electrode PXE, the common electrode CE, the first reflective layer RFL1, and the second reflective layer RFL2 are illustrated to be separated, but the present disclosure is not limited thereto. For example, the first reflective layer RFL1 may be a part of the pixel electrode PXE, and the second reflective layer RFL2 may be a part of the common electrode CE. As an example, the pixel electrode PXE may be formed of a single-layer or multi-layer electrode including the first reflective layer RFL1, and the common electrode CE may be formed of a single-layer or multi-layer electrode including the second reflective layer RFL2. Alternatively, the display panel 100 may not include the first reflective layer RFL1 and the second reflective layer RFL2 of FIG. 8, and the eighth insulating layer 132, the first connection electrode BE1, and the second connection electrode BE2 may be located directly on the pixel electrode layer PCDL. In one or more embodiments, the display panel 100 may not include separate first reflective layer RFL1 and the second reflective layer RFL2, and the patterns of the pixel electrode layer PCDL may function as a reflective layer by including a material with high reflectivity.

The eighth insulating layer 132 may be located on the pixel electrode layer PCDL and the reflective layer RFL. The eighth insulating layer 132 may be an adhesive layer that temporarily fixes or adheres the light emitting elements LE to prevent the light emitting elements LE from tilting and falling over or tipping over during the process of transferring the light emitting elements LE to the display panel 100. For example, the eighth insulating layer 132 may be a film for temporarily adhering the light emitting elements LE onto each of the pixel electrodes PXE and the common electrode CE. To facilitate temporary adhesion, the thickness of the eighth insulating layer 132 may be greater than the thickness of each of the pixel electrodes PXE and the common electrode CE, and may be greater than the thickness of each of the first and second contact electrodes CTE1 and CTE2 of the light emitting elements LE. The eighth insulating layer 132 may also be referred to as “adhesive layer.”

The eighth insulating layer 132 may cover a part of each of the pixel electrode PXE1, the common electrode CE, the first reflective layer RFL1, and the second reflective layer RFL2 under the light emitting element LE. The eighth insulating layer 132 may be opened at portions corresponding to the first connection hole BH1 and the second connection hole BH2 to partially expose the top surfaces of the first reflective layer RFL1 and the second reflective layer RFL2 (or the top surfaces of the pixel electrode PXE and the common electrode CE).

Although it is illustrated in FIG. 8 that the eighth insulating layer 132 is entirely located in the display area DA or a/the sub-pixel area, the present disclosure is not limited thereto. For example, in another embodiment, the eighth insulating layer 132 may be located only on a part of the emission area EA including the area where each of the light emitting element LE is located.

The eighth insulating layer 132 may include at least one insulating material, for example, an organic insulating material. For example, the eighth insulating layer 132 may be a photosensitive organic layer such as a photoresist. Alternatively, the eighth insulating layer 132 may include acryl resin, epoxy resin, phenolic resin, polyamide resin, polyimide resin, and/or the like.

Although it is illustrated in FIG. 8 that the eighth insulating layer 132 is located with an overall uniform thickness or height, the present disclosure is not limited thereto. For example, the eighth insulating layer 132 may have a lower height in portions where each of the light emitting elements LE are located than in other portions. For example, the eighth insulating layer 132 may be pressed by the pressure applied during the process of locating the light emitting elements LE on the eighth insulating layer 132, so that the height of the eighth insulating layer 132 may be partially reduced.

The light emitting elements LE may be located on the eighth insulating layer 132. In one or more embodiments, each of the light emitting elements LE may be a micro LED including an inorganic material. For example, each of the light emitting elements LE may include an inorganic material such as gallium nitride (GaN), and the length in the first direction DR1, the length in the second direction DR2, and the length in the third direction DR3 of each of the light emitting elements LE may each be several µm to several hundred µm. For example, the length in the first direction DR1, the length in the second direction DR2, and the length in the third direction DR3 of each of the light emitting elements LE may each be approximately 100 µm or less.

The light emitting elements LE may be formed by growing on a semiconductor substrate such as a silicon substrate or sapphire substrate. The light emitting elements LE may be transferred directly from the semiconductor substrate onto the pixel electrodes PXE and the common electrode CE of the display panel 100. Alternatively, the light emitting elements LE may be transferred onto the common electrode CE and the pixel electrodes PXE of the display panel 100 through an electrostatic method using an electrostatic head or a stamping method using an elastic polymer material such as PDMS and/or silicon as a transfer substrate.

The light emitting element LE may include a conductive layer E1, a semiconductor stack STC, the first and second contact electrodes CTE1 and CTE2, and a protective film PRL. The semiconductor stack STC may include a first semiconductor layer SEM1, an active layer MQW (e.g., light emitting layer), and a second semiconductor layer SEM2 sequentially arranged along the third direction DR3. In one or more embodiments, the semiconductor stack STC may selectively further include a third semiconductor layer SEM3 located on the second semiconductor layer SEM2.

The conductive layer E1 may be located on the bottom surface of the first semiconductor layer SEM1. FIG. 9 illustrates that the conductive layer E1 covers the entire bottom surface of the first semiconductor layer SEM1, but the present disclosure is not limited thereto. For example, the conductive layer E1 may be located on a portion of the bottom surface of the first semiconductor layer SEM1. The conductive layer E1 may include molybdenum (Mo), aluminum (Al), chromium (Cr), gold (Au), titanium (Ti), nickel (Ni), neodymium (Nd), and/or copper (Cu), and/or a transparent conductive material such as metal oxide.

The first semiconductor layer SEM1 may be located on the conductive layer E1. The first semiconductor layer SEM1 may include a semiconductor material layer doped with a first conductivity type dopant such as magnesium (Mg), zinc (Zn), calcium (Ca), strontium (Sr), and/or barium (Ba), for example, gallium nitride (GaN).

The active layer MQW may be located on the first semiconductor layer SEM1. The active layer MQW may include the same semiconductor material as the first semiconductor layer SEM1 and the second semiconductor layer SEM2. For example, when the first semiconductor layer SEM1 and the second semiconductor layer SEM2 include gallium nitride (GaN), the active layer MQW may also include gallium nitride (GaN). For example, the active layer MQW may include gallium nitride (GaN), indium gallium nitride (InGaN), and/or aluminum gallium nitride (AlGaN). The active layer MQW may emit light by recombination of electron-hole pairs according to an electrical signal applied through the first semiconductor layer SEM1 and the second semiconductor layer SEM2.

The active layer MQW may include a material having a single or multiple quantum well structure. When the active layer MQW includes a material having a multiple quantum well structure, the active layer MQW may have the structure in which a plurality of well layers and barrier layers are alternately stacked. At this time, the well layer may include InGaN, and the barrier layer may include GaN or AlGaN, but the present disclosure is not limited thereto. Alternatively, the active layer MQW may have a structure in which semiconductor materials having large band gap energy and semiconductor materials having small band gap energy are alternately stacked, and may include other Group III to Group V semiconductor materials according to the wavelength band of the emitted light.

When the active layer MQW includes indium gallium nitride (InGaN), the color of emitted light may vary depending on the content of indium (In). For example, as the content of indium (In) increases, the wavelength band of the light emitted by the active layer MQW may shift to the red wavelength band, and as the content of indium (In) decreases, the wavelength band of the light emitted by the active layer MQW may shift to the blue wavelength band.

The second semiconductor layer SEM2 may be located on the active layer MQW. The second semiconductor layer SEM2 may include a semiconductor material layer doped with a second conductivity type dopant such as silicon (Si), germanium (Ge), and tin (Sn), for example, gallium nitride (GaN).

The third semiconductor layer SEM3 may be located on the second semiconductor layer SEM2. The third semiconductor layer SEM3 may be a semiconductor material layer having an n-type dopant lower than a selected critical value, and may be referred to as an undoped semiconductor layer. For example, the third semiconductor layer SEM3 may be indium aluminum gallium nitride (InAlGaN), gallium nitride (GaN), aluminum gallium nitride (AlGaN), indium gallium nitride (InGaN), aluminum nitride (AlN), and/or indium nitride (InN) having an n-type dopant lower than a selected threshold value. The third semiconductor layer SEM3 may be omitted.

An electron blocking layer may be located between the first semiconductor layer SEM1 and the active layer MQW. The electron blocking layer may be a layer for suppressing or preventing too many electrons from flowing into the active layer MQW. For example, the electron blocking layer may be AlGaN or p-AlGaN doped with p-type Mg. The electron blocking layer may be omitted.

A superlattice layer may be located between the active layer MQW and the second semiconductor layer SEM2. The superlattice layer may be a layer for relieving stress between the second semiconductor layer SEM2 and the active layer MQW. For example, the superlattice layer may include InGaN or GaN. The superlattice layer may be omitted.

The protective film PRL may be located on the side surfaces of the conductive layer E1 and the semiconductor stack STC. The protective film PRL may include an inorganic material, for example, silicon nitride (SiNx), silicon oxide (SiOx), silicon oxynitride (SiON), titanium oxide (TiOx), aluminum oxide (AlOx), and/or another inorganic insulating material.

A hole LEH that penetrates the conductive layer E1, the first semiconductor layer SEM1, and the active layer MQW of the light emitting element LE to expose the second semiconductor layer SEM2 may be formed. The hole LEH may have a circular planar shape, but the shape of the hole LEH is not limited thereto. For example, the hole LEH may have a planar shape such as an elliptical shape or a polygonal shape, such as a quadrilateral shape.

The protective film PRL may be located on the sidewall of the conductive layer E1 exposed in the hole LEH, the sidewall of the first semiconductor layer SEM1, and the sidewall of the active layer MQW. The protective film PRL may not cover the second semiconductor layer SEM2 at the hole LEH.

The first contact electrode CTE1 may be located on at least one side surface of the semiconductor stack STC and at least one side surface and the bottom surface of the conductive layer E1 on the protective film PRL. The first contact electrode CTE1 may be located on the bottom surface of the conductive layer E1 not covered by the protective film PRL to be electrically connected to the conductive layer E1.

The second contact electrode CTE2 may be located on at least one side surface of the semiconductor stack STC and at least one side surface and the bottom surface of the conductive layer E1 on the protective film PRL. At this time, the first contact electrode CTE1 may be located on the first side surface of the semiconductor stack STC and the first side surface of the conductive layer E1, while the second contact electrode CTE2 may be located on the second side surface of the semiconductor stack STC and the second side surface of the conductive layer E1.

The second contact electrode CTE2 may be located on the protective film PRL located in the hole LEH and the second semiconductor layer SEM2 exposed without being covered by the protective film PRL in the hole LEH. Accordingly, the second contact electrode CTE2 may be electrically connected to the second semiconductor layer SEM2 in the hole LEH.

In one or more embodiments, each of the first contact electrode CTE1 and the second contact electrode CTE2 may be located on three side surfaces of the semiconductor stack STC. For example, when the semiconductor stack STC includes first to fourth side surfaces, the first contact electrode CTE1 may be located on the first side surface, the third side surface, and the fourth side surface, and the second contact electrode CTE2 may be located on the second side surface, the third side surface, and the fourth side surface.

Each of the first contact electrode CTE1 and the second contact electrode CTE2 may include at least one conductive material, for example, molybdenum (Mo), aluminum (Al), chromium (Cr), gold (Au), titanium (Ti), nickel (Ni), neodymium (Nd), and/or copper (Cu). In one or more embodiments, in order to increase the reflectivity, the first contact electrode CTE1 and the second contact electrode CTE2 may be formed in a two-layer structure (Cr/Au) of chromium (Cr) and gold (Au), a three-layer structure (Ti/Al/Ti) of titanium (Ti), aluminum (Al), and titanium (Ti), or a three-layer structure (ITO/Ag/ITO) of indium tin oxide (ITO), silver (Ag), and indium tin oxide (ITO).

When each of the first contact electrode CTE1 and the second contact electrode CTE2 includes metal having high reflectivity, light emitted from the active layer MQW of the light emitting element LE, which propagates in the lateral direction of the light emitting element LE, may be reflected by the first contact electrode CTE1 and the second contact electrode CTE2 and emitted to the top surface of the light emitting element LE. Accordingly, light loss from the light emitting element LE may be reduced, and the light efficiency of the light emitting element LE may be increased. To increase the light efficiency of the light emitting element LE, the first contact electrode CTE1 and the second contact electrode CTE2 may be located to cover most of the side surface of the semiconductor stack STC.

The first connection electrode BE1 and the second connection electrode BE2 may be located on the eighth insulating layer 132.

The first connection electrode BE1 connects the first contact electrode CTE1 of the light emitting element LE to the pixel electrode PXE. For example, the first connection electrode BE1 of the first sub-pixel SPX1 may connect the first contact electrode CTE1 of the first light emitting element LE1 and the first pixel electrode PXE1. The first connection electrode BE1 of the second sub-pixel SPX2 may connect the first contact electrode CTE1 of the second light emitting element LE2 to the second pixel electrode PXE2. The first connection electrode BE1 of the third sub-pixel SPX3 may connect the first contact electrode CTE1 of the third light emitting element LE3 to the third pixel electrode PXE3.

In one or more embodiments, the first connection electrode BE1 may be in contact with the first contact electrode CTE1 of the light emitting element LE on one part of each of the pixel electrode PXE and the first reflective layer RFL1 and on the eighth insulating layer 132, and may be in contact with the first reflective layer RFL1 on another part of each of the pixel electrode PXE and the first reflective layer RFL1. For example, the first connection electrode BE1 may be in contact with and/or connected to the first reflective layer RFL1 through the first connection hole BH1, which is formed by an opening of the eighth insulating layer 132, and may be electrically connected to each pixel electrode PXE through the first reflective layer RFL1. In another embodiment, in a case where the eighth insulating layer 132 is located only on one portion of the first reflective layer RFL1 overlapping the light emitting element LE, the first connection hole BH1 may not be necessary. For example, the first connection electrode BE1 may be directly located on the first reflective layer RFL1 (or the pixel electrode PXE) exposed at the periphery of the light emitting element LE.

The second connection electrode BE2 connects the second contact electrode CTE2 of the light emitting element LE to the common electrode CE. For example, the second connection electrode BE2 of the first sub-pixel SPX1 may connect the second contact electrode CTE2 of the first light emitting element LE1 and the common electrode CE. The second connection electrode BE2 of the second sub-pixel SPX2 may connect the second contact electrode CTE2 of the second light emitting element LE2 to the common electrode CE. The second connection electrode BE2 of the third sub-pixel SPX3 may connect the second contact electrode CTE2 of the third light emitting element LE3 to the common electrode CE.

In one or more embodiments, the second connection electrode BE2 may be in contact with the second contact electrode CTE2 of the light emitting element LE on one part of each of the common electrode CE and the second reflective layer RFL2, and on the eighth insulating layer 132, and may be in contact with the second reflective layer RFL2 on another part of each of the common electrode CE and the second reflective layer RFL2. For example, the second connection electrode BE2 may be in contact with and/or connected to the second reflective layer RFL2 through the second connection hole BH2, which is formed by an opening of the eighth insulating layer 132, and may be electrically connected to the common electrode CE through the second reflective layer RFL2. In another embodiment, in a case where the eighth insulating layer 132 is located only on one portion of the second reflective layer RFL2 overlapping the light emitting element LE, the second connection hole BH2 may not be necessary. For example, the second connection electrode BE2 may be directly located on the second reflective layer RFL2 (or the common electrode CE) exposed at the periphery of the light emitting element LE.

Each of the first connection electrode BE1 and the second connection electrode BE2 may include at least one conductive material, for example, molybdenum (Mo), aluminum (Al), chromium (Cr), gold (Au), titanium (Ti), nickel (Ni), neodymium (Nd), and/or copper (Cu). Alternatively, each of the first connection electrode BE1 and the second connection electrode BE2 may include a transparent conductive material (for example, a transparent conductive oxide (TCO)) such as indium tin oxide (ITO) and/or indium zinc oxide (IZO).

The conductive layer E1 of the light emitting element LE may be in contact with and/or connected to the first contact electrode CTE1, and may be electrically connected to the first connection electrode BE1 through the first contact electrode CTE1. The second semiconductor layer SEM2 of the light emitting element LE may be in contact with and/or connected to the second contact electrode CTE2 formed in the hole LEH, and may be electrically connected to the second connection electrode BE2 through the second contact electrode CTE2.

The ninth insulating layer 134 may be located on the eighth insulating layer 132. In one or more embodiments, the ninth insulating layer 134 may be formed to have a height less than or equal to the height of the light emitting elements LE, and may partially or entirely cover the side surfaces of the light emitting elements LE. The top surface of each of the light emitting elements LE may be exposed without being covered by the ninth insulating layer 134.

Further, the ninth insulating layer 134 may cover at least a part of the first and second connection electrodes BE1 and BE2. For example, as illustrated in FIGS. 8 - 9, the ninth insulating layer 134 may be formed to have a height greater than or equal to the maximum height of the first and second connection electrodes BE1 and BE2 to completely cover the first and second connection electrodes BE1 and BE2, but the present disclosure is not limited thereto.

The ninth insulating layer 134 may include at least one insulating material, for example, an organic insulating material. For example, the ninth insulating layer 134 may be formed as an organic insulating layer such as acrylic resin, epoxy resin, phenolic resin, polyamide resin, polyimide resin, and/or the like. The ninth insulating layer 134 may be formed as a single layer or multiple layers. The ninth insulating layer 134 may flatten the stepped portion caused by the light emitting elements LE.

The first capping layer 136 may be located on the light emitting elements LE and the ninth insulating layer 134. The first capping layer 136 may include at least one insulating material, for example, an inorganic insulating material.

The optical layer 140 may be located on the first capping layer 136. The optical layer 140 may include a light transmitting layer TPL located in the emission areas EA of the sub-pixels SPX, a light blocking layer BM located in the non-emission area NEA around (e.g., surrounding) the emission areas EA of the sub-pixels SPX, and color filters (for example, first, second, and third color filters CF1, CF2, and CF3) corresponding to the emission color of each of the sub-pixels SPX.

Although the structure in which the light blocking layer BM, the second capping layer 142, and the reflective film RF are located on the first capping layer 136, and the light transmitting layer TPL and a third capping layer 144 are located on the second capping layer 142 and the reflective film RF is illustrated in FIG. 8, the present disclosure is not limited thereto. For example, the arrangement order and/or shape of the light blocking layer BM, the reflective film RF, and the light transmitting layer TPL may vary depending on embodiments.

The light blocking layer BM may be located on the first capping layer 136. The light blocking layer BM may partition the emission area EA and the non-emission area NEA. The light blocking layer BM may include a light blocking material such as an organic black pigment or an inorganic black pigment such as carbon black and/or the like. The light blocking layer BM may include an organic film such as acryl resin, epoxy resin, phenolic resin, polyamide resin, polyimide resin, and/or the like, but is not limited thereto.

The second capping layer 142 may be located on the first capping layer 136 and the light blocking layer BM. The second capping layer 142 may include at least one insulating material, for example, an inorganic insulating material.

The reflective film RF may be located on the light blocking layer BM. For example, the reflective film RF may be located on a part of the second capping layer 142 that covers the side surface of the light blocking layer BM. The reflective film RF may reflect light propagating in the lateral direction from the light transmitting layer TPL. The reflective film RF may include a material having high light reflectivity, for example, a metal such as aluminum (Al). Alternatively, the reflective film RF may be formed as a distributed Bragg reflector including inorganic films (for example, silicon nitride (SiNₓ), silicon nitride oxide (SiON), silicon oxide (SiOₓ), titanium oxide (TiOₓ), and/or aluminum oxide (AlOₓ)) having different refractive indices and arranged alternately.

The light transmitting layer TPL may be located in each emission area EA and surrounded by the light blocking layer BM and may be on the second capping layer 142. In one or more embodiments, the light transmitting layer TPL may include a substantially transparent organic material. For example, the light transmitting layer TPL may be a light transmitting organic film including epoxy resin, acrylic resin, cardo resin, and/or imide resin.

In one or more embodiments, the light emitting element LE may emit light of a color corresponding to the emission color of each sub-pixel SPX, and the light transmitting layer TPL may transmit the light emitted from the light emitting element LE. When the sub-pixels SPX include the light emitting elements LE that emit light corresponding to each emission color, the light emitted from the light emitting elements LE may be utilized more efficiently. For example, it is possible to prevent a decrease in the light efficiency of the sub-pixels SPX due to light conversion. In addition, the color purity of light emitted from the sub-pixels SPX may be increased.

In another embodiment, the light emitting element LE of at least one sub-pixel SPX may emit light of a color different from the emission color of the corresponding sub-pixel SPX, and a light conversion layer (e.g., a wavelength conversion layer) including wavelength conversion particles may be located on the light emitting element LE of the at least one sub-pixel SPX. In one or more embodiments, the light conversion layer may include base resin constituting the light transmitting layer TPL, and wavelength conversion particles (for example, quantum dots, quantum rods, fluorescent materials, or phosphorescent materials) dispersed in the light transmitting layer TPL. The light conversion layer may convert light emitted from the light emitting element LE of the corresponding sub-pixel SPX into light of another color. For example, when the first light emitting element LE1 emits blue light and the first sub-pixel SPX1 is a red sub-pixel that emits red light, the light conversion layer including wavelength conversion particles for converting blue light into red light may be located on the first light emitting element LE1. When the sub-pixels SPX include light emitting elements LE that emit light of the same color, the manufacturing efficiency of the display panel 100 may be increased.

The third capping layer 144 may be located on the second capping layer 142 and the light transmitting layer TPL. The third capping layer 144 may include at least one insulating material, for example, an inorganic insulating material.

A first overcoat layer 146 may be located on the third capping layer 144. In one embodiment, the first overcoat layer 146 may include a light transmitting organic material (for example, acrylic resin, epoxy resin, phenolic resin, polyamide resin, or polyimide resin), and the top surface of the first overcoat layer 146 may be substantially flat. However, the present disclosure is not limited thereto. For example, the first overcoat layer 146 may be an inorganic layer including an inorganic material, and the first overcoat layer 146 may be formed to have a sufficient thickness to include a substantially flat top surface or may be flattened through a separate planarization process. Accordingly, the top surface of the first overcoat layer 146 may be substantially flat.

The color filters of the sub-pixels SPX may be located on the first overcoat layer 146. The color filter for selectively transmitting light corresponding to the color (or wavelength) corresponding to the emission color of the corresponding sub-pixel SPX may be located in the emission area EA of each of the sub-pixels SPX. For example, the first color filter CF1 for selectively transmitting light of the first color may be located in the emission area EA of the first sub-pixel SPX1. In one or more embodiments, the color filters of the sub-pixels SPX may be located to overlap each other in the non-emission area NEA, thereby forming a light blocking pattern. For example, the first color filter CF1, the second color filter CF2, and the third color filter CF3 respectively located in the first sub-pixel SPX1, the second sub-pixel SPX2, and the third sub-pixel SPX3 may overlap each other in the non-emission area NEA. The second color filter CF2 may selectively transmit light of the second color corresponding to an emission light of the second sub-pixel SPX2, and the third color filter CF3 may selectively transmit light of the third color corresponding to an emission light of the third sub-pixel SPX3.

A second overcoat layer 148 may be located on the first color filter CF1, the second color filter CF2, and the third color filter CF3. In one or more embodiments, the second overcoat layer 148 may include a light transmitting organic material, and the top surface of the second overcoat layer 148 may be substantially flat. However, the present disclosure is not limited thereto. For example, the second overcoat layer 148 may be an inorganic layer including an inorganic material, and the second overcoat layer 148 may be formed to have a sufficient thickness to include a substantially flat top surface or may be flattened through a separate planarization process. Accordingly, the top surface of the second overcoat layer 148 may be substantially flat.

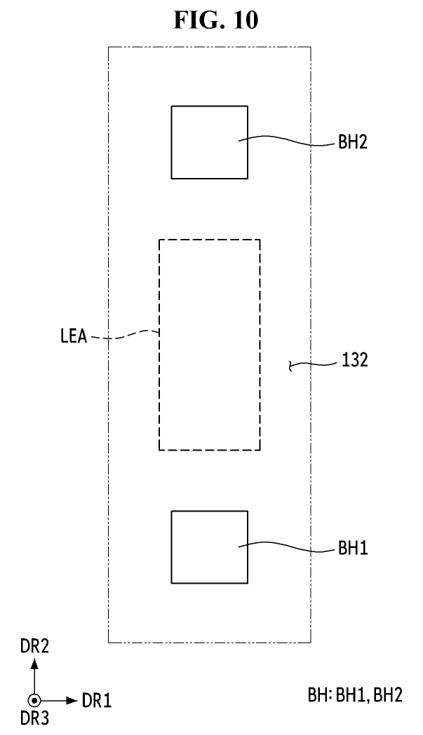

FIG. 10 is a plan view showing an insulating layer located between a pixel electrode layer and a light emitting element of a display panel according to one or more embodiments. For example, FIG. 10 shows the eighth insulating layer 132 of FIG. 8. In FIG. 10, a plan surface of a portion of the eighth insulating layer 132 located in one sub-pixel area is schematically illustrated.

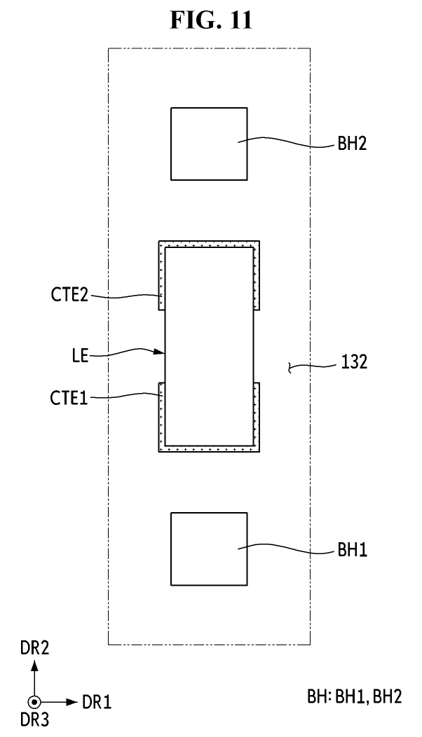

FIG. 11 is a plan view showing the insulating layer and the light emitting element located on the insulating layer of FIG. 10. For example, FIG. 11 shows the eighth insulating layer 132 and one light emitting element LE (e.g., the first light emitting element LE1) located on the eighth insulating layer 132 of FIG. 8. In FIGS. 10 and 11, the plane shapes of the eighth insulating layer 132 and the light emitting element LE when viewed from above the light emitting element LE are illustrated.

Referring to FIGS. 10 and 11 in addition to FIGS. 6 - 9, the eighth insulating layer 132 may include connection holes BH located at the periphery of a light emitting element area LEA where the light emitting element LE is located. For example, the eighth insulating layer 132 may include a first connection hole BH1 and a second connection hole BH2 located on different sides of the light emitting element area LEA.

The first connection hole BH1 and the second connection hole BH2 may be spaced (e.g., spaced apart) from the light emitting element area LEA, and accordingly, may not overlap the light emitting element LE in the third direction DR3. The first connection hole BH1 may expose the first reflective layer RFL1 (or the pixel electrode PXE) at the periphery of one end of the light emitting element LE including the first contact electrode CTE1. The second connection hole BH2 may expose the second reflective layer RFL2 (or the common electrode CE) at the periphery of the other end of the light emitting element LE including the second contact electrode CTE2.

The light emitting element LE may be located on the eighth insulating layer 132 between the first connection hole BH1 and the second connection hole BH2. The light emitting element LE may be located to be spaced (e.g., spaced apart) from the first connection hole BH1 and the second connection hole BH2. In one or more embodiments, the light emitting element LE may be spaced (e.g., spaced apart) by the same or similar distance from the first connection hole BH1 and the second connection hole BH2. In this case, even when a slight alignment error occurs during the process of placing the light emitting element LE, the light emitting element LE may be stably placed on the eighth insulating layer 132. However, the present disclosure is not limited thereto. For example, the light emitting element LE may be placed closer to any one of the first connection hole BH1 and the second connection hole BH2.

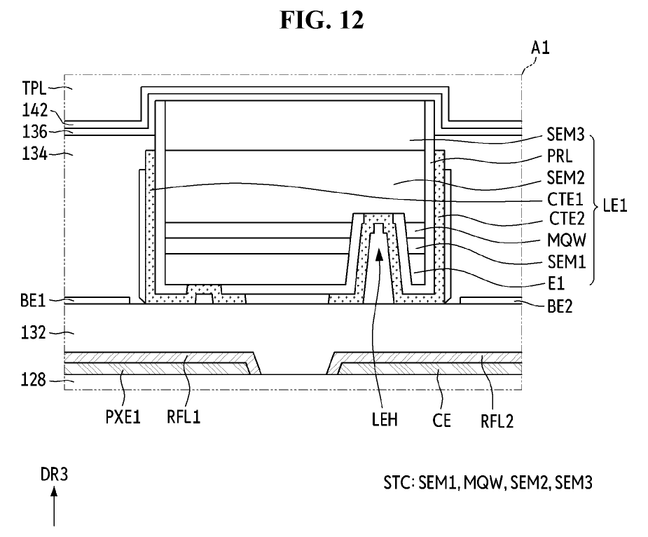

FIG. 12 is a cross-sectional view showing an example of an open-circuit failure that may occur in a display panel according to one or more embodiments. For example, FIG. 12 shows an example of an open-circuit failure (or a disconnection defect) that may occur to connection electrodes in an area A1 of FIGS. 8 and 9.

Referring to FIG. 12 in addition to FIGS. 6 - 11, as the light emitting element LE is aligned in substantially straight line on the eighth insulating layer 132, there is a risk of open-circuit failures of the connection electrodes BE. For example, in a case where the side surfaces of the light emitting element LE are aligned in substantially straight line in respect to the eighth insulating layer 132, a conductive film may not be appropriately formed at the periphery of the interface where the light emitting element LE and the eighth insulating layer 132 meet in the process of forming the film of a conductive material (e.g., a sputtering process) for forming the first connection electrode BE1 and the second connection electrode BE2. For example, although a structure in which the lower edge of the light emitting element LE is placed in completely close contact with the eighth insulating layer 132 is shown in FIG. 12, the lower edge of the light emitting element LE may not be completely in contact with the eighth insulating layer 132 and a slight gap may occur in the manufacturing process of the display panel 100, and due to this, a conductive film may be disconnected along the lower edge of the light emitting element LE. Alternatively, regardless of whether the light emitting element LE and the eighth insulating layer 132 are in close contact, because the light emitting element LE is substantially vertically arranged on the eighth insulating layer 132, a conductive material may not be properly or sufficiently deposited at a corner where at least one side surface of the light emitting element LE and the lower edge of the light emitting element LE meet. Accordingly, the light emitting element LE may not be properly (e.g., completely) connected between the pixel electrode PXE and the common electrode CE by the connection electrodes BE.

For example, when a conductive film is disconnected on one end of the light emitting element LE including the first contact electrode CTE1, the first connection electrode BE1 may be disconnected. Similarly, as the conductive film is disconnected on the other end of the light emitting element LE including the second contact electrode CTE2, the second connection electrode BE2 may be disconnected. For example, the conductive film formed on the side surface of the light emitting element LE and the conductive film formed on the eighth insulating layer 132 may be separated, thereby causing at least one of the first connection electrode BE1 and the second connection electrode BE2 to be disconnected. FIG. 12 illustrates a case where the first connection electrode BE1 and the second connection electrode BE2 are all disconnected as an example.

In a case where at least one among the first connection electrode BE1 and the second connection electrode BE2 is disconnected, the light emitting element LE may not be properly connected between the pixel electrode PXE and the common electrode CE. Accordingly, an open-circuit failure may occur in the sub-pixel SPX. The open-circuit failure of the sub-pixel SPX may cause a defect of the display device, for example, a scotoma defect.

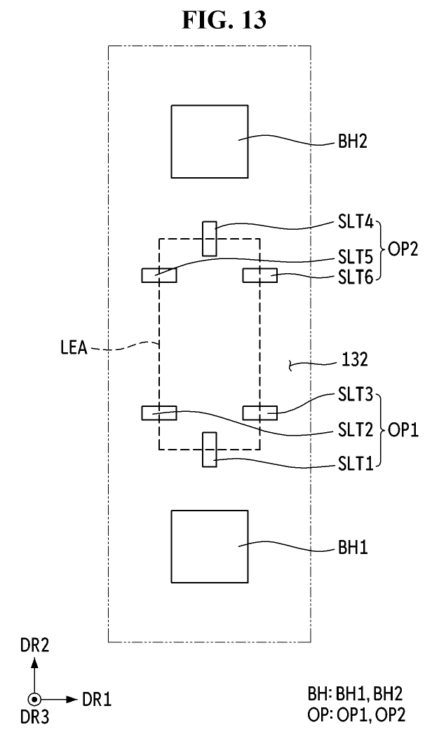

FIG. 13 is a plan view illustrating an insulating layer between a pixel electrode layer and a light emitting element of a display panel according to one or more embodiments. For example, FIG. 13 shows the eighth insulating layer 132 of the display panel 100 according to one or more embodiments.

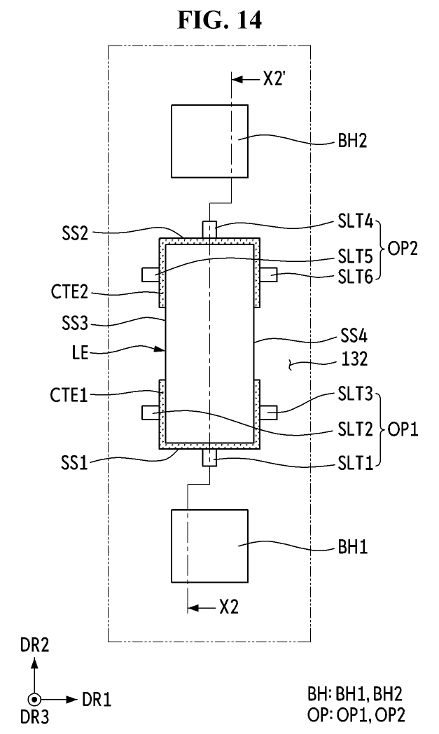

FIG. 14 is a plan view illustrating the insulating layer and the light emitting element located on the insulating layer of FIG. 13. For example, FIG. 14 shows the eighth insulating layer 132 and the light emitting element LE located on the eighth insulating layer 132 of FIG. 13.

In FIGS. 13 and 14, a portion of the eighth insulating layer 132 located in one sub-pixel area and one light emitting element LE (e.g., the first light emitting element LE1) located on a portion of the eighth insulating layer 132 are illustrated. In addition, in FIGS. 13 and 14, the plane shapes of the eighth insulating layer 132 and the light emitting element LE when viewed from above are illustrated.

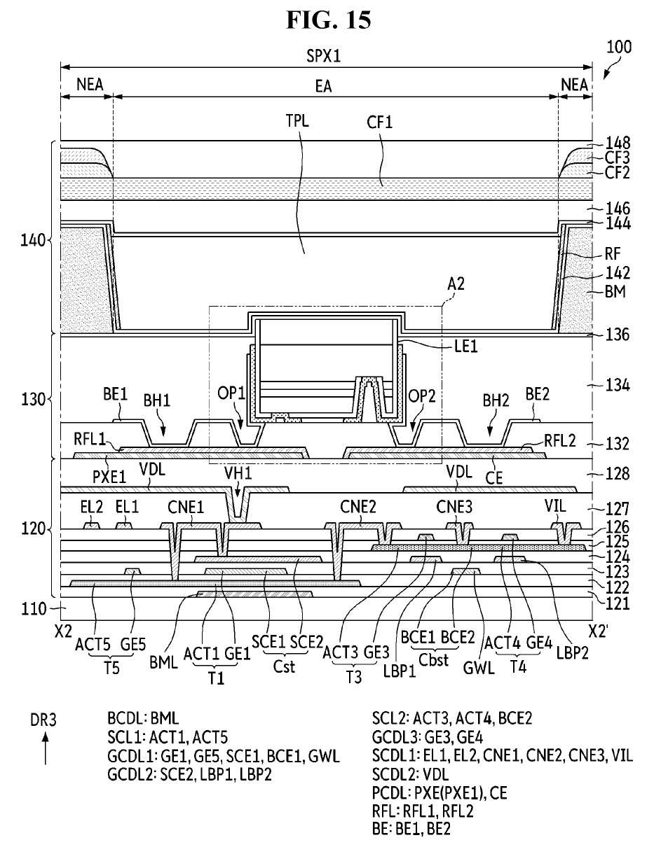

FIG. 15 is a cross-sectional view showing a display panel according to one or more embodiments. For example, FIG. 15 shows an embodiment of a cross-section of a portion of the display panel 100 corresponding to the line X2-X2’ of FIG. 14. The line X2-X2’ of FIG. 14 may be a cross-sectional line at a position corresponding to the line X1-X1’ in FIG. 7. For example, FIG. 15 shows an embodiment of a cross-section of a portion of the display panel 100 where one first sub-pixel SPX1 is placed.

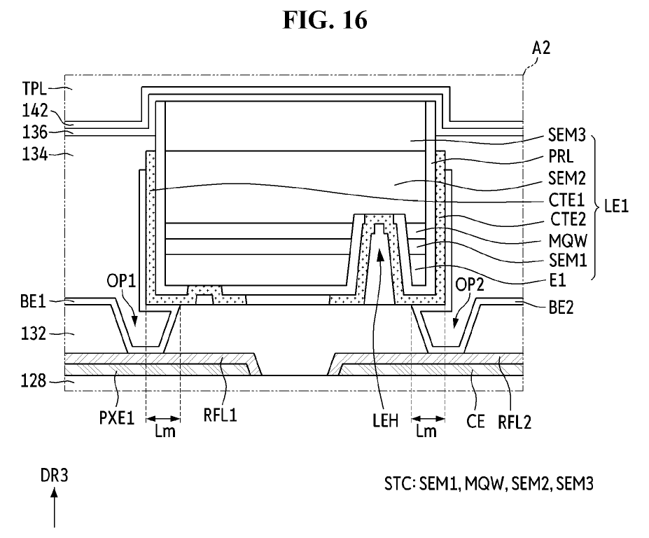

FIG. 16 is a cross-sectional view showing an area A2 of FIG. 15 in detail. For example, FIG. 16 shows a portion of the first sub-pixel SPX1 according to one or more embodiments in detail. In one or more embodiments, the first light emitting element LE1, the second light emitting element LE2, and the third light emitting element LE3 of the respective first sub-pixel SPX1, the second sub-pixel SPX2, and the third sub-pixel SPX3 may have substantially the same or similar cross-sectional structure to each other.

Referring to FIGS. 13 - 16, the eighth insulating layer 132 may be partially opened below the light emitting element LE of each of the sub-pixels SPX. For example, the eighth insulating layer 132 may include openings OP located below the light emitting element LE of each of the sub-pixels SPX.

The eighth insulating layer 132 may include at least one first opening OP1 located below the first contact electrode CTE1. The first opening OP1 may have a width or area smaller than the width or area of the first contact electrode CTE1 and may be partially positioned only below a portion of the first contact electrode CTE1.

In one or more embodiments, in a case where the light emitting element LE is a flip-chip type light emitting element further including the second contact electrode CTE2, the eighth insulating layer 132 may further include at least one second opening OP2 located below the second contact electrode CTE2. The second opening OP2 may have a width or area smaller than the width or area of second contact electrode CTE2 and may be partially positioned only below a portion of the second contact electrode CTE2.

In one or more embodiments, the eighth insulating layer 132 may include a plurality of first openings OP1 overlapping different portions of the first contact electrode CTE1 and a plurality of second openings OP2 overlapping different portions of the second contact electrode CTE2. The first openings OP1 may be formed to be separated from each other below the first contact electrode CTE1. The second openings OP2 may be formed to be separated from each other below the second contact electrode CTE2.

In one or more embodiments, the first contact electrode CTE1 may be located on a first side surface SS1, a third side surface SS3 (for example, a portion of the third side surface SS3 adjacent to the first side surface SS1), and a fourth side surface SS4 (for example, a portion of the fourth side surface SS4 adjacent to the first side surface SS1) of the light emitting element LE. In addition, the first openings OP1 may include a plurality of slit-type openings crossing different side surfaces of the light emitting element LE (or the semiconductor stack STC). For example, the first openings OP1 may include a first slit-type opening SLT1 crossing the first side surface SS1 of the light emitting element LE below the first contact electrode CTE1, a second slit-type opening SLT2 crossing the third side surface SS3 of the light emitting element LE below the first contact electrode CTE1, and a third slit-type opening SLT3 crossing the fourth side surface SS4 of the light emitting element LE below the first contact electrode CTE1. The first slit-type opening SLT1, the second slit-type opening SLT2, and the third slit-type opening SLT3 may overlap different portions of the first contact electrode CTE1 and may be spaced (e.g., spaced apart) from each other.

The first slit-type opening SLT1 may have a width smaller than the width of each of the first side surface SS1 of the light emitting element LE and the first contact electrode CTE1 in the first direction DR1, and may overlap the first side surface SS1 of the light emitting element LE and the central portion of the first contact electrode CTE1. For example, the first slit-type opening SLT1 may have a width smaller than the width of the first contact electrode CTE1 in the first direction DR1 along which a first edge (for example, the lower end of the bottom surface of the light emitting element LE) where the first side surface SS1 of the light emitting element LE and the bottom surface of the light emitting element LE meet extends and the first slit-type opening SLT1 may cross the central portion of the first edge. The first slit-type opening SLT1 may not be located on both ends of the first edge. The first slit-type opening SLT1 may extend in a second direction DR2 intersecting the first direction DR1. The first edge may be located at the central portion of the first slit-type opening SLT1 in the second direction DR2.

The second slit-type opening SLT2 may have a width smaller than the width of each of the third side surface SS3 of the light emitting element LE and the first contact electrode CTE1 in the second direction DR2, and may overlap the central portion of the first contact electrode CTE1. For example, the second slit-type opening SLT2 may have a width smaller than the width of the first contact electrode CTE1 in the second direction DR2 along which a third edge (for example, the left end of the bottom surface of the light emitting element LE) where the third side surface SS3 of the light emitting element LE and the bottom surface of the light emitting element LE meet extends and the second slit-type opening SLT2 may cross a portion of the third edge. The second slit-type opening SLT2 may not be located on both ends of the third edge and the first contact electrode CTE1. The second slit-type opening SLT2 may extend in the first direction DR1. The third edge of the light emitting element LE may be located at the central portion of the second slit-type opening SLT2 in the first direction DR1.

The third slit-type opening SLT3 may have a width smaller than the width of each of the fourth side surface SS4 of the light emitting element LE and the first contact electrode CTE1 in the second direction DR2, and may overlap the central portion of the first contact electrode CTE1. For example, the third slit-type opening SLT3 may have a width smaller than the width of the first contact electrode CTE1 in the second direction DR2 along which a fourth edge (for example, the right end of the bottom surface of the light emitting element LE) where the fourth side surface SS4 of the light emitting element LE and the bottom surface of the light emitting element LE meet extends and the third slit-type opening SLT3 may cross a portion of the fourth edge. The third slit-type opening SLT3 may not be located on both ends of the fourth edge and the first contact electrode CTE1. The third slit-type opening SLT3 may extend in the first direction DR1. The fourth edge of the light emitting element LE may be located at the central portion of the third slit-type opening SLT3 in the first direction DR1.

In one or more embodiments, the second slit-type opening SLT2 and the third slit-type opening SLT3 may be located in parallel to each other in the first direction DR1. In this case, the eighth insulating layer 132 more stably (e.g., more evenly) supports the light emitting element LE at the periphery of the second slit-type opening SLT2 and the third slit-type opening SLT3 to prevent the light emitting element LE from being tilted or slanted in any one direction. However, the present disclosure is not limited thereto. For example, if the stability of the light emitting element LE is not impaired, the second slit-type opening SLT2 and the third slit-type opening SLT3 may be aligned or be formed to be asymmetrical in the first direction DR1 and/or the second direction DR2.

In one or more embodiments, the second contact electrode CTE2 may be located on a second side surface SS2, the third side surface SS3 (for example, a portion of the third side surface SS3 adjacent to the second side surface SS2), and the fourth side surface SS4 (for example, a portion of the fourth side surface SS4 adjacent to the second side surface SS2) of the light emitting element LE. In addition, the second openings OP2 may include a plurality of slit-type openings crossing different side surfaces of the light emitting element LE (or the semiconductor stack STC). For example, the second openings OP2 may include a fourth slit-type opening SLT4 crossing the second side surface SS2 of the light emitting element LE below the second contact electrode CTE2, a fifth slit-type opening SLT5 crossing the third side surface SS3 of the light emitting element LE below the second contact electrode CTE2, and a sixth slit-type opening SLT6 crossing the fourth side surface SS4 of the light emitting element LE below the second contact electrode CTE2. The fourth slit-type opening SLT4, the fifth slit-type opening SLT5, and the sixth slit-type opening SLT6 may overlap different portions of the second contact electrode CTE2 and may be spaced (e.g., spaced apart) from each other.

The fourth slit-type opening SLT4 may have a width smaller than the width of each of the second side surface SS2 of the light emitting element LE and the second contact electrode CTE2 in the first direction DR1, and may overlap the second side surface SS2 of the light emitting element LE and the central portion of the second contact electrode CTE2. For example, the fourth slit-type opening SLT4 may have a width smaller than the width of the second contact electrode CTE2 in the first direction DR1 along which a second edge (for example, the upper end of the bottom surface of the light emitting element LE) where the second side surface SS2 of the light emitting element LE and the bottom surface of the light emitting element LE meet extends and the fourth slit-type opening SLT4 may cross the central portion of the second edge. The fourth slit-type opening SLT4 may not be located on both ends of the second edge. The fourth slit-type opening SLT4 may extend in the second direction DR2. The second edge of the light emitting element LE may be located at the central portion of the fourth slit-type opening SLT4.

In one or more embodiments, the first slit-type opening SLT1 and the fourth slit-type opening SLT4 may be located in parallel to each other in the second direction DR2. In this case, the eighth insulating layer 132 more stably supports the light emitting element LE at the periphery of the first slit-type opening SLT1 and the fourth slit-type opening SLT4. However, the present disclosure is not limited thereto. For example, if the stability of the light emitting element LE is not impaired, the first slit-type opening SLT1 and the fourth slit-type opening SLT4 may be aligned or be formed to be asymmetrical in the first direction DR1 and/or the second direction DR2.

The fifth slit-type opening SLT5 may have a width smaller than the width of each of the third side surface SS3 of the light emitting element LE and the second contact electrode CTE2 in the second direction DR2, and may overlap the central portion of the second contact electrode CTE2. For example, the fifth slit-type opening SLT5 may have a width smaller than the width of the second contact electrode CTE2 in the second direction DR2 along which the third edge of the light emitting element LE extends and the fifth slit-type opening SLT5 may cross a portion of the third edge. The fifth slit-type opening SLT5 may not be located on both ends of the third edge and the second contact electrode CTE2. The fifth slit-type opening SLT5 may extend in the first direction DR1. The third edge of the light emitting element LE may be located at the central portion of the fifth slit-type opening SLT5 in the first direction.

The sixth slit-type opening SLT6 may have a width smaller than the width of each of the fourth side surface SS4 of the light emitting element LE and the second contact electrode CTE2 in the second direction DR2, and may overlap the central portion of the second contact electrode CTE2. For example, the sixth slit-type opening SLT6 may have a width smaller than the width of the second contact electrode CTE2 in the second direction DR2 along which the fourth edge of the light emitting element LE extends and the sixth slit-type opening SLT6 may cross a portion of the fourth edge. The sixth slit-type opening SLT6 may not be located on both ends of the fourth edge and the second contact electrode CTE2. The sixth slit-type opening SLT6 may extend in the first direction DR1. The fourth edge of the light emitting element LE may be located at the central portion of the sixth slit-type opening SLT6 in the first direction.

In one or more embodiments, the fifth slit-type opening SLT5 and the sixth slit-type opening SLT6 may be located in parallel to each other in the first direction DR1. In this case, the eighth insulating layer 132 more stably supports the light emitting element LE at the periphery of the fifth slit-type opening SLT5 and the sixth slit-type opening SLT6. However, the present disclosure is not limited thereto. For example, if the stability of the light emitting element LE is not impaired, the fifth slit-type opening SLT5 and the sixth slit-type opening SLT6 may be aligned or be formed to be asymmetrical in the first direction DR1 and/or the second direction DR2.

As each first opening OP1 and each second opening OP2 are located below the central portion of each edge of the light emitting element LE, the bottom surface vertex portions of the light emitting element LE may be located below the eighth insulating layer 132. Due to this, the eighth insulating layer 132 may stably support the light emitting element LE. For example, as the eighth insulating layer 132 supports the light emitting element LE at least below the bottom surface vertex portions of the light emitting element LE, the light emitting element LE may be stably placed and/or fixed on the eighth insulating layer 132.

As at least one first opening OP1 is formed in a portion of the eighth insulating layer 132 corresponding to the first contact electrode CTE1, a portion of the bottom surface of the first contact electrode CTE1 may not be covered by the eighth insulating layer 132. For example, a portion of the bottom surface of the first contact electrode CTE1 may not be covered by the eighth insulating layer 132 in an area where each first opening OP1 is located. The other portion of the bottom surface of the first contact electrode CTE1 may be located on the eighth insulating layer 132 around (e.g., surrounding) each first opening OP1 and may be covered by the eighth insulating layer 132.

The portion of the bottom surface of the first contact electrode CTE1 not covered by the eighth insulating layer 132 may be covered by the first connection electrode BE1. For example, as illustrated in FIGS. 15 and 16, a portion of the first connection electrode BE1 may be located in the first opening OP1 and may cover the portion of the bottom surface of the first contact electrode CTE1 not covered by the eighth insulating layer 132. For example, the first connection electrode BE1 may be in contact with the bottom surface of the first contact electrode CTE1 on each of the first openings OP1 to directly cover the portion of the bottom surface.

An embodiment in which the first connection electrode BE1 is formed to be completely in contact with the portion of the bottom surface of the first contact electrode CTE1 not covered by the eighth insulating layer 132 is shown in FIGS. 15 and 16, but the present disclosure is not limited thereto. For example, in a portion corresponding to at least one first opening OP1, the first connection electrode BE1 and the first contact electrode CTE1 may not be completely in contact with each other and may be partially separated.

The first connection electrode BE1 may extend from one end connected to the light emitting element LE to the other end connected to the pixel electrode PXE and/or the first reflective layer RFL1. For example, the first connection electrode BE1 may continuously extend from one end located on the first side surface SS1 of the light emitting element LE and connected to the first contact electrode CTE1, crossing at least one first opening OP1 and the first connection electrode BH1, to the other end located at the outer edge of the emission area EA (or the outer edge of the sub-pixel SPX).

As at least one second opening OP2 is formed in a portion of the eighth insulating layer 132 corresponding to the second contact electrode CTE2, a portion of the bottom surface of the second contact electrode CTE2 may not be covered by the eighth insulating layer 132. For example, the portion of the bottom surface of the second contact electrode CTE2 may not be covered by the eighth insulating layer 132 in an area where each second opening OP2 is located. The other portion of the bottom surface of the second contact electrode CTE2 may be located on the eighth insulating layer 132 around (e.g., surrounding) each second opening OP2 and may be covered by the eighth insulating layer 132.

A portion of the bottom surface of the second contact electrode CTE2 not covered by the eighth insulating layer 132 may be covered by the second connection electrode BE2. For example, as shown in FIGS. 15 and 16, a portion of the second connection electrode BE2 may be located in the second opening OP2 and cover a portion of the bottom surface of the second contact electrode CTE2 not covered by the eighth insulating layer 132. For example, the second connection electrode BE2 may be in contact with the bottom surface of the second contact electrode CTE2 on each second opening OP2 to directly cover the portion of the bottom surface.

An embodiment in which the second connection electrode BE2 is formed to be completely in contact with the portion of the bottom surface of the second contact electrode CTE2 not covered by the eighth insulating layer 132 is shown in FIGS. 15 and 16, but the present disclosure is not limited thereto. For example, in a portion corresponding to at least one second opening OP2, the second connection electrode BE2 and the second contact electrode CTE2 may not be completely in contact with each other and may be partially separated.

The second connection electrode BE2 may extend from one end connected to the light emitting element LE to the other end connected to the common electrode CE and/or the second reflective layer RFL2. For example, the second connection electrode BE2 may continuously extend from one end located on the second side surface SS2 of the light emitting element LE and connected to the second contact electrode CTE2, crossing at least one second opening OP2 and the second connection hole BH2, to the other end located at the outer edge of the emission area EA (or the outer edge of the sub-pixel SPX).

In one or more embodiments, a length Lm of a portion overlapping each of the first opening OP1 and the first contact electrode CTE1 and a length Lm of a portion overlapping each of the second opening OP2 and the second contact electrode CTE2 may be substantially the same. For example, the reliability may be evaluated by forming the connection electrodes BE on the openings OP with modifying the length of the openings OP, and an appropriate (e.g., optimized) length Lm may be derived so that each of the connection electrodes BE are stably connected without disconnection on each of the openings OP. In describing the embodiments, the length Lm by which each opening OP overlaps the first contact electrode CTE1 or the second contact electrode CTE2 may also be referred to as “overlapping length” or “margin length.” Because the end of the light emitting element LE is located on a portion corresponding to approximately half of each of the openings OP, each of the openings OP may have a length corresponding to approximately double the derived margin length Lm.

According to the embodiments of FIGS. 13 - 16, as the openings OP (e.g., slit-type openings of a narrow width) are formed in the eighth insulating layer 132 below the first contact electrode CTE1 and the second contact electrode CTE2, disconnection of the first contact electrode CTE1 and the second contact electrode CTE2 may be prevented. For example, in the process of forming a conductive film for forming the first connection electrode BE1 and the second connection electrode BE2, a conductive material may be properly deposited even inside the openings OP below the light emitting element LE. Accordingly, the conductive film may be prevented from being disconnected at the periphery around the bottom surface of the light emitting element LE. For example, the first connection electrode BE1 may be in contact with a portion of the bottom surface of the first contact electrode CTE1 exposed by the first opening OP1 as well as the side surface of the first contact electrode CTE1 and may stably extend to the top portion of the first reflective layer RFL1 and the pixel electrode PXE. In addition, the second connection electrode BE2 may be in contact with a portion of the bottom surface of the second contact electrode CTE2 exposed by the second opening OP2 as well as the side surface of the second contact electrode CTE2 and may stably extend to the top portion of the second reflective layer RFL2 and the common electrode CE. Accordingly, the first connection electrode BE1 may be stably formed between the pixel electrode PXE and the first contact electrode CTE1, and the second connection electrode BE2 may be stably formed between the common electrode CE and the second contact electrode CTE2. Due to this, the light emitting element LE may be stably connected between the pixel electrode PXE and the and the common electrode CE.

In addition, according to the embodiment of FIGS. 13 - 16, the light emitting element LE may be stably supported by the eighth insulating layer 132. For example, the eighth insulating layer 132 may be opened below the first contact electrode CTE1 and the second contact electrode CTE2 by a width smaller than the width of the first contact electrode CTE1 and the second contact electrode CTE2, and the other portions of the bottom surface of the light emitting element LE including the bottom surface vertex portions of the light emitting element LE may be stably supported by the eighth insulating layer 132. Accordingly, the light emitting element LE may be prevented from being tilted or slanted and the light emitting element LE may be stably supported in each sub-pixel SPX.

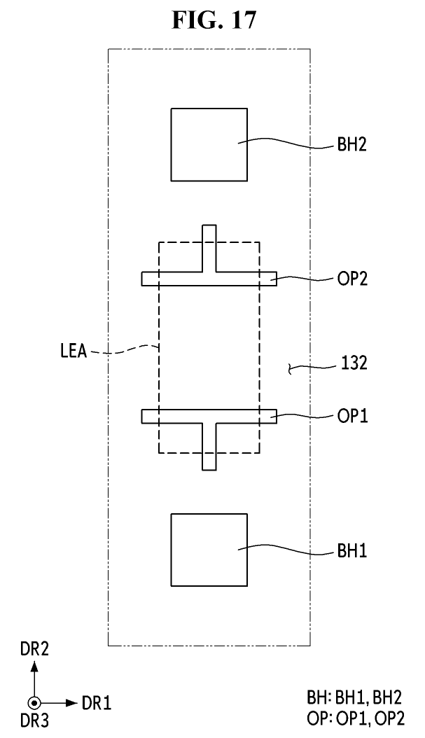

FIG. 17 is a plan view illustrating an insulating layer between a pixel electrode layer and a light emitting element of a display panel according to one or more embodiments. For example, FIG. 17 shows the eighth insulating layer 132 of the display panel 100 according to one or more embodiments.

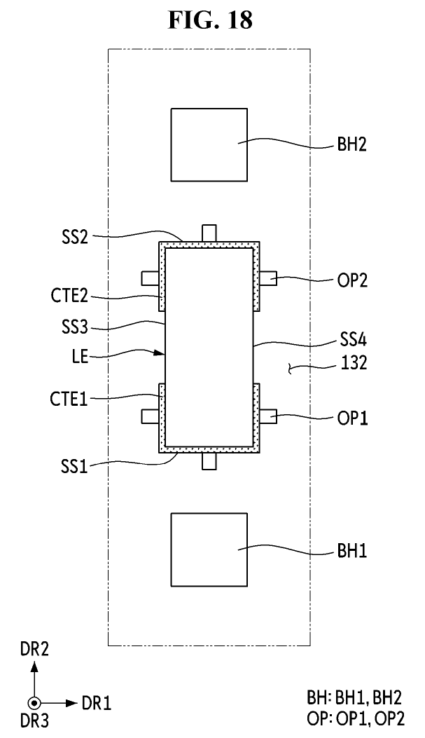

FIG. 18 is a plan view illustrating the insulating layer and the light emitting element located on the insulating layer of FIG. 17. For example, FIG. 18 shows the eighth insulating layer 132 and the light emitting element LE located on the eighth insulating layer 132 of FIG. 17.

FIGS. 17 and 18 show embodiments different from the embodiments of FIGS. 13 and 14 in relation to the first opening OP1 and the second opening OP2 formed in the eighth insulating layer 132.

Referring to FIGS. 17 and 18 in addition to FIGS. 13 - 16, the plurality of slit-type openings included in each of the first opening OP1 and the second opening OP2 may be combined as one integral opening. For example, the first, second, and third slit-type openings SLT1, SLT2, and SLT3 of FIGS. 13 and 14 may extend further in the first direction DR1 and/or the second direction DR2 to meet each other and may substantially form one first opening OP1. Similarly, the fourth, fifth, and sixth slit-type openings SLT4, SLT5, and SLT6 of FIGS. 13 and 14 may extend further in the first direction DR1 and/or the second direction DR2 to meet each other and may substantially form one second opening OP2.

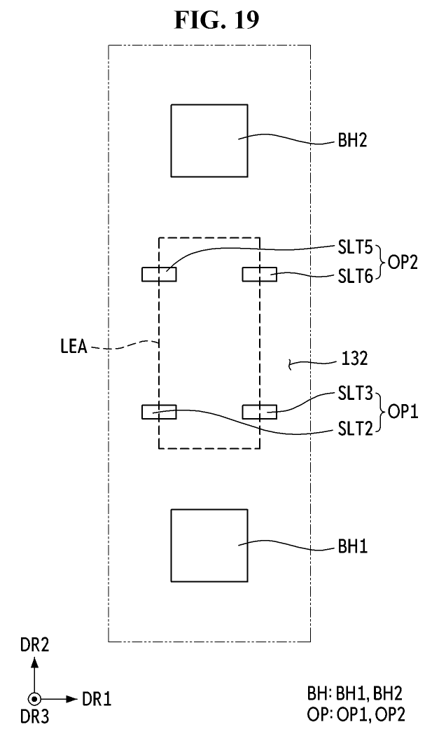

FIG. 19 is a plan view illustrating an insulating layer between a pixel electrode layer and a light emitting element of a display panel according to one or more embodiments. For example, FIG. 19 shows the eighth insulating layer 132 of the display panel 100 according to one or more embodiments.

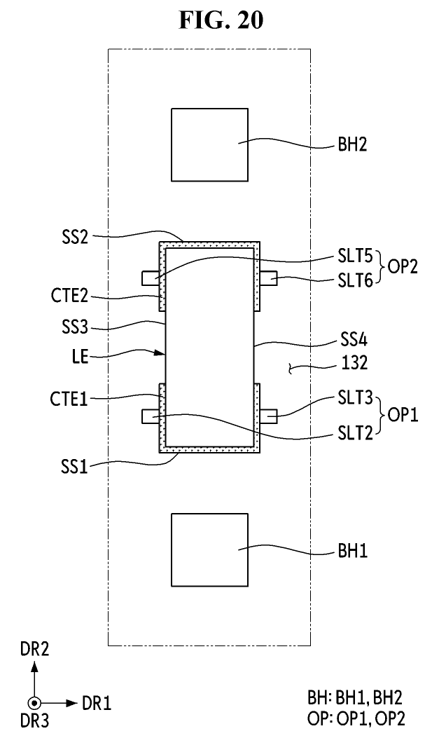

FIG. 20 is a plan view illustrating the insulating layer and the light emitting element located on the insulating layer of FIG. 19. For example, FIG. 20 shows the eighth insulating layer 132 and the light emitting element LE located on the eighth insulating layer 132 of FIG. 19.

FIGS. 19 and 20 show embodiments different from the embodiments of FIGS. 13 and 14 with respect to the first opening OP1 and the second opening OP2 formed in the eighth insulating layer 132.

Referring to FIGS. 19 and 20 in addition to FIGS. 13 - 16, the first opening OP1 and the second opening OP2 may include slit-type openings extending and/or aligned in the first direction DR1. For example, the first opening OP1 may not include the first slit-type opening SLT1 of FIGS. 13 and 14 and include only the second slit-type opening SLT2 and the third slit-type opening SLT3. In addition, the second opening OP2 may not include the fourth slit-type opening SLT4 of FIGS. 13 and 14 and include only the fifth slit-type opening SLT5 and the sixth slit-type opening SLT6.

Although the embodiment in which each of the first opening OP1 and the second opening OP2 includes the plurality of slit-type openings is illustrated in each of FIGS. 19 and 20, the present disclosure is not limited thereto. For example, the first opening OP1 may include only one from among the second slit-type opening SLT2 or the third slit-type opening SLT3 and the second opening OP2 may include only one from among the fifth slit-type opening SLT5 or the sixth slit-type opening SLT6.

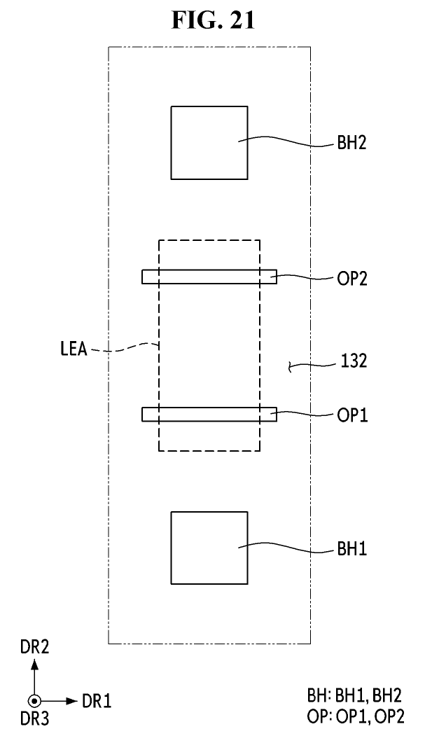

FIG. 21 is a plan view illustrating an insulating layer between a pixel electrode layer and a light emitting element of a display panel according to an embodiment. For example, FIG. 21 shows the eighth insulating layer 132 of the display panel 100 according to an embodiment.

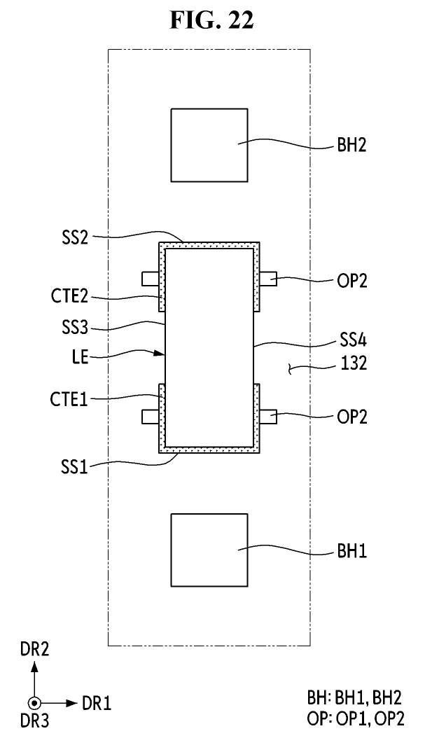

FIG. 22 is a plan view illustrating the insulating layer and the light emitting element located on the insulating layer of FIG. 21. For example, FIG. 22 shows the eighth insulating layer 132 and the light emitting element LE located on the eighth insulating layer 132 of FIG. 21.

FIGS. 21 and 22 show embodiments different from the embodiments of FIGS. 19 and 20 in relation to the first opening OP1 and the second opening OP2 formed in the eighth insulting layer 132.

Referring to FIGS. 21 and 22 in addition to FIGS. 19 and 20, the plurality of slit-type openings included in each of the first opening OP1 and the second opening OP2 of FIGS. 19 and 20 may be combined as one integral opening. For example, the second and third slit-type openings SLT2 and SLT3 of FIGS. 19 and 20 may extend further in the first direction DR1 to meet each other and may substantially form one first opening OP1. Similarly, the fifth and sixth slit-type openings SLT5 and SLT6 of FIGS. 19 and 20 may extend further in the first direction DR1 to meet each other and may substantially form one second opening OP2.

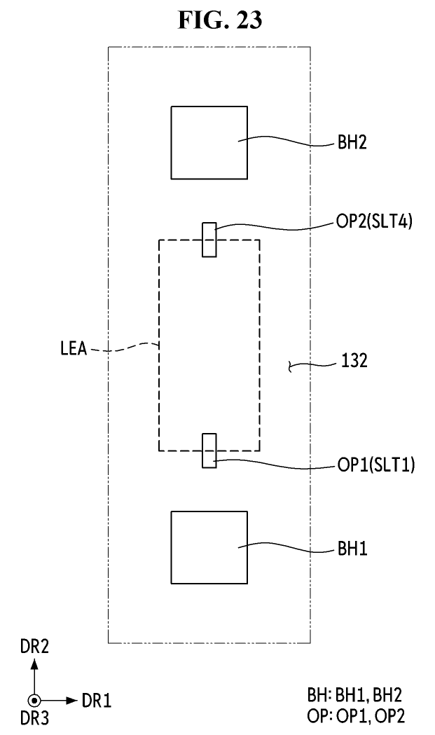

FIG. 23 is a plan view illustrating an insulating layer between a pixel electrode layer and a light emitting element of a display panel according to one or more embodiments. For example, FIG. 23 shows the eighth insulating layer 132 of the display panel 100 according to one or more embodiments.

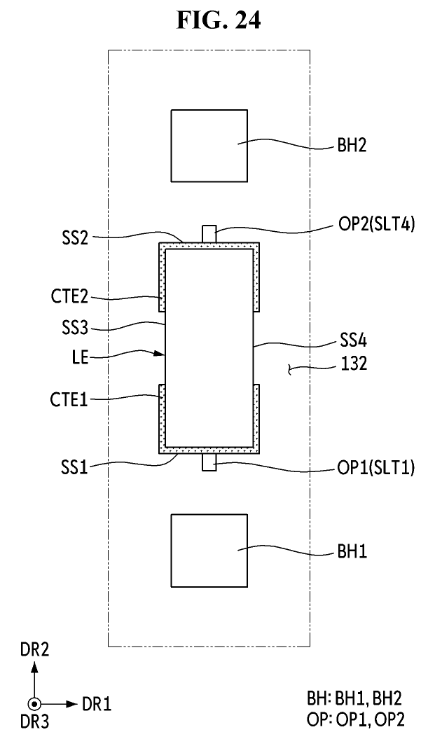

FIG. 24 is a plan view illustrating the insulating layer and the light emitting element located on the insulating layer of FIG. 23. For example, FIG. 24 shows the eighth insulating layer 132 and the light emitting element LE located on the eighth insulating layer 132 of FIG. 23.

FIGS. 23 and 24 show embodiments different from the embodiments of FIGS. 13 and 14 in relation to the first opening OP1 and the second opening OP2 formed in the eighth insulting layer 132.

Referring to FIGS. 23 and 24 in addition to FIGS. 13 - 16, each of the first opening OP1 and the second opening OP2 may include slit-type openings extending and/or aligned in the second direction DR2. For example, the first opening OP1 may not include the second and third slit-type openings SLT2 and SLT3 of FIGS. 13 and 14 and may include only the first slit-type opening SLT1. In addition, the second opening OP2 may not include the fifth and sixth slit-type openings SLT5 and SLT6 of FIGS. 13 and 14 and may include only the fourth slit-type opening SLT4.

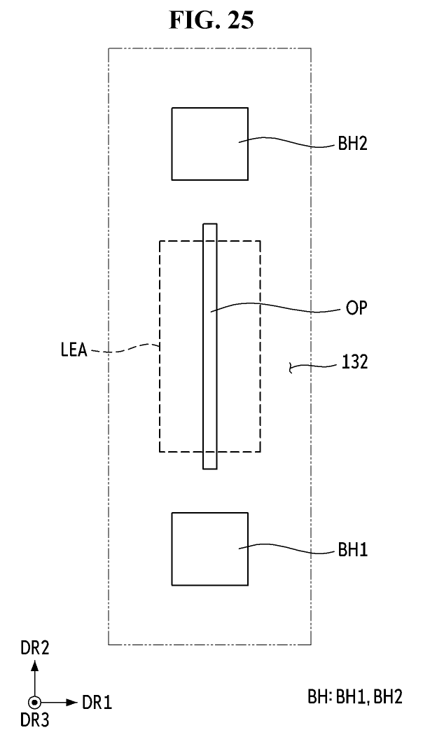

FIG. 25 is a plan view illustrating an insulating layer between a pixel electrode layer and a light emitting element of a display panel according to an embodiment. For example, FIG. 25 shows the eighth insulating layer 132 of the display panel 100 according to an embodiment.

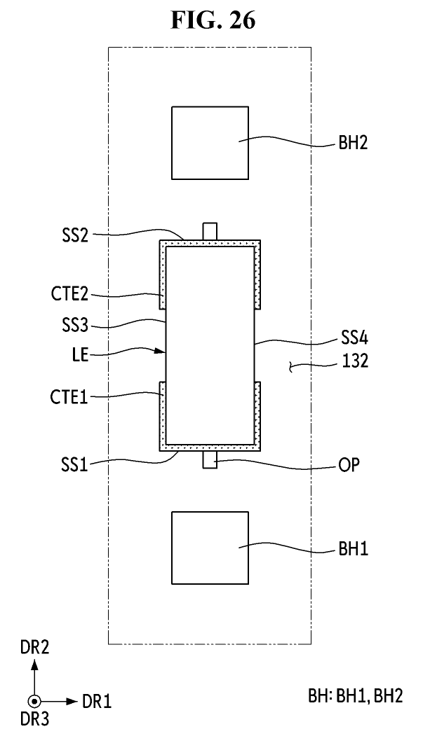

FIG. 26 is a plan view illustrating the insulating layer and the light emitting element located on the insulating layer of FIG. 25. For example, FIG. 26 shows the eighth insulating layer 132 and the light emitting element LE located on the eighth insulating layer 132 of FIG. 25.

FIGS. 25 and 26 show embodiments different from the embodiments of FIGS. 23 and 24 with respect to the first opening OP1 and the second opening OP2 formed in the eighth insulating layer 132.

Referring to FIGS. 25 and 26 in addition to FIGS. 23 and 24, the first opening OP1 and the second opening OP2 of FIGS. 23 and 24 may be combined as one opening. For example, the first opening OP1 (e.g., the first slit-type opening SLT1) and the second opening OP2 (e.g., the fourth slit-type opening SLT4) of FIGS. 23 and 24 may extend in the second direction DR2 to meet each other and substantially form one opening OP.

In the embodiments of FIGS. 17 - 26, by forming at least one opening OP overlapping a portion of the first contact electrode CTE1 and the second contact electrode CTE2 in the eighth insulating layer 132 below the light emitting element LE, disconnection of the first contact electrode CTE1 and the second contact electrode CTE2 may be prevented. Accordingly, the light emitting element LE may be stably connected between the pixel electrode PXE and the and the common electrode CE.

In addition, even in the embodiments of FIGS. 17 - 26, the light emitting element LE may be stably supported by the eighth insulating layer 132. For example, a portion of the bottom surface of the light emitting element LE including the bottom surface vertex portions of the light emitting element LE may be stably supported by the eighth insulating layer 132. Accordingly, the light emitting element LE may be stably placed in each sub-pixel SPX.

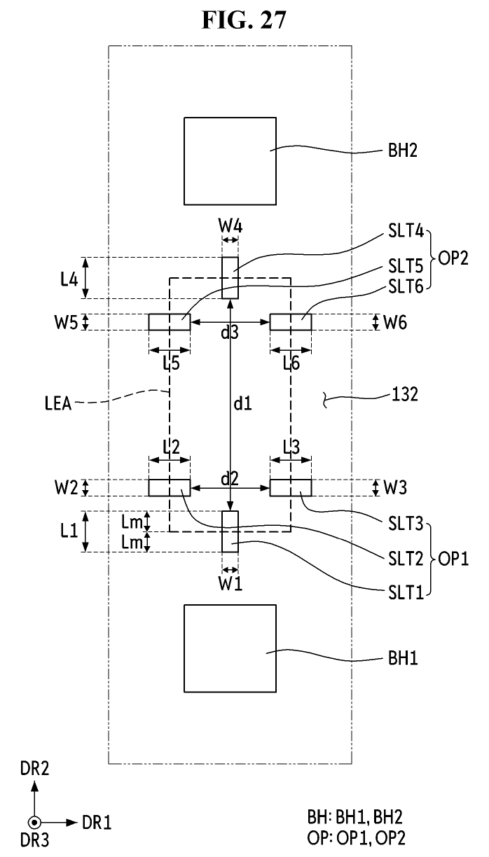

FIG. 27 is a plan view illustrating openings of an insulating layer according to one or more embodiments. For example, FIG. 27 shows the openings OP formed in the eighth insulating layer 132 according to the embodiment of FIG. 13 in detail.

Referring to FIG. 27, each of the openings OP may have a width smaller than the width or length of the light emitting element area LEA at a portion crossing one side of the light emitting element area LEA where the light emitting element LE is disposed. In addition, each of the openings OP may extend in a direction crossing the one side of the light emitting element area LEA.

The first slit-type opening SLT1 may have a first width W1 smaller than the width of the light emitting element area LEA in the first direction DR1 and may have a first length L1 in the second direction DR2. The second slit-type opening SLT2 may have a second width W2 smaller than the length of the light emitting element area LEA in the second direction DR2 and may have a second length L2 in the first direction DR1. The third slit-type opening SLT3 may have a third width W3 smaller than the length of the light emitting element area LEA in the second direction DR2 and may have a third length L3 in the first direction DR1.

The fourth slit-type opening SLT4 may have a fourth width W4 smaller than the width of the light emitting element area LEA in the first direction DR1 and may have a fourth length L4 in the second direction DR2. The fifth slit-type opening SLT5 may have a fifth width W5 smaller than the length of the light emitting element area LEA in the second direction DR2 and may have a fifth length L5 in the first direction DR1. The sixth slit-type opening SLT6 may have a sixth width W6 smaller than the length of the light emitting element area LEA in the second direction DR2 and may have a sixth length L6 in the first direction DR1.

In one or more embodiments, the slit-type openings may have substantially the same size and/or shape. For example, the slit-type openings may have a rectangular planar shape and have substantially the same width and length. Each of the slit-type openings may be aligned in the first direction DR1 or the second direction DR2.

For example, the first, second, third, fourth, fifth, and sixth widths W1, W2, W3, W4, W5, and W6 of the respective first, second, third, fourth, fifth, and sixth slit-type openings SLT1, SLT2, SLT3, SLT4, SLT5, and SLT6 may be the same as each other, and the first, second, third, fourth, fifth, and sixth lengths L1, L2, L3, L4, L5, and L6 of the respective first, second, third, fourth, fifth, and sixth slit-type openings SLT1, SLT2, SLT3, SLT4, SLT5, and SLT6 may be the same as each other. Some of the first, second, third, fourth, fifth, and sixth slit-type openings SLT1, SLT2, SLT3, SLT4, SLT5, and SLT6 (for example, the first and fourth slit-type openings SLT1 and SLT4) may each be extended and/or aligned in the second direction DR2, and the rest of the first, second, third, fourth, fifth, and sixth slit-type openings SLT1, SLT2, SLT3, SLT4, SLT5, and SLT6 (for example, the second, third, fifth, and sixth slit-type openings SLT2, SLT3, SLT5, and SLT6) may each be extended and/or aligned in the first direction DR1.

In one or more embodiments, the length of each of the slit-type openings may correspond to the margin length Lm corresponding to an overlapping length of each of the slit-type opening and the light emitting element LE. For example, the margin length Lm may be a length experimentally set for a stable forming of the connection electrodes BE, and the length of each of the slit-type openings may be approximately double the margin length Lm.

In one or more embodiments, the margin length Lm may be set as equal to or less than 1.5 µm to stably prevent disconnection of each of the first connection electrode BE1 and the second connection electrode BE2. In this case, the first, second, third, fourth, fifth, and sixth lengths L1, L2, L3, L4, L5, and L6 may each be equal to or less than 3 µm. For example, in a case where the margin length Lm is set as a value belonging within the range from approximately 1 µm to 1.5 µm, each of the first, second, third, fourth, fifth, and sixth lengths L1, L2, L3, L4, L5, and L6 may be in the range of 2 µm to 3 µm. Accordingly, the edge of the bottom surface of the light emitting element LE may appropriately overlap each of the slit-type openings, and the first connection electrode BE1 and the second connection electrode BE2 may be stably formed. However, in a case where each of the first, second, third, fourth, fifth, and sixth lengths L1, L2, L3, L4, L5, and L6 is less than 2 µm, there is a high possibility that each slit-type opening and the light emitting element LE will not appropriately overlap if an alignment error occurs during the manufacturing process of the display panel 100. In a case where each of the first, second, third, fourth, fifth, and sixth lengths L1, L2, L3, L4, L5, and L6 is greater than 3 µm, the possibility of a disconnection occurring in the first connection electrode BE1 and/or the second connection electrode BE2 may increase.

In one or more embodiments, when the margin length Lm suitable for forming the first connection electrode BE1 and the second connection electrode BE2 so that the conductive film is stably formed without being disconnected is within 1.5 µm, the margin length Lm may be set to 1.2 µm considering a process error of approximately 20%. In this case, each slit-type opening (or each opening OP) may be formed to have a length of approximately 2.4 µm.

In one or more embodiments, the width of each of the slit-type openings may vary depending on the limits of the process capability to appropriately and/or easily form each slit-type opening and at least one of the width or length of the light emitting element LE, the first contact electrode CTE1 and/or the second contact electrode CTE2. For example, in a case where the width or length of each of the light emitting element LE, the first contact electrode CTE1 and/or the second contact electrode CTE2 is several micrometers (µm) to several tens of micrometers, the width of each of the slit-type openings may be reduced or minimized to match the limits of the process capability, thereby stably supporting the light emitting elements LE by the eighth insulating layer 132.

For example, if it is difficult to properly or easily form each of the slit-type openings in case the width of each of the slit-type openings is less than 1 µm and if each of the slit-shaped openings can be properly and/or easily formed in case the width of each of the slit-type openings is 1 µm or more, each of the slit-type openings may be formed to have a width of 1 µm or more. In addition, the width of each of the slit-type openings may be smaller than the width or the shortest length of each of the first contact electrode CTE1 and the second contact electrode CTE2. For example, in a case where the light emitting element area LEA in which the light emitting element LE is to be placed has the width of 10 µm and the length of 25 µm respectively in the first direction DR1 and the second direction DR2, the width of each of the slit-type openings may be set as equal to or less than 5 µm. In one or more embodiments, in a case where the slit-type openings having the width of approximately 1/3 or less (e.g., approximately 3 µm or less) of the width of the light emitting element LE are arranged below the light emitting element LE, the slit-type openings may not be biased on the vertex portions of the bottom surface of the light emitting element LE even if a slight process error occurs, and may be appropriately placed on the targeted position. In one or more embodiments, when the width of each of the slit-type openings is reduced or minimized (for example, when the slit-type openings each having the width of 1 µm are placed below the light emitting element LE), the overlapping area of the eighth insulating layer 132 and the light emitting element LE may increase or may be maximized. Accordingly, the eighth insulating layer 132 may more stably support the light emitting element LE.

In one or more embodiments, the distance between the slit-type openings may vary depending on the size of the light emitting element LE (or the light emitting element area LEA) and the size of the slit-type openings. For example, a first distance d1 between the first slit-type opening SLT1 and the fourth slit-type opening SLT4, a second distance d2 between the second slit-type opening SLT2 and the third slit-type opening SLT3, and a third distance d3 between the fifth slit-type opening SLT5 and the sixth slit-type opening SLT6 may vary depending on the size of the light emitting element LE (or the light emitting element area LEA) and the size of each of the first, second, third, fourth, fifth, and sixth slit-type openings SLT1, SLT2, SLT3, SLT4, SLT5, and SLT6. For example, in a case where each slit-type opening has a width of 1 µm and a length of 2.4 µm and the light emitting element LE (or the light emitting element area LEA) has a width of 10 µm and a length of 25 µm respectively in the first direction DR1 and the second direction DR2, the first distance d1, the second distance d2, and the third distance d3 may be respectively 22.6 µm, 7.6 µm, and 7.6 µm.

In addition to the embodiments described above, if the light emitting element LE and the connection electrodes BE may be stably aligned and/or formed in each sub-pixel SPX, the size, shape, distance between adjacent openings OP and/or the like of each opening OP may be variously modified according to one or more embodiments. In addition, the distance between the openings OP and the connection holes BH may be changed depending on the size of the light emitting element LE, the size or position of each opening OP, and/or the size or position of the connection holes BH.

As described above, the display panel 100 of the display device 1 according to one or more embodiments may include the eighth insulating layer 132 located below the light emitting element LE of each of the sub-pixels SPX, and the eighth insulating layer 132 may include at least one opening OP crossing the entire side surfaces or some side surfaces of the light emitting element LE below the light emitting element LE of each of the sub-pixels SPX. Each opening OP may expose a portion of the bottom surface of the contact electrode (for example, the first contact electrode CTE1 or the second contact electrode CTE2) located at least on one side surface of the light emitting element LE, and the portion of the bottom surface of the exposed contact electrode may be covered by the first connection electrode BE1 or the second connection electrode BE2. According to one or more embodiments, disconnection of the connection electrodes BE may be prevented, and the light emitting element LE may be stably aligned and/or connected between the pixel electrode PXE and the common electrode CE of each sub-pixel SPX.

In addition, in one or more embodiments, the eighth insulating layer 132 may stably support the light emitting element LE. For example, the eighth insulating layer 132 may not be opened below the bottom surface vertex portions of the light emitting element LE, and thus, may stably support the light emitting element LE.

The number, size, and/or shape of the opening OP located in each sub-pixel SPX may be variously modified according to one or more embodiments. For example, in the eighth insulating layer 132, the openings OP according to at least one embodiment from among the embodiments of FIGS. 13 - 26 may be formed.

Depending on the size and/or arrangement of the openings OP, the stability of the connection by the connecting electrodes BE and the stability of the arrangement of the light emitting elements LE may vary. For example, as shown in the embodiments of FIGS. 13 - 16, in a case where the first openings OP1 and the second openings OP2 crossing different side surfaces of the respective first contact electrode CTE1 and the second contact electrode CTE2 are placed to be separated below the first contact electrode CTE1 and the second contact electrode CTE2, the first connection electrode BE1 may be appropriately formed on each side surface of the first contact electrode CTE1 and the second connection electrode BE2 may be appropriately formed on each side surface of the second contact electrode CTE2. Accordingly, the first contact electrode CTE1 may be stably connected to the pixel electrode PXE, and the second contact electrode CTE2 may be stably connected to the common electrode CE. In addition, according to the embodiments of FIGS. 13 - 16, the size (e.g., area) of an area of the eighth insulting layer 132 opened may be reduced or minimized below each of the light emitting element LE. For example, the eighth insulting layer 132 of FIGS. 13 and 14 may include relatively small opening OP compared to the eighth insulting layer 132 of FIGS. 17 and 18, and thus, the overlapping area of the eighth insulting layer 132 and the light emitting element LE may increase. Accordingly, in the embodiments of FIGS. 13 - 16, the light emitting element LE may be more stably connected between the pixel electrode PXE and the common electrode CE while concurrently (e.g., simultaneously) more stably placing the light emitting element LE on the eighth insulating layer 132.

The embodiments in which the eighth insulating layer 132 is etched or removed by its entire thickness in the area where each opening OP is formed are disclosed in FIGS. 13 - 27, but the present disclosure is not limited thereto. For example, as the eighth insulating layer 132 is etched or removed by its entire thickness in the area where each opening OP is formed, a groove may be formed in the eighth insulating layer 132. For example, the openings OP of the eighth insulating layer 132 according to one or more embodiments may be formed as grooves of the eighth insulating layer 132. Even in this case, conductive material may be appropriately deposited inside each groove of the eighth insulating layer 132 during the process of forming the connection electrodes BE and prevent disconnection of the connection electrodes BE.

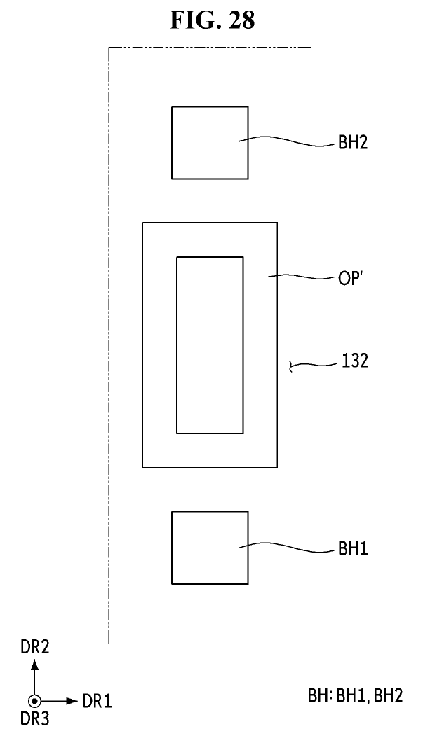

FIG. 28 is a plan view illustrating an insulating layer between a pixel electrode layer and a light emitting element of a display panel according to one or more embodiments. For example, FIG. 28 shows the eighth insulating layer 132 of the display panel 100 according to one or more embodiments.

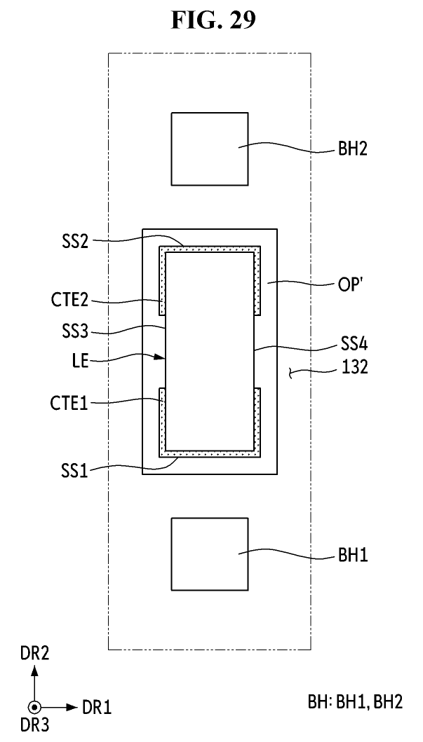

FIG. 29 is a plan view illustrating the insulating layer and the light emitting element located on the insulating layer of FIG. 28. For example, FIG. 29 shows the eighth insulating layer 132 and the light emitting element LE located on the eighth insulating layer 132 of FIG. 28.

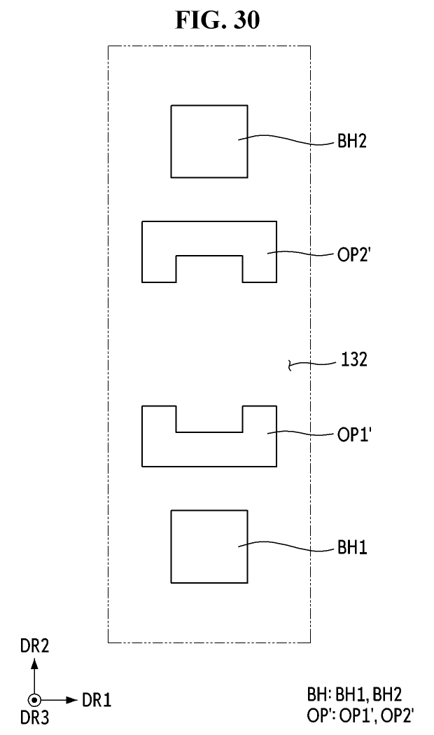

FIG. 30 is a plan view illustrating an insulating layer between a pixel electrode layer and a light emitting element of a display panel according to one or more embodiments. For example, FIG. 30 shows the eighth insulating layer 132 of the display panel 100 according to one or more embodiments.

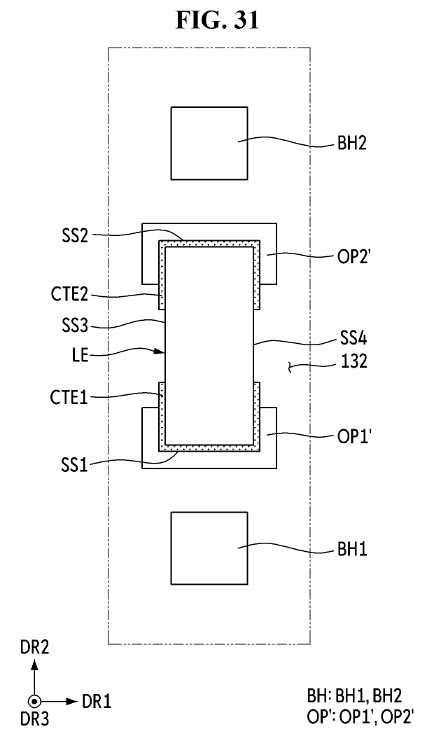

FIG. 31 is a plan view illustrating the insulating layer and the light emitting element located on the insulating layer of FIG. 30. For example, FIG. 31 shows the eighth insulating layer 132 and the light emitting element LE located on the eighth insulating layer 132 of FIG. 30.

Referring to FIGS. 28 - 31, an opening OP’ having a width and/or length greater than the width and/or length of the light emitting element LE may be formed in the eighth insulating layer 132. For example, as shown in FIGS. 28 and 29, the eighth insulating layer 132 may include an opening OP’ formed below the edge portion of the light emitting element LE including the side surfaces of the light emitting element LE and may support the light emitting element LE only below the central portion of the light emitting element LE. Alternatively, as shown in FIGS. 30 and 31, the eighth insulating layer 132 may include a first opening OP1’ having a width greater than the first contact electrode CTE1 and the light emitting element LE below one end of the light emitting element LE including a first side surface SS1 of the light emitting element LE and may include a second opening OP2’ having a width greater than the second contact electrode CTE2 and the light emitting element LE below an other end of the light emitting element LE including a second side surface SS2 of the light emitting element LE.

According to the embodiments of FIGS. 28 - 31, as shown in the embodiments of FIGS. 13 - 27, as a portion of the eighth insulating layer 132 is opened below the light emitting element LE, disconnection of the connection electrodes BE may be prevented. However, in comparison to the embodiments of FIGS. 13-27, it may be difficult to for the eighth insulating layer 132 to stably support the light emitting element LE in the embodiments of FIGS. 28 - 31. For example, because the eighth insulating layer 132 does not support the bottom surface vertex portions of the light emitting element LE, in a process of arranging and/or fixing the light emitting element LE on the eighth insulating layer 132, the light emitting element LE may be tilted to one side to cause lifting on the other side or there may be an increased risk of the light emitting element LE falling over. Accordingly, the stability of arranging and/or fixing the light emitting element LE may be reduced, and thus, a bonding error or a scotoma defect of the light emitting element LE may occur.

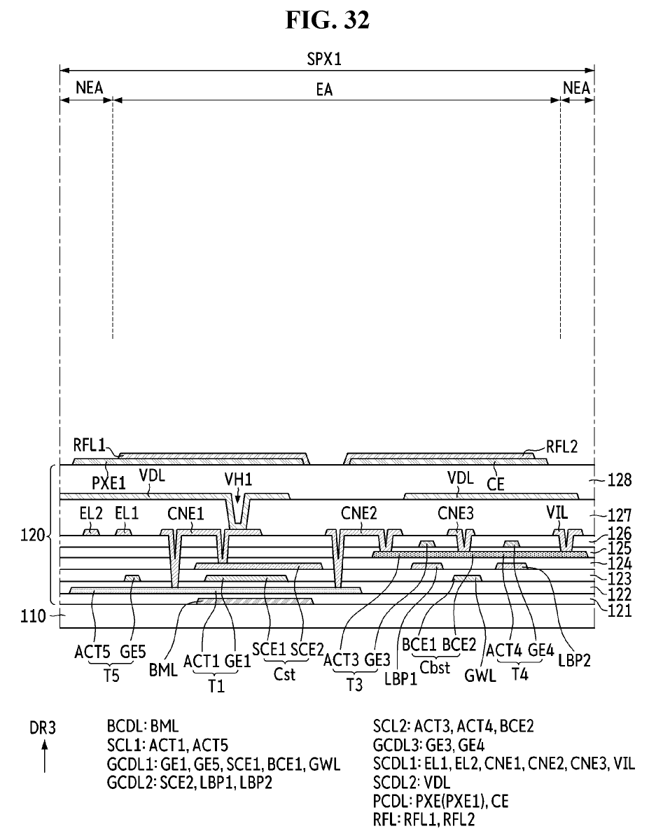

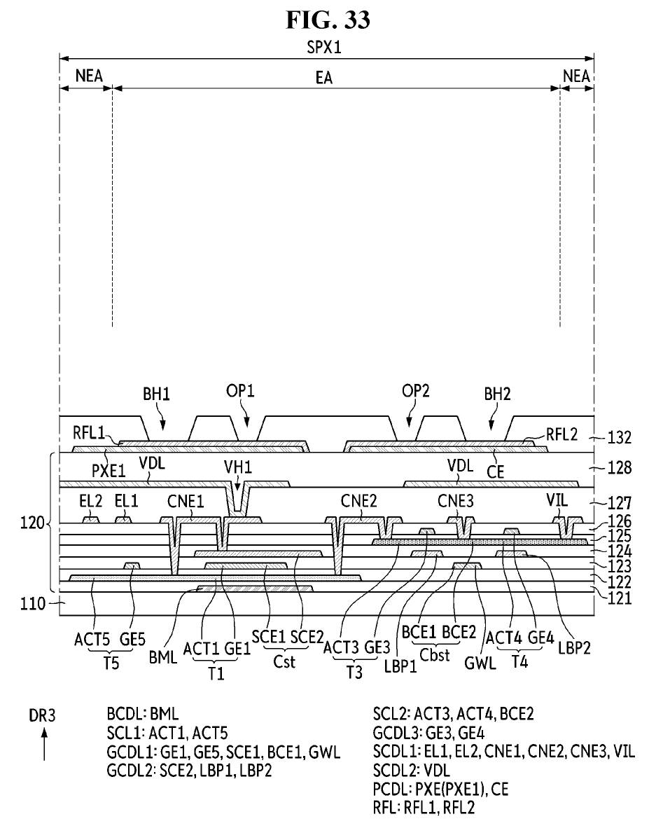

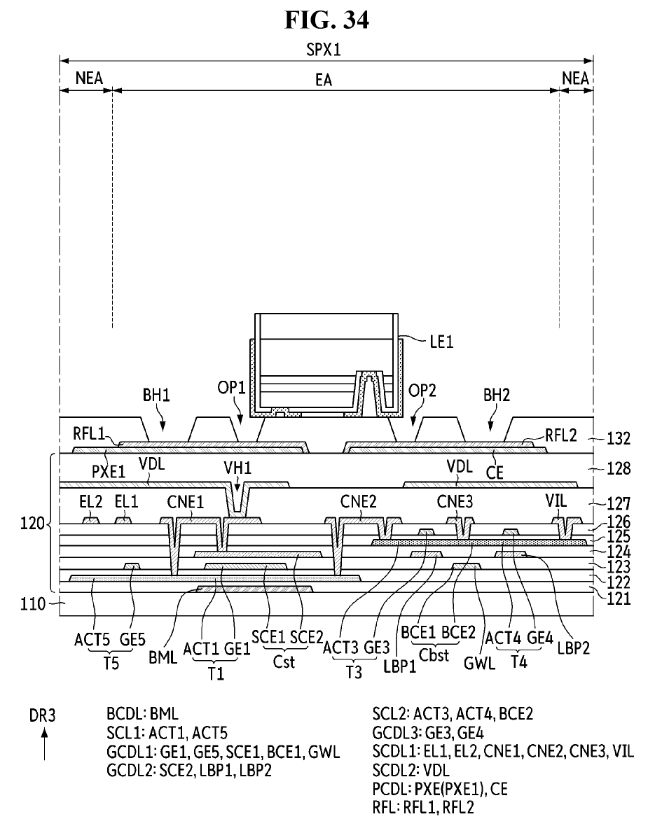

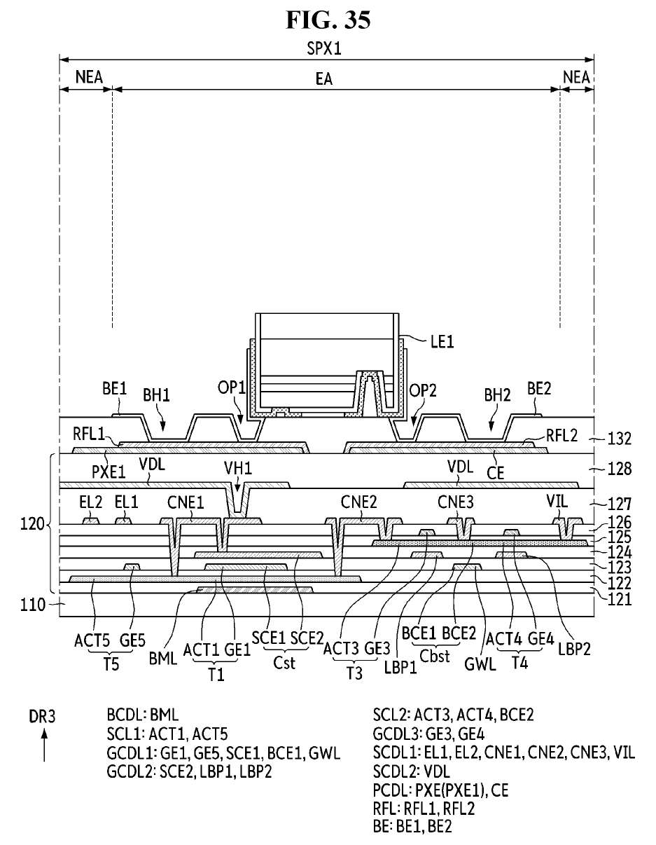

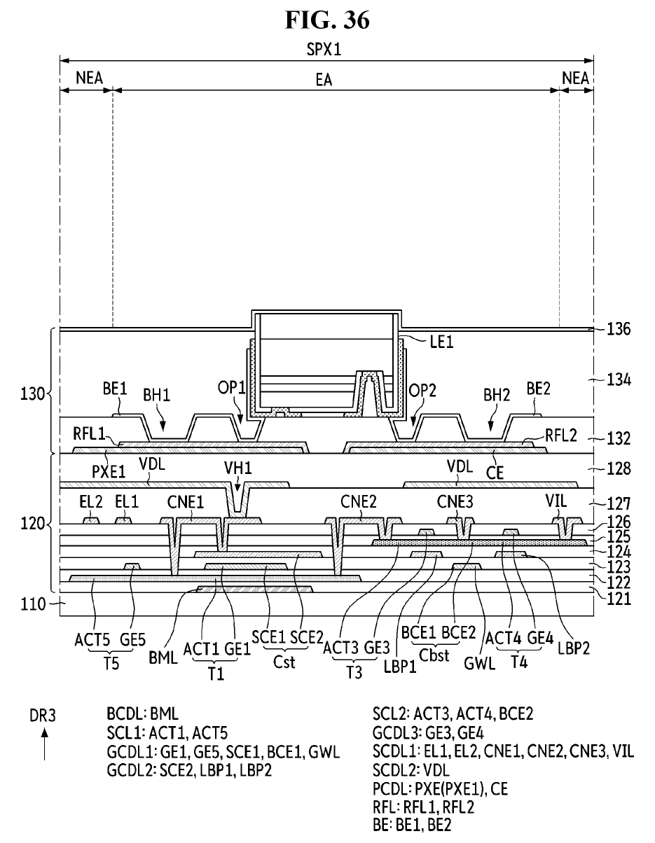

FIGS. 32 - 36 are cross-sectional views showing a manufacturing method of a display device according to one or more embodiments. For example, FIGS. 32 - 36 sequentially show manufacturing steps for forming a light emitting element layer 130 from among the manufacturing steps for forming the display panel 100 according to the embodiments of FIGS. 13 - 16. The display panel 100 according to other embodiments may be manufactured in a manner substantially the same or similar to the display panel 100 according to the embodiments of FIGS. 13 - 16, except that the number, shape, size, and/or position of the openings OP formed in the eighth insulating layer 132 are changed.

Referring to FIG. 32 in addition to FIGS. 13 and 31, a pixel electrode layer PCDL may be formed on a substrate 110. For example, a backplane layer 120 may be formed on the substrate 110, and the pixel electrode layer PCDL including the pixel electrodes PXE and the common electrode CE of the sub-pixels SPX may be formed on the backplane layer 120.

Patterns of the pixel electrode layer PCDL may use at least one conductive material to form patterns of a single-layer or multi-layer. For example, after forming (for example, forming on the entire surface) a conductive film of a single layer or a multi-layer on the backplane layer 120 by using at least one conductive material appropriate to form the pixel electrodes PXE and the common electrode CE, a patterning process including an etching process of the conductive film is performed to form the conductive film as patterns of the pixel electrode layer PCDL.

Thereafter, a reflective layer RFL may be formed on the pixel electrode layer PCDL. For example, a first reflective layer RFL1 may be formed on a portion of each of the pixel electrodes PXE, and a second reflective layer RFL2 may be formed on a portion of the common electrode CE. In one or more embodiments, the reflective layer RFL may be formed using a conductive material such as metal. For example, a film formation process and a patterning process of the conductive film using at least one conductive material including metal with high reflectivity may be performed to form the reflective layer RFL on the pixel electrode layer PCDL.

Referring to FIG. 33, an eighth insulating layer 132 (e.g., adhesive layer) may be formed on the pixel electrode layer PCDL and the reflective layer RFL. For example, by etching or removing a portion of the eighth insulating layer 132 after forming the eighth insulating layer 132 on the entire surface of the display area DA and/or the like by using an organic insulating material having adhesive properties, a first connection hole BH1, a second connection hole BH2, and at least one opening OP (for example, a first opening OP1 and a second opening OP2 each including at least one slit-type opening, or one combined opening OP) may be formed in each of the sub-pixels SPX. Alternatively, the eighth insulating layer 132 is remained only on a portion of each sub-pixels SPX including each of the light emitting element area LEA and the peripheral area (e.g., an area in which the opening OP is to be formed and/or the like) and the eighth insulating layer 132 may be etched or removed in the other portion (for example, emission area EA or an outer edge area of a sub-pixel area) of each of the sub-pixels SPX.

In one or more embodiments, each of the openings OP may be formed having a width smaller than the width of the first contact electrode CTE1 and/or the second contact electrode CTE2 to match the position where first contact electrode CTE1 and/or the second contact electrode CTE2 is to be placed. By forming at least one opening OP having a width narrower than each of the light emitting element LE below each of the light emitting element LE, disconnection of the connection electrodes BE may be prevented while stably supporting the light emitting element LE in the subsequent process.

Referring to FIG. 34, the light emitting element LE of each of the sub-pixels SPX may be placed on the eighth insulating layer 132. In one or more embodiments, the light emitting elements LE may be grown and formed in a semiconductor substrate such as a silicon substrate or a sapphire substrate, and then may be moved on the pixel electrodes PXE and the common electrode CE of the display panel 100. Each of the light emitting element LE may be placed in each of the light emitting element area LEA and may be supported by the eighth insulating layer 132.

Referring to FIG. 35, the connection electrodes BE of the sub-pixels SPX may be formed on the pixel electrode layer PCDL, the reflective layer RFL, the eighth insulating layer 132, and the light emitting elements LE. For example, a first connection electrode BE1 and a second connection electrode BE2 may be formed on the light emitting element LE and the eighth insulating layer 132 of each of the sub-pixels SPX. In one or more embodiments, the first connection electrode BE1 and the second connection electrode BE2 may be formed using a transparent conductive oxide, and sputtering method or other methods may be used for forming.

The first connection electrode BE1 may cover the first connection hole BH1 and the first opening OP1 (or a portion of the opening OP in which the first opening OP1 and the second opening OP2 are combined) of the eighth insulating layer 132. The first connection electrode BE1 may be in contact with and/or connected to the first reflective layer RFL1 (or the pixel electrode PXE) in an area where the first connection hole BH1 is located and may be in contact with and/or connected to the first contact electrode CTE1 of the light emitting element LE in an area where the first opening OP1 is located. In one or more embodiments, the first connection electrode BE1 may be in contact with and/or connected to the first reflective layer RFL1 (or the pixel electrode PXE) even in an area where the first opening OP1 is located.

The second connection electrode BE2 may cover the second connection hole BH2 and the second opening OP2 (or the other portion of the opening OP in which the first opening OP1 and the second opening OP2 are combined) of the eighth insulating layer 132. The second connection electrode BE2 may be in contact with and/or connected to the second reflective layer RFL2 (or the common electrode CE) in an area where the second connection hole BH2 is located and may be in contact with and/or connected to the second contact electrode CTE2 of the light emitting element LE in an area where the second opening OP2 is located. In one or more embodiments, the second connection electrode BE2 may be in contact with and/or connected to the second reflective layer RFL2 (or the common electrode CE) even in an area where the second opening OP2 is located.

Referring to FIG. 36, a ninth insulating layer 134 may be formed on the light emitting element LE, the first connection electrode BE1, and the second connection electrode BE2 of each of the sub-pixels SPX. In one or more embodiments, the ninth insulating layer 134 may be formed to a height less than or equal to the height of the light emitting element LE using at least one organic insulating material, but the present disclosure is not limited thereto. The ninth insulating layer 134 may alleviate or eliminate a step caused by the light emitting elements LE.

Thereafter, a first capping layer 136 may be formed on the ninth insulating layer 134. In one or more embodiments, the first capping layer 136 may be formed as a thin film having a thin thickness using at least one inorganic insulating material. For example, the first capping layer 136 may be formed of a material and in thickness appropriate for protecting the patterns and/or light emitting elements LE located in the light emitting element layer 130.

By the process described above with reference to FIGS. 32 - 36, the light emitting element layer 130 of the display panel 100 according to one or more embodiments may be formed. Thereafter, the optical layer 140 of FIG. 15 may be formed on the light emitting element layer 130. Accordingly, a display panel 100 according to the embodiment of FIG. 15 and/or the like may be manufactured.

The display device 1 according to at least one embodiment from among the above-described embodiments may be applied to various electronic devices. The electronic device according to one or more embodiments may include the above-described display device 1 (or a display module including the display panel 100 according to at least one or more embodiments), and further include a module or a device having other additional functions.

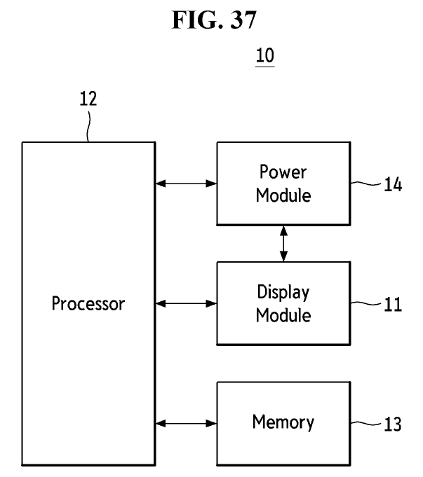

FIG. 37 is a block diagram of an electronic device according to one or more embodiments. Referring to FIG. 37, an electronic device 10 according to one or more embodiments may include a display module 11, a processor 12, a memory 13, and a power module 14.

The electronic device 10 may output various information in the form of images through the display module 11. For example, when the processor 12 executes an application stored in the memory 13, image information provided by the application may be provided to a user through the display module 11.

The display module 11 may include the display panel 100 for displaying an image. For example, the display module 11 may include the display panel 100 according to at least one of the aforementioned embodiments.

The processor 12 may include at least one of a central processing unit (CPU), an application processor (AP), a graphic processing unit (GPU), a communication processor (CP), an image signal processor (ISP), or a controller.

The memory 13 may store data information required for the operation of the processor 12 or the display module 11. For example, the memory 13 may store an image data signal and/or an input control signal.

The processor 12 may control the display module 11 using information stored in the memory 13. The processor 12 may transmit the image data signal and/or the input control signal stored in the memory 13 to the display module 11. For example, when the processor 12 executes an application stored in the memory 13, an image data signal and/or an input control signal is transmitted to the display module 11, and the display module 11 may process the received signal and output image information through a display screen.

The power module 14 may include a power supply module, such as a power adapter or a battery device, and a power conversion module that converts power supplied by the power supply module to generate power required for the operation of the electronic device 10.

At least one of the components of the electronic device 10 described above may be included in the display device 1 according to the embodiments described above. Further, some of individual modules functionally included in one module may be included in the display device 1 and some others may be provided separately from the display device 1. For example, the display device 1 may include the display module 11, and the processor 12, the memory 13, and the power module 14 may be provided in the form of other devices in the electronic device 10 other than the display device 1.

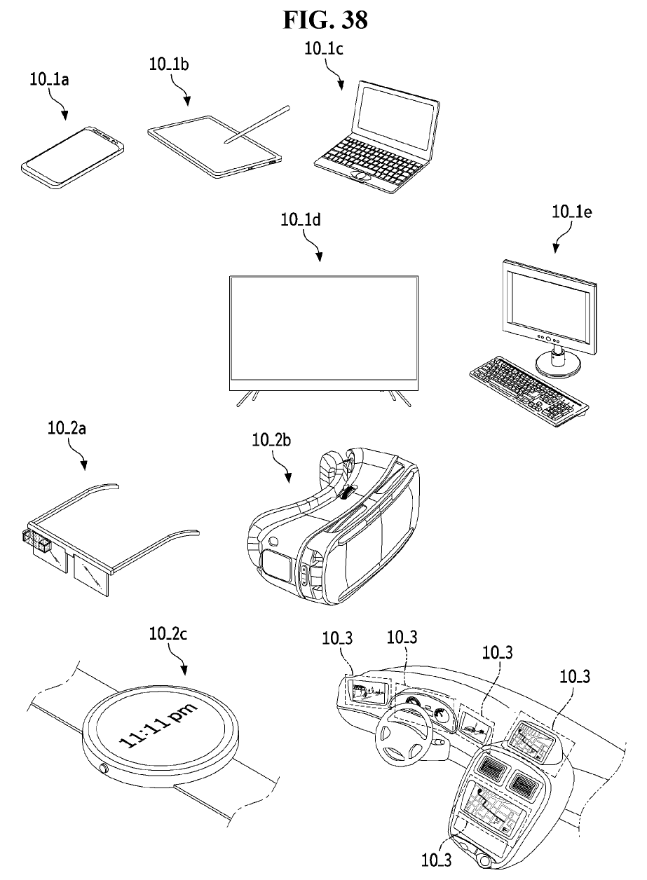

FIG. 38 is schematic views of electronic devices according to various embodiments.

Referring to FIG. 38, various electronic devices to which the display device 1 according to one or more embodiments is applied may include not only an image display electronic device such as a smartphone 10_1a, a tablet PC 10_1b, a laptop 10_1c, a TV 10_1d, and a desk monitor 10_1e, but also a wearable electronic device including a display module, such as smart glasses 10_2a, a head mounted display 10_2b, or a smart watch 10_2c, a vehicle electronic device 10_3 including a display module, such as a center fascia, and a dashboard of an automobile, a center information display (CID) placed on the dashboard, a room mirror display, and/or the like.

In concluding the detailed description, those skilled in the art will appreciate that many variations and modifications can be made to the embodiments without substantially departing from the principles and scope of the present disclosure. Therefore, the embodiments of the present disclosure are used in a generic and descriptive sense only and not for purposes of limitation.

What is claimed is:

1. A display device comprising:
a pixel electrode layer located on a substrate and comprising a pixel electrode;
an insulating layer located on the pixel electrode layer and covering a portion of the pixel electrode;
a light emitting element located on the insulating layer and including a first contact electrode located at a first side surface of the light emitting element; and
a first connection electrode located on the insulating layer and the first side surface of the light emitting element and connecting the pixel electrode and the first contact electrode,
wherein the insulating layer is located at least below bottom surface vertex portions of the light emitting element and supporting the light emitting element, the insulating layer including a first opening having a width smaller than a width of the first contact electrode and located below a portion of the first contact electrode, and
wherein a portion of the first connection electrode is located inside the first opening.

2. The display device of claim 1,
wherein the light emitting element further comprises a second side surface facing the first side surface, a third side surface in contact with one end of the first side surface and one end of the second side surface, and a fourth side surface in contact with an other end of the first side surface and an other end of the second side surface, and
wherein the first contact electrode is further located at a portion of the third side surface and a portion of the fourth side surface of the light emitting element.

3. The display device of claim 2,
wherein the first opening includes:
a first slit-type opening crossing the first side surface of the light emitting element below the first contact electrode;
a second slit-type opening crossing the third side surface of the light emitting element below the first contact electrode; and
a third slit-type opening crossing the fourth side surface of the light emitting element below the first contact electrode.

4. The display device of claim 3,
wherein at least two slit-type openings from among the first slit-type opening, the second slit-type opening, and the third slit-type opening are spaced from each other.

5. The display device of claim 3,
wherein at least two slit-type openings from among the first slit-type opening, the second slit-type opening, and the third slit-type opening are connected to form one integral opening.

6. The display device of claim 3,
wherein a length of each of the first slit-type opening, the second slit-type opening, and the third slit-type opening is 2 µm to 3 µm.

7. The display device of claim 3,
wherein the first slit-type opening has a width smaller than the width of the first contact electrode in a direction in which an edge where the first side surface and a bottom surface of the light emitting element meet extends,
wherein the second slit-type opening has a width smaller than the width of the first contact electrode in a direction in which an edge where the third side surface and the bottom surface of the light emitting element meet extends,
wherein the third slit-type opening has a width smaller than the width of the first contact electrode in a direction in which an edge where the fourth side surface and the bottom surface of the light emitting element meet extends, and
wherein the width of each of the first slit-type opening, the second slit-type opening, and the third slit-type opening is equal to or greater than 1 µm.

8. The display device of claim 2,
wherein the pixel electrode layer further comprises a common electrode spaced from the pixel electrode and having a portion covered by the insulating layer, and
wherein the light emitting element further comprises a second contact electrode located at the second side surface.

9. The display device of claim 8, further comprising a second connection electrode located on the insulating layer and the second side surface of the light emitting element and connecting the common electrode and the second contact electrode,
wherein the insulating layer further comprises a second opening having a width smaller than a width of the second contact electrode below a portion of the second contact electrode, and
wherein a portion of the second connection electrode is located inside the second opening.

10. The display device of claim 9,
wherein the second contact electrode is further located at an other portion of the third side surface of the light emitting element and an other portion of the fourth side surface, and
wherein the second opening includes at least one from among a fourth slit-type opening crossing the second side surface of the light emitting element below the second contact electrode, a fifth slit-type opening crossing the third side surface of the light emitting element below the second contact electrode, or a sixth slit-type opening crossing the fourth side surface of the light emitting element below the second contact electrode.

11. The display device of claim 10,
wherein the second opening includes at least two slit-type openings from among the fourth slit-type opening, the fifth slit-type opening, and the sixth slit-type opening, and
wherein the at least two slit-type openings are spaced from each other.

12. The display device of claim 10,
wherein the second opening includes at least two slit-type openings from among the fourth slit-type opening, the fifth slit-type opening, and the sixth slit-type opening, and
wherein the at least two slit-type openings are connected to each other to form one integral opening.

13. The display device of claim 10,
wherein a length of each of the fourth slit-type opening, the fifth slit-type opening, and the sixth slit-type opening is 2 µm to 3 µm.

14. The display device of claim 10,
wherein the fourth slit-type opening has a width smaller than the width of the second contact electrode in a direction in which an edge where the second side surface and a bottom surface of the light emitting element meet extends,
wherein the fifth slit-type opening has a width smaller than the width of the second contact electrode in a direction in which an edge where the third side surface and the bottom surface of the light emitting element meet extends,
wherein the sixth slit-type opening has a width smaller than the width of the second contact electrode in a direction in which an edge where the fourth side surface and the bottom surface of the light emitting element meet extends, and
wherein the width of each of the fourth slit-type opening, the fifth slit-type opening, and the sixth slit-type opening is equal to or greater than 1 µm.

15. The display device of claim 9,
wherein the first contact electrode and the second contact electrode are further located on different portions of a bottom surface of the light emitting element,
wherein the first connection electrode is in contact with the bottom surface of the first contact electrode on the first opening, and
wherein the second connection electrode is in contact with the bottom surface of the second contact electrode on the second opening.

16. An electronic device comprising:
a display module comprising a display panel; and
a processor configured to transmit an image data signal to the display module,
wherein the display panel comprises:
a pixel electrode layer located on a substrate and comprising a pixel electrode;
an insulating layer located on the pixel electrode layer and covering a portion of the pixel electrode;
a light emitting element located on the insulating layer and including a first contact electrode located at a first side surface of the light emitting element; and
a first connection electrode located on the insulating layer and the first side surface of the light emitting element and connecting the pixel electrode and the first contact electrode,
wherein the insulating layer is located at least below bottom surface vertex portions of the light emitting element and supporting the light emitting element, the insulating layer including a first opening having a width smaller than a width of the first contact electrode below a portion of the first contact electrode, and
wherein a portion of the first connection electrode is located inside the first opening.

17. The electronic device of claim 16,
wherein the light emitting element further comprises a second side surface facing the first side surface, a third side surface in contact with one end of the first side surface and one end of the second side surface, and a fourth side surface in contact with an other end of the first side surface and an other end of the second side surface,
wherein the first contact electrode is further located at a portion of the third side surface and a portion of the fourth side surface of the light emitting element, and
wherein the first opening comprises at least one slit-type opening crossing at least one from among the first side surface, the third side surface, or the fourth side surface of the light emitting element.

18. The electronic device of claim 17,
wherein the pixel electrode layer further comprises a common electrode spaced from the pixel electrode and a portion covered by the insulating layer,
wherein the light emitting element further comprises a second contact electrode located at the second side surface, an other portion of the third side surface and an other portion of the fourth side surface, and
wherein the display panel further comprises a second connection electrode located on the insulating layer and the second contact electrode and connecting the common electrode and the second contact electrode.

19. The electronic device of claim 18,
wherein the insulating layer further includes a second opening having a width smaller than the width of the second contact electrode and located below a portion of the second contact electrode, and
wherein a portion of the second connection electrode is located inside the second opening.

20. The electronic device of claim 19,
wherein the second opening includes at least one slit-type opening crossing at least one from among the second side surface, the third side surface, or the fourth side surface of the light emitting element.
